(19) United States
(12) Patent Application Publication
(10) Pub. No.: US 2024/0431103 A1
(43) Pub. Date: Dec. 26, 2024

(54) 3D FLASH MEMORY AND MANUFACTURING METHOD THEREOF

(71) Applicant: IUCF-HYU (Industry-University Cooperation Foundation Hanyang University), Seoul (KR)

(72) Inventors: Yun Heub SONG, Seoul (KR); Jea Min SHIM, Seoul (KR)

(21) Appl. No.: 18/706,010

(22) PCT Filed: Oct. 31, 2022
(86) PCT No.: PCT/KR2022/016815

§ 371 Date: Apr. 30, 2024

(30) Foreign Application Priority Data
Nov. 1, 2021 (KR) 10-2021-0147598
Dec. 8, 2021 (KR) 10-2021-0174954
Dec. 8, 2021 (KR) 10-2021-0174955

(51) Int. Cl. H10B 43/27; H01L 23/528; H10B 41/10; H10B 41/27; H10B 43/10

(52) U.S. Cl. CPC H10B 43/27; H01L 23/5283; H10B 41/10; H10B 41/27; H10B 43/10

(57) ABSTRACT

A 3D flash memory for improving integration and the influence of a fringing field due to a word line formed in one large area in a stack structure and a method for manufacturing the 3D flash memory are disclosed.

### TECHNICAL FIELD

Embodiments of the present disclosure described herein relate to a 3D flash memory, and more particularly, relate to a 3D flash memory for improving integration and a method for manufacturing the same.

### BACKGROUND ART

A flash memory device is an electrically erasable programmable read only memory (EEPROM) capable of electrically performing a program operation and an erase operation by electrically controlling the input and output of data by Fowler-Nordheim (F-N) tunneling or hot electron injection. The flash memory device may be commonly used in a computer, a digital camera, an MP3 player, a game system, a memory stick, and the like.

In the flash memory device, it is required to increase the degree of integration to meet excellent performance and low price demanded by consumers, and therefore a three-dimensional structure in which memory cell transistors are vertically arranged to form cell strings has been proposed.

Recently, a 3D flash memory has been manufactured to have a staggered shape in which circular channel holes are arranged in a staggered pattern to implement an integrated structure.

The existing 3D flash memory having the staggered shape has a problem in that it is difficult to secure an etching profile because it is difficult for an etching gas to flow into the channel holes.

Accordingly, the following embodiments are intended to provide a technology for solving the aforementioned problem.

In addition, since the existing 3D flash memory shares word lines within one block (stack structure) made up of a plurality of memory cell strings, the existing 3D flash memory has a problem in that a fringing field affects adjacent memory cell strings within the same block during a memory operation of an arbitrary memory cell string within the block.

Accordingly, the following embodiments are intended to provide a technology for solving the aforementioned problem.

### DETAILED DESCRIPTION OF THE INVENTION

### Technical Problem

To solve a problem that it is difficult to secure an etching profile because it is difficult for an etching gas to flow into channel holes, embodiments of the present disclosure provide a 3D flash memory in which an etching profile is secured by using at least one vertical connecting trench connecting channel holes, a method for manufacturing the 3D flash memory, and an electronic system including the 3D flash memory.

To achieve simplification of a process of filling at least one vertical connecting trench, embodiments of the present disclosure provide a 3D flash memory in which at least one vertical connecting pattern formed in the at least one vertical connecting trench is simultaneously formed through the same process together with vertical channel structures formed in channel holes, a method for manufacturing the 3D flash memory, and an electronic system including the 3D flash memory.

To implement a multi-level cell while improving the influence of a fringing field due to a large word line area in a memory, embodiments of the present disclosure provide a 3D flash memory in which at least one vertical connecting trench connects channel holes to divide word lines on a horizontal plane, a method for manufacturing the 3D flash memory, and an electronic system including the 3D flash memory.

To solve a problem such as a short circuit that occurs due to a rounded portion included in an edge where at least one vertical connecting pattern is brought into contact with each of vertical channel structures, embodiments of the present disclosure provide a 3D flash memory manufacturing method using a shape-modified mask pattern to form channel holes and at least one vertical connecting trench, and the mask pattern.

To solve a problem such as a short circuit that occurs due to a rounded portion included in an edge where at least one vertical connecting pattern is brought into contact with each of vertical channel structures, embodiments of the present disclosure provide a 3D flash memory manufacturing method for removing a seam formed within at least one vertical connecting pattern.

To improve the influence of a fringing field due to word lines formed in one large area within a stack structure, embodiments of the present disclosure provide a 3D flash memory in which each of word lines is divided into a plurality of word lines on a horizontal plane through at least one separation film, a method for manufacturing the 3D flash memory, and an electronic system including the 3D flash memory.

To simplify a process of forming at least one separation film, embodiments of the present disclosure provide a 3D flash memory in which at least one separation film is simultaneously formed through the same process together with vertical channel structures formed in channel holes, a method for manufacturing the 3D flash memory, and an electronic system including the 3D flash memory.

Embodiments of the present disclosure provide a 3D flash memory in which at least one separation film is formed to connect vertical channel structures on a horizontal plane and at least one separation film trench in which the at least one separation film is formed is used in a process of securing an etching profile for channel holes, a method for manufacturing the 3D flash memory, and an electronic system including the 3D flash memory.

However, the problems to be solved by the present disclosure are not limited to the aforementioned problems and may be expanded in various ways without departing from the spirit and scope of the present disclosure.

### Technical Solution

According to an embodiment, a 3D flash memory includes interlayer insulating films and word lines that extend in a horizontal direction and that are alternately stacked in a vertical direction, vertical channel structures that extend through the interlayer insulating films and the word lines in the vertical direction, and at least one vertical connecting pattern that connects the vertical channel structures to each other on a horizontal plane and extends in the vertical direction. Each of the vertical channel structures includes a vertical channel pattern that extends in the vertical direction and a data storage pattern that surrounds an outer wall of the vertical channel pattern.

According to an aspect, the at least one vertical connecting pattern may be simultaneously formed with the vertical channel structures through the same process.

According to another aspect, the at least one vertical connecting pattern may be formed of only the data storage pattern included in each of the vertical channel structures.

According to another aspect, the at least one vertical connecting pattern may have a size smaller than a size of each of the vertical channel structures on the horizontal plane.

According to another aspect, the at least one vertical connecting pattern may connect the vertical channel structures to each other to divide the word lines on the horizontal plane.

According to an embodiment, a mask pattern used to form vertical channel structures and at least one vertical connecting pattern in a 3D flash memory includes a serif-shaped portion included in an area corresponding to an edge where the at least one vertical connecting pattern is brought into contact with each of the vertical channel structures. The vertical channel structures extend in a vertical direction, and each of the vertical channel structures includes a vertical channel pattern that extends in the vertical direction and a data storage pattern that surrounds an outer wall of the vertical channel pattern. The at least one vertical connecting pattern connects the vertical channel structures to each other on a horizontal plane and extends in the vertical direction.

According to an aspect, the mask pattern may include the serif-shaped portion considering optical proximity correction (OPC) in a process in which the mask pattern is used.

According to another aspect, the mask pattern may include the serif-shaped portion in the area corresponding to the edge where the at least one vertical connecting pattern is brought into contact with each of the vertical channel structures such that a rounded portion is not included in the edge where the at least one vertical connecting pattern is brought into contact with each of the vertical channel structures.

According to an embodiment, a 3D flash memory includes interlayer insulating films and word lines that extend in a horizontal direction and that are alternately stacked in a vertical direction, vertical channel structures that extend through the interlayer insulating films and the word lines in the vertical direction, each vertical channel structure including a vertical channel pattern that extends in the vertical direction and a data storage pattern that surrounds an outer wall of the vertical channel pattern, and at least one separation film that is formed of the same material as that of the data storage pattern and that divides each of the word lines into a plurality of word lines on a horizontal plane.

According to an aspect, the at least one separation film may connect vertical channel structures included in at least one row or column among the vertical channel structures on the horizontal plane.

According to another aspect, the at least one separation film may include the vertical channel structures included in the at least one row or column and connecting parts that connect the vertical channel structures included in the at least one row or column on the horizontal plane.

According to another aspect, each of the vertical channel structures included in the at least one row or column may not include the vertical channel pattern.

According to another aspect, the at least one separation film may have a shape in which protrusions and indentations are repeated in an extension direction on the horizontal plane to divide each of the word lines into the plurality of portions on the horizontal plane.

According to another aspect, the at least one separation film may be simultaneously formed with the vertical channel structures through the same process.

### Advantageous Effects of the Invention

By providing the 3D flash memory in which the etching profile is secured by using the at least one vertical connecting trench connecting the channel holes, the method of manufacturing the 3D flash memory, and the electronic system including the 3D flash memory, it is possible to solve the problem that it is difficult to secure the etching profile because it is difficult for the etching gas to flow into the channel holes.

By providing the 3D flash memory in which the at least one vertical connecting pattern formed in the at least one vertical connecting trench is simultaneously formed through the same process together with the vertical channel structures formed in the channel holes, the method of manufacturing the 3D flash memory, and the electronic system including the 3D flash memory, it is possible to simplify the process of filling the at least one vertical connecting trench.

By providing the 3D flash memory in which the at least one vertical connecting trench connects the channel holes to divide the word lines on the horizontal plane, the method for manufacturing the 3D flash memory, and the electronic system including the 3D flash memory, it is possible to implement the multi-level cell while improving the influence of the fringing field due to the large word line area in the memory.

By providing the 3D flash memory manufacturing method using the shape-modified mask pattern to form the channel holes and the at least one vertical connecting trench and the mask pattern, it is possible to solve a problem such as a short circuit that occurs due to the rounded portion included in the edge where the at least one vertical connecting pattern is brought into contact with each of the vertical channel structures.

By providing the 3D flash memory manufacturing method for removing the seam formed within the at least one vertical connecting pattern, it is possible to solve a problem such as a short circuit that occurs due to the rounded portion included in the edge where the at least one vertical connecting pattern is brought into contact with each of the vertical channel structures.

By providing the 3D flash memory in which each of the word lines is divided into the plurality of word lines on the horizontal plane through the at least one separation film, the method for manufacturing the 3D flash memory, and the electronic system including the 3D flash memory, it is possible to improve the influence of the fringing field due to the word lines formed in one large area within the stack structure.

By providing the 3D flash memory in which the at least one separation film is simultaneously formed through the same process together with the vertical channel structures formed in the channel holes, the method for manufacturing the 3D flash memory, and the electronic system including the 3D flash memory, it is possible to simplify the process of forming the at least one separation film.

By forming the at least one separation film such that the at least one separation film connects the vertical channel structures on the horizontal plane, it is possible to use the at least one separation film trench having the at least one separation film formed therein in the process of securing the etching profile for the channel holes.

However, effects of the present disclosure are not limited to the aforementioned effects and may be expanded in various ways without departing from the spirit and scope of the present disclosure.

### DESCRIPTION OF THE DRAWINGS

FIG. 1 is a schematic circuit diagram illustrating an array of a 3D flash memory according to an embodiment.

FIG. 2 is a plan view illustrating the structure of the 3D flash memory according to an embodiment.

FIG. 3 is a sectional view illustrating the structure of the 3D flash memory illustrated in FIG. 2, where FIG. 3 corresponds to a sectional view taken along line A-A′ in FIG. 2.

FIG. 4 is a plan view illustrating the structure of a 3D flash memory according to another embodiment.

FIGS. 5A and 5B are plan views for explaining implementation of a multi-level cell by the structure of the 3D flash memory illustrated in FIG. 4.

FIG. 6 is a flowchart illustrating a 3D flash memory manufacturing method according to an embodiment.

FIGS. 7A to 7H are plan views illustrating the structure of the 3D flash memory to explain the 3D flash memory manufacturing method illustrated in FIG. 6.

FIGS. 8A to 8H are sectional views illustrating the structure of the 3D flash memory illustrated in FIG. 6 and correspond to sections taken along lines A-A′ in FIGS. 7A to 7H.

FIGS. 9A to 9H are sectional views illustrating the structure of the 3D flash memory illustrated in FIG. 6 and correspond to sections taken along lines B-B′ in FIGS. 7A to 7H.

FIG. 10 is a flowchart illustrating a 3D flash memory manufacturing method according to another embodiment.

FIG. 11 is a plan view illustrating a 3D flash memory having a structure in which a rounded portion is included in an edge where at least one vertical connecting pattern is brought into contact with each of vertical channel structures.

FIGS. 12A to 12D are plan views illustrating mask patterns used in a process of manufacturing the 3D flash memory illustrated in FIGS. 2 and 3.

FIG. 13 is a flowchart illustrating a manufacturing method according to an embodiment in which a gate first method is applied to manufacture the 3D flash memory illustrated in FIGS. 2 and 3.

FIGS. 14A to 14E are plan views illustrating the structure of the 3D flash memory to explain the 3D flash memory manufacturing method illustrated in FIG. 13.

FIGS. 15A to 15E are sectional views illustrating the structure of the 3D flash memory illustrated in FIGS. 14A to 14E and correspond to sections taken along lines A-A′ in FIGS. 14A to 14E.

FIGS. 16A to 16E are sectional views illustrating the structure of the 3D flash memory illustrated in FIGS. 14A to 14E and correspond to sections taken along lines B-B′ in FIGS. 14A to 14E.

FIG. 17 is a flowchart illustrating a manufacturing method according to an embodiment in which a stack method is applied in addition to the gate first method to manufacture the 3D flash memory illustrated in FIGS. 2 and 3.

FIG. 18 is a flowchart illustrating a manufacturing method according to an embodiment in which a word line replacement method is applied to manufacture the 3D flash memory illustrated in FIGS. 2 and 3.

FIG. 19 is a flowchart illustrating a manufacturing method according to an embodiment in which a stack method is applied in addition to the word line replacement method to manufacture the 3D flash memory illustrated in FIGS. 2 and 3.

FIG. 20 is a flowchart illustrating a manufacturing method according to another embodiment in which the gate first method is applied to manufacture the 3D flash memory illustrated in FIGS. 2 and 3.

FIGS. 21A to 21E are plan views illustrating the structure of the 3D flash memory to explain the 3D flash memory manufacturing method illustrated in FIG. 20.

FIGS. 22A to 22E are sectional views illustrating the structure of the 3D flash memory illustrated in FIGS. 21A to 21E and correspond to sections taken along lines A-A′ in FIGS. 21A to 21E.

FIGS. 23A to 23E are sectional views illustrating the structure of the 3D flash memory illustrated in FIGS. 21A to 21E and correspond to sections taken along lines B-B′ in FIGS. 21A to 21E.

FIG. 24 is a flowchart illustrating a manufacturing method according to another embodiment in which a stack method is applied in addition to the gate first method to manufacture the 3D flash memory illustrated in FIGS. 2 and 3.

FIG. 25 is a flowchart illustrating a manufacturing method according to another embodiment in which the word line replacement method is applied to manufacture the 3D flash memory illustrated in FIGS. 2 and 3.

FIG. 26 is a flowchart illustrating a manufacturing method according to another embodiment in which a stack method is applied in addition to the word line replacement method to manufacture the 3D flash memory illustrated in FIGS. 2 and 3.

FIG. 27 is a plan view illustrating the structure of a 3D flash memory according to an embodiment.

FIG. 28 is a sectional view illustrating the structure of the 3D flash memory illustrated in FIG. 27, where FIG. 28 corresponds to a sectional view taken along line A-A′ in FIG. 27.

FIG. 29 is a plan view illustrating the structure of a 3D flash memory according to another embodiment.

FIG. 30 is a plan view illustrating the structure of a 3D flash memory according to another embodiment.

FIG. 31 is a flowchart illustrating a 3D flash memory manufacturing method according to an embodiment in which the gate first method is applied to manufacture the 3D flash memory illustrated in FIGS. 27 and 28.

FIGS. 32A to 32D are plan views illustrating the structure of the 3D flash memory to explain the 3D flash memory manufacturing method illustrated in FIG. 31.

FIGS. 33A to 33D are sectional views illustrating the structure of the 3D flash memory illustrated in FIGS. 32A to 32D and correspond to sections taken along lines A-A′ in FIGS. 32A to 32D.

FIGS. 34A to 34D are sectional views illustrating the structure of the 3D flash memory illustrated in FIGS. 32A to 32D and correspond to sections taken along lines B-B′ in FIGS. 32A to 32D.

FIG. 35 is a flowchart illustrating a 3D flash memory manufacturing method according to an embodiment in which a stack method is applied in addition to the gate first method to manufacture the 3D flash memory illustrated in FIGS. 27 and 28.

FIG. 36 is a flowchart illustrating a 3D flash memory manufacturing method according to an embodiment in which the word line replacement method is applied to manufacture the 3D flash memory illustrated in FIGS. 27 and 28.

FIG. 37 is a flowchart illustrating a 3D flash memory manufacturing method according to an embodiment in which a stack method is applied in addition to the word line replacement method to manufacture the 3D flash memory illustrated in FIGS. 27 and 28.

FIG. 38 is a schematic perspective view illustrating an electronic system including a 3D flash memory according to an embodiment.

### BEST MODE

Hereinafter, embodiments of the present disclosure will be described in detail with reference to the accompanying drawings. However, the present disclosure is not restricted or limited by the embodiments. In addition, the same reference numerals in the drawings indicate the same members.

Terminologies used in this specification are used to appropriately express the embodiments of the present disclosure and may be changed according to the intention of a viewer or operator or the custom in the field to which the present disclosure pertains. Therefore, the terminologies should be defined based on the contents throughout this specification. As used herein, the singular forms are intended to include the plural forms as well, unless context clearly indicates otherwise. It will be further understood that the terms “comprises” and/or “comprising”, when used in this specification, specify the presence of stated components, steps, operations, and/or elements, but do not preclude the presence or addition of one or more other components, steps, operations, and/or elements. In addition, although the terms such as first, second, etc. are used herein to describe various areas, directions, and shapes, these areas, directions, and shapes should not be limited by these terms. These terms are merely used to distinguish one area, direction or shape from another area, direction or shape. Accordingly, a part referred to as a first part in one embodiment may be referred to as a second part in another embodiment.

It should be understood that various embodiments of the present disclosure are different from one another, but need not be mutually exclusive. For example, specific shapes, structures and characteristics described herein may be implemented in other embodiments without departing from the spirit and scope of the present disclosure in connection with one embodiment.

In addition, it should be understood that in the presented embodiments, the positions, arrangements, or configurations of individual components may be changed without departing from the spirit and scope of the present disclosure.

Hereinafter, a 3D flash memory, a method of operating the same, and an electronic system including the same according to embodiments will be described in detail with reference to the accompanying drawings.

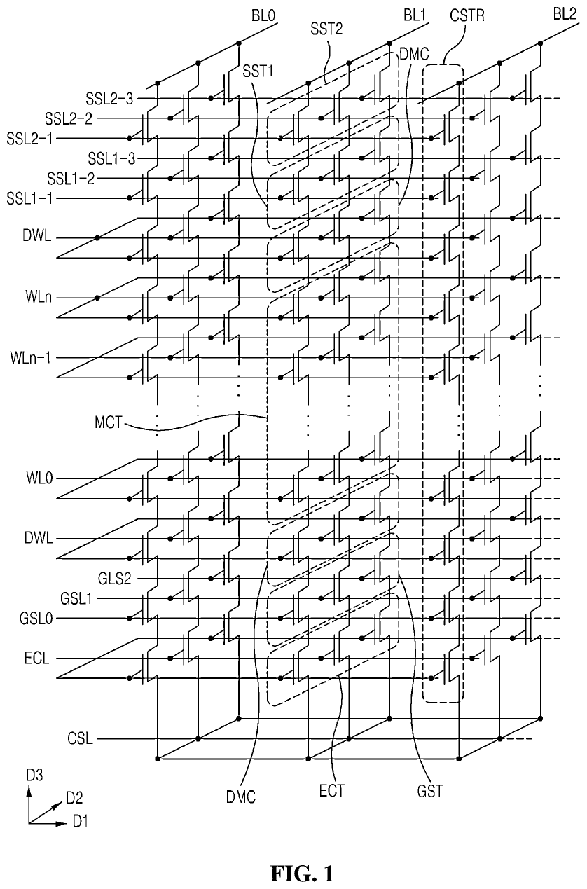

FIG. 1 is a schematic circuit diagram illustrating an array of a 3D flash memory according to an embodiment.

Referring to FIG. 1, the array of the 3D flash memory according to this embodiment may include a common source line CSL, a plurality of bit lines BL0, BL1, and BL2, and a plurality of cell strings CSTR disposed between the common source line CSL and the bit lines BL0, BL1, and BL2.

The bit lines BL0, BL1, and BL2 may extend in a second direction D2 and may be spaced apart from one another in a first direction D1 and arranged in two dimensions. Here, the first direction D1, the second direction D2, and the third direction D3 may be orthogonal to one another and may form a Cartesian coordinate system defined by the X, Y, and Z axes.

The plurality of cell strings CSTR may be connected to the bit lines BL0, BL1, and BL2 in parallel, respectively. The cell strings CSTR may be provided between the bit lines BL0, BL1, and BL2 and the common source line CSL and may be commonly connected to the common source line CSL. In this case, the common source line CSL may be provided in plural numbers, and the plurality of common source lines CSL may extend in the first direction D1 and may be spaced apart from one another in the second direction D2 and arranged in two dimensions. The same electrical voltage may be applied to the plurality of common source lines CSL. However, the present disclosure is not restricted or limited thereto. The plurality of common source lines CSL may be electrically independently controlled, and different voltages may be applied to the plurality of common source lines CSL.

The cell strings CSTR may extend in the third direction D3 and may be spaced apart from one another in the second direction D2 for the respective bit lines. According to an embodiment, each of the cell strings CSTR may be constituted by a ground selection transistor GST connected to the common source line CSL, first and second string selection transistors SST1 and SST2 connected to the bit lines BL0, BL1, and BL2 and connected in series, memory cell transistors MCT connected in series and disposed between the ground selection transistor GST and the first and second string selection transistors SST1 and SST2, and an erase control transistor ECT. In addition, each of the memory cell transistors MCT may include a data storage element.

For example, each of the cell strings CSTR may include the first and second string selection transistors SST1 and SST2 connected in series, and the second string selection transistor SST2 may be connected to one of the bit lines BL0, BL1, and BL2. However, without being restricted or limited thereto, each of the cell strings CSTR may include one string selection transistor. In another example, in each of the cell strings CSTR, similarly to the first and second string selection transistors SST1 and SST2, the ground selection transistor GST may be constituted by a plurality of MOS transistors connected in series.

One cell string CSTR may be constituted by the plurality of memory cell transistors MCT having different distances from the common source lines CSL. That is, the memory cell transistors MCT may be disposed between the first string selection transistor SST1 and the ground selection transistor GST in the third direction D3 and may be connected in series. The erase control transistor ECT may be connected between the ground selection transistor GST and the common source lines CSL. Each of the cell strings CSTR may further include a dummy cell transistor DMC connected between the first string selection transistor SST1 and the highest of the memory cell transistors MCT and a dummy cell transistor DMC connected between the ground selection transistor GST and the lowest of the memory cell transistors MCT.

According to an embodiment, the first string selection transistor SST1 may be controlled by first string selection lines SSL1-1, SSL1-2, and SSL1-3, and the second string selection transistor SST2 may be controlled by second string selection lines SSL2-1, SSL2-2, and SSL2-3. The memory cell transistors MCT may be controlled by a plurality of word lines WL0 to WLn, respectively, and the dummy cell transistors DMC may be controlled by dummy word lines DWL, respectively. The ground selection transistor GST may be controlled by ground selection lines GSL0, GSL1, and GSL2, and the erase control transistor ECT may be controlled by an erase control line ECL. The erase control transistor ECT may be provided in plural numbers. The common source lines CSL may be commonly connected to sources of the erase control transistors ECT.

Gate electrodes of the memory cell transistors MCT provided at substantially the same distance from the common source lines CSL may be commonly connected to one of the word lines WL0 to WLn and DWL and may be in an equipotential state. However, the present disclosure is not restricted or limited thereto, and even though the gate electrodes of the memory cell transistors MCT are provided at substantially the same level from the common source lines CSL, gate electrodes provided in different rows or columns may be independently controlled.

The ground selection lines GSL0, GSL1, and GSL2, the first string selection lines SSL1-1, SSL1-2, and SSL1-3, and the second string selection lines SSL2-1, SSL2-2, and SSL2-3 may extend in the first direction D1 and may be spaced apart from one another in the second direction D2 and arranged in two dimensions. The ground selection lines GSL0, GSL1, and GSL2, the first string selection lines SSL1-1, SSL1-2, and SSL1-3, and the second string selection lines SSL2-1, SSL2-2, and SSL2-3 provided at substantially the same level from the common source lines CSL may be electrically isolated from one another. In addition, the erase control transistors ECT of the different cell strings CSTR may be controlled by the common erase control line ECL. The erase control transistors ECT may generate gate induced drain leakage (GIDL) during an erase operation of a memory cell array. In some embodiments, during the erase operation of the memory cell array, an erase voltage may be applied to the bit lines BL0, BL1, and BL2 and/or the common source lines CSL, and a gate induced leakage current may be generated in the string selection transistors SST and/or the erase control transistors ECT.

The above-described string selection lines SSL may be expressed as upper selection lines USL, and the above-described ground selection lines GSL may be expressed as lower selection lines.

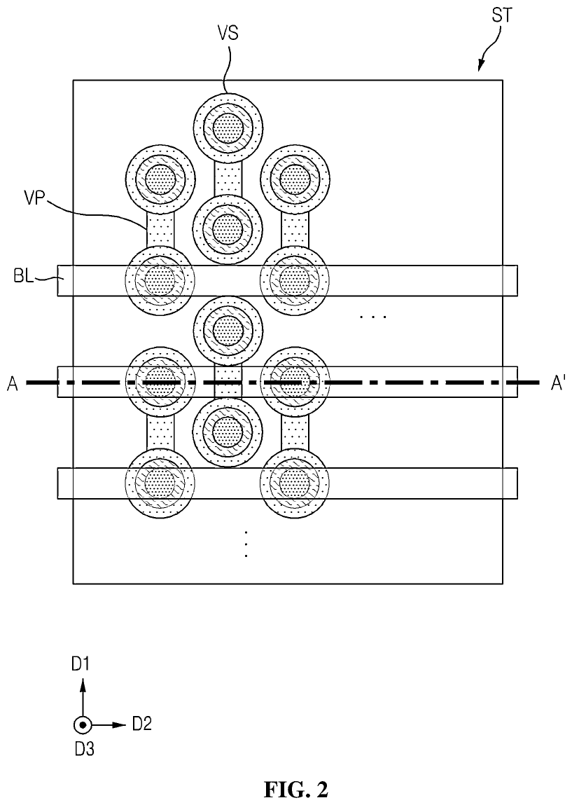

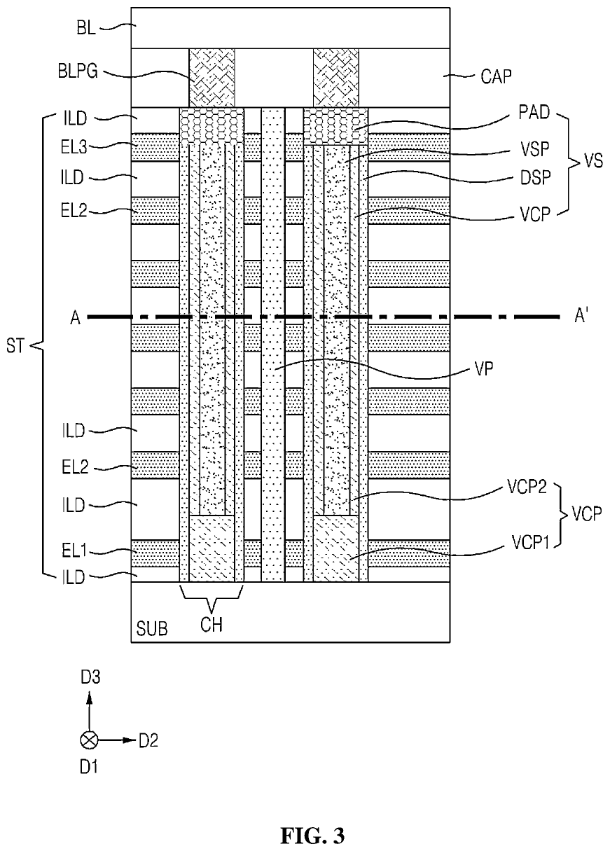

FIG. 2 is a plan view illustrating the structure of the 3D flash memory according to an embodiment, and FIG. 3 is a sectional view illustrating the structure of the 3D flash memory illustrated in FIG. 2, where FIG. 3 corresponds to a sectional view taken along line A-A′ in FIG. 2.

Referring to FIGS. 2 and 3, a substrate SUB may be a semiconductor substrate such as a silicon substrate, a silicon-germanium substrate, a germanium substrate, or a monocrystalline epitaxial layer grown on a monocrystalline silicon substrate. The substrate SUB may be doped with a first conductive type impurity (e.g., a P-type impurity).

Stack structures ST may be disposed on the substrate SUB. The stack structures ST may extend in the first direction D1 and may be two-dimensionally arranged in the second direction D2. In addition, the stack structures ST may be spaced apart from one another in the second direction D2.

Each of the stack structures ST may include gate electrodes EL1, EL2, and EL3 and interlayer insulating films ILD alternately stacked on the upper surface of the substrate SUB in a vertical direction (e.g., the third direction D3). The stack structures ST may have a substantially flat upper surface. That is, the upper surfaces of the stack structures ST may be parallel to the upper surface of the substrate SUB. Hereinafter, the vertical direction refers to the third direction D3 or the direction opposite to the third direction D3.

Referring again to FIG. 1, each of the gate electrodes EL1, EL2, and EL3 may be one of the erase control line ECL, the ground selection lines GSL0, GSL1, and GSL2, the word lines WL0 to WLn and DWL, the first string selection lines SSL1-1, SSL1-2, and SSL1-2, and the second string selection lines SSL2-1, SSL2-2, and SSL2-3 sequentially stacked on the substrate SUB.

The gate electrodes EL1, EL2, and EL3 may extend in the first direction D1 and may have substantially the same thickness in the third direction D3. Hereinafter, a thickness refers to a thickness in the third direction D3. Each of the gate electrodes EL1, EL2, and EL3 may be formed of a conductive material. For example, each of the gate electrodes EL1, EL2, and EL3 may include at least one selected from doped semiconductor (e.g., doped silicon), metal (e.g., tungsten (W), copper (Cu), aluminum (Al), titanium (Ti), tantalum (Ta), molybdenum (Mo), ruthenium (Ru), or gold (Au)), or conductive metal nitride (e.g., titanium nitride or tantalum nitride). Each of the gate electrodes EL1, EL2, and EL3 may include at least one of all metallic materials capable of being formed through ALD, in addition to the metallic materials described above.

More specifically, the gate electrodes EL1, EL2, and EL3 may include the first gate electrode EL1 at the bottom, the third gate electrode EL3 at the top, and the plurality of second gate electrodes EL2 between the first gate electrode EL1 and the third gate electrode EL3. Each of the first gate electrode EL1 and the third gate electrode EL3 is illustrated and described in a singular form. However, this is illustrative, and the present disclosure is not limited thereto. The first gate electrode EL1 and the third gate electrode EL3 may be provided in plural numbers as needed. The first gate electrode EL1 may correspond to one of the ground selection lines GSL0, GSL1, and GSL2 illustrated in FIG. 1. The second gate electrode EL2 may correspond to one of the word lines WL0 to WLn and DWL illustrated in FIG. 1. The third gate electrode EL3 may correspond to one of the first string selection lines SSL1-1, SSL1-2, and SSL1-3 illustrated in FIG. 1, or may correspond to one of the second string selection lines SSL2-1, SSL2-2, and SSL2-3 illustrated in FIG. 1.

Although not illustrated, an end portion of each of the stack structures ST may have a stepwise structure in the first direction D1. More specifically, the lengths of the gate electrodes EL1, EL2, and EL3 of the stack structures ST in the first direction D1 may be decreased farther away from the substrate SUB. The third gate electrode EL3 may have the smallest length in the first direction D1 and may have the greatest separation distance from the substrate SUB in the third direction D3. The first gate electrode EL1 may have the greatest length in the first direction D1 and may have the smallest separation distance from the substrate SUB in the third direction D3. Due to the stepwise structure, each of the stack structures ST may have a decreasing thickness farther away from the outermost one of vertical channel structures VS that will be described below, and sidewalls of the gate electrodes EL1, EL2, and EL3 may be spaced apart from one another at certain intervals in the first direction D1 when viewed in the plan view.

The interlayer insulating films ILD may have different thicknesses. For example, among the interlayer insulating films ILD, the lowermost and uppermost interlayer insulating films ILD may have thicknesses smaller than those of the other interlayer insulating films ILD. However, this is illustrative, and the present disclosure is not limited thereto. The interlayer insulating films ILD may have different thicknesses depending on the characteristics of a semiconductor device, or may have the same thickness. The interlayer insulating films ILD may be formed of an insulating material for the purpose of insulation between the gate electrodes EL1, EL2, and EL3. For example, the interlayer insulating films ILD may be formed of silicon oxide.

A plurality of channel holes CH may be formed through the stack structures ST and a portion of the substrate SUB. The vertical channel structures VS may be provided in the channel holes CH. The vertical channel structures VS may correspond to the plurality of cell strings CSTR illustrated in FIG. 1. The vertical channel structures VS may be connected to the substrate SUB and may extend in the third direction D3. The connection of the vertical channel structures VS to the substrate SUB may be achieved by bringing the lower surfaces of portions of the vertical channel structures VS into contact with the upper surface of the substrate SUB. However, without being restricted or limited thereto, the connection of the vertical channel structures VS to the substrate SUB may be achieved by embedding the portions of the vertical channel structures VS in the substrate SUB. When the portions of the vertical channel structures VS are embedded in the substrate SUB, the lower surfaces of the vertical channel structures VS may be located at a lower level than the upper surface of the substrate SUB.

A plurality of columns of vertical channel structures VS may penetrate one of the stack structures ST. For example, as illustrated in FIG. 2, columns of three vertical channel structures VS may penetrate one of the stack structures ST. However, without being restricted or limited thereto, columns of two vertical channel structures VS may penetrate one of the stack structures ST, or columns of four or more vertical channel structures VS may penetrate one of the stack structures ST. In a pair of columns adjacent to each other, vertical channel structures VS corresponding to one column may be shifted in the first direction D1 from vertical channel structures VS corresponding to the other column adjacent to the one column. The vertical channel structures VS may be arranged in zigzags in the first direction D1 when viewed in the plan view. However, without being restricted or limited thereto, the vertical channel structures VS may be arranged side by side in rows and columns to form an array.

In particular, at least two of the vertical channel structures VS may be paired and may be connected with each other on a horizontal plane through at least one vertical connecting pattern VP to form a peanut shape as illustrated in the drawing.

Each of the vertical channel structures VS may extend from the substrate SUB in the third direction D3. In the drawing, the vertical channel structure VS is illustrated as having a pillar shape in which the lower and upper ends have the same width. However, without being restricted or limited thereto, the vertical channel structure VS may have a shape in which the widths in the first direction D1 and the second direction D2 are increased in the third direction D3. The upper surface of the vertical channel structure VS may have a circular shape, an oval shape, a quadrangular shape, or a bar shape.

Each of the vertical channel structures VS may include a data storage pattern DSP, a vertical channel pattern VCP, a vertical semiconductor pattern VSP, and a conductive pad PAD. In the vertical channel structure VS, the data storage pattern DSP may have a pipe or macaroni shape in which the lower end is open, and the vertical channel pattern VCP may have a pipe or macaroni shape in which the lower end is closed. The vertical semiconductor pattern VSP may fill the space surrounded by the vertical channel pattern VCP and the conductive pad PAD.

The data storage pattern DSP may cover the inner wall of the channel hole CH. The inside of the data storage pattern DSP may surround the outer wall of the vertical channel pattern VCP, and the outside of the data storage pattern DSP may make contact with the sidewalls of the gate electrodes EL1, EL2, and EL3. Accordingly, areas of the data storage pattern DSP that correspond to the second gate electrodes EL2, together with areas of the vertical channel pattern VCP that correspond to the second gate electrodes EL2, may constitute memory cells in which a memory operation (e.g., a program operation, a read operation, or an erase operation) is performed by a voltage applied through the second gate electrodes EL2. The memory cells correspond to the memory cell transistors MCT illustrated in FIG. 1. That is, the data storage pattern DSP may serve as data storage in the 3D flash memory by trapping charges or holes due to the voltage applied through the second gate electrodes EL2 or maintaining the state of the charges (e.g., the polarization state of the charges). For example, an ONO (tunnel oxide film (Oxide)-charge storage film (Nitride)-blocking oxide film (Oxide)) layer or a ferroelectric layer may be used as the data storage pattern DSP. The data storage pattern DSP may represent a binary data value or a multi-level data value due to a change in the trapped charges or holes, or may represent a binary data value or a multi-level data value due to a change in the state of the charges.

The vertical channel pattern VCP may cover the inner wall of the data storage pattern DSP. The vertical channel pattern VCP may include a first part VCP1 and a second part VCP2 on the first part VCP1.

The first part VCP1 of the vertical channel pattern VCP may be provided in a lower portion of the channel hole CH and may make contact with the substrate SUB. The first part VCP1 of the vertical channel pattern VCP may be used to block, suppress, or minimize leakage current in the vertical channel structure VS and/or may be used as an epitaxial pattern. For example, the thickness of the first part VCP1 of the vertical channel pattern VCP may be greater than the thickness of the first gate electrode EL1. The sidewall of the first part VCP1 of the vertical channel pattern VCP may be surrounded by the data storage pattern DSP. The upper surface of the first part VCP1 of the vertical channel pattern VCP may be located at a higher level than the upper surface of the first gate electrode EL1. More specifically, the upper surface of the first part VCP1 of the vertical channel pattern VCP may be located between the upper surface of the first gate electrode EL1 and the lower surface of the lowermost one of the second gate electrodes EL2. The lower surface of the first part VCP1 of the vertical channel pattern VCP may be located at a lower level than the top surface of the substrate SUB (that is, the lower surface of the lowermost one of the interlayer insulating films ILD). A portion of the first part VCP1 of the vertical channel pattern VCP may overlap the first gate electrode EL1 in a horizontal direction. Hereinafter, the horizontal direction refers to any one direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2. Accordingly, as described above, the second part VCP2 of the vertical channel pattern VCP may constitute the memory cells together with the areas of the data storage pattern DSP that correspond to the second gate electrodes EL2.

The upper surface of the second part VCP2 of the vertical channel pattern VCP may be substantially coplanar with the upper surface of the vertical semiconductor pattern VSP. The upper surface of the second part VCP2 of the vertical channel pattern VCP may be located at a higher level than the upper surface of the uppermost one of the second gate electrodes EL2. More specifically, the upper surface of the second part VCP2 of the vertical channel pattern VCP may be located between the upper and lower surfaces of the third gate electrode EL3.

The vertical channel pattern VCP may be a component that transfers charges or holes to the data storage pattern DSP. The vertical channel pattern VCP may be formed of monocrystalline silicon or polycrystalline silicon and may form a channel, or may be boosted, by an applied voltage. However, without being restricted or limited thereto, the vertical channel pattern VCP may be formed of an oxide semiconductor material capable of blocking, suppressing, or minimizing leakage current. For example, the vertical channel pattern VCP may be formed of an oxide semiconductor material containing at least one of In, Zn, or Ga with excellent leakage current characteristics or a group IV semiconductor material. For example, the vertical channel pattern VCP may be formed of a ZnOx-based material including AZO, ZTO, IZO, ITO, IGZO, or Ag—ZnO. Accordingly, the vertical channel pattern VCP may block, suppress, or minimize leakage current to the gate electrodes EL1, EL2, and EL3 or the substrate SUB and may improve transistor characteristics (e.g., threshold voltage distribution and the speed of program/read operations) of at least one of the gate electrodes EL1, EL2, and EL3. Thus, the vertical channel pattern VCP may improve electrical characteristics of the 3D flash memory.

The vertical semiconductor pattern VSP may be surrounded by the second part VCP2 of the vertical channel pattern VCP. The upper surface of the vertical semiconductor pattern VSP may make contact with the conductive pad PAD, and the lower surface of the vertical semiconductor pattern VSP may make contact with the first part VCP1 of the vertical channel pattern VCP. The vertical semiconductor pattern VSP may be spaced apart from the substrate SUB in the third direction D3. In other words, the vertical semiconductor pattern VSP may be electrically floated from the substrate SUB.

The vertical semiconductor pattern VSP may be formed of a material that helps diffusion of charges or holes in the vertical channel pattern VCP. In more detail, the vertical semiconductor pattern VSP may be formed of a material with excellent charge and hole mobility. For example, the vertical semiconductor pattern VSP may be formed of a semiconductor material doped with an impurity, an intrinsic semiconductor material that is not doped with an impurity, or a polycrystalline semiconductor material. In a more specific example, the vertical semiconductor pattern VSP may be formed of polycrystalline silicon doped with the same first conductive type impurity (e.g., a P-type impurity) as that of the substrate SUB. That is, the vertical semiconductor pattern VSP may improve the speed of a memory operation by improving the electrical characteristics of the 3D flash memory.

Referring again to FIG. 1, the vertical channel structures VS may correspond to channels of the erase control transistor ECT, the first and second string selection transistors SST1 and SST2, the ground selection transistor GST, and the memory cell transistors MCT.

The conductive pad PAD may be provided on the upper surface of the second part VCP2 of the vertical channel pattern VCP and the upper surface of the vertical semiconductor pattern VSP. The conductive pad PAD may be connected with the upper portion of the vertical channel pattern VCP and the upper portion of the vertical semiconductor pattern VSP. The sidewall of the conductive pad PAD may be surrounded by the data storage pattern DSP. The upper surface of the conductive pad PAD may be substantially coplanar with the upper surface of each of the stack structures ST (that is, the upper surface of the uppermost one of the interlayer insulating films ILD). The lower surface of the conductive pad PAD may be located at a lower level than the upper surface of the third gate electrode EL3. More specifically, the lower surface of the conductive pad PAD may be located between the upper surface and the lower surface of the third gate electrode EL3. That is, at least a portion of the conductive pad PAD may overlap the third gate electrode EL3 in the horizontal direction.

The conductive pad PAD may be formed of a semiconductor or conductive material doped with an impurity. For example, the conductive pad PAD may be formed of a semiconductor material doped with an impurity different from that of the vertical semiconductor pattern VSP (more precisely, an impurity of a second conductive type (e.g., N-type) different from the first conductive type (e.g., P-type)).

The conductive pad PAD may reduce contact resistance between a bit line BL to be described below and the vertical channel pattern VCP (or, the vertical semiconductor pattern VSP).

Although it has been described that the vertical channel structures VS include the conductive pad PAD, the present disclosure is not restricted or limited thereto, and the vertical channel structures VS may have a structure from which the conductive pad PAD is omitted. Since the conductive pad PAD is omitted from the vertical channel structures VS in this case, the vertical channel pattern VCP and the vertical semiconductor pattern VSP may extend in the third direction D3 such that the upper surfaces of the vertical channel pattern VCP and the vertical semiconductor pattern VSP are substantially coplanar with the upper surface of each of the stack structures ST (that is, the upper surface of the uppermost one of the interlayer insulating films ILD). In addition, in this case, a bit line contact plug BLPG to be described below may be electrically connected with the vertical channel pattern VCP through direct contact therebetween instead of being indirectly electrically connected with the vertical channel pattern VCP through the conductive pad PAD.

Although it has been described that the vertical semiconductor pattern VSP is included in the vertical channel structures VS, the present disclosure is not restricted or limited thereto, and the vertical semiconductor pattern VSP may be omitted.

Although it has been described that the vertical channel pattern VCP includes the first part VCP1 and the second part VCP2, the present disclosure is not restricted or limited thereto, and the vertical channel pattern VCP may have a structure from which the first part VCP1 is excluded. For example, the vertical channel pattern VCP may be provided between the vertical semiconductor pattern VSP extending to the substrate SUB and the data storage pattern DSP and may extend to the substrate SUB to make contact with the substrate SUB. In this case, the lower surface of the vertical channel pattern VCP may be located at a lower level than the top surface of the substrate SUB (the lower surface of the lowermost one of the interlayer insulating films ILD), and the upper surface of the vertical channel pattern VCP may be substantially coplanar with the upper surface of the vertical semiconductor pattern VSP.

The at least one vertical connecting pattern VP may connect the vertical channel structures VS to each other on the horizontal plane and may extend in the vertical direction (e.g., the third direction D3). When the at least one vertical connecting pattern VP connects the vertical channel structures VS to each other on the horizontal plane, this means that the at least one vertical connecting pattern VP connects the entire side surfaces of the vertical channel structures VS to each other.

In this case, the at least one vertical connecting pattern VP may be simultaneously formed with the vertical channel structures VS through the same process. In more detail, the at least one vertical connecting pattern VP may be simultaneously formed through the process in which the data storage patterns DSP of the vertical channel structures VS are formed. Accordingly, the at least one vertical connecting pattern VP may be formed of only the data storage pattern DSP. For example, when the data storage patterns DSP of the vertical channel structures VS are implemented with an ONO layer, the at least one vertical connecting pattern VP may be formed of a charge storage film (Nitride) and a blocking oxide film (Oxide) of the ONO layer.

Under the condition that the at least one vertical connecting pattern VP has a size larger than the minimum limit size of at least one vertical connecting trench VT that smoothly introduces an etching gas into the channel holes CH to be described below, the at least one vertical connecting pattern VP may have a size L2 smaller than the size L1 of each of the vertical channel structures VS on the horizontal plane, and thus the area occupied by the at least one vertical connecting pattern VP in the 3D flash memory may be minimized.

The size L2 at which the at least one vertical connecting pattern VP is formed may be determined to be a value that satisfies the condition in which channels of the vertical channel structures VS connected by the at least one vertical connecting pattern VP are not connected together. That is, the at least one vertical connecting pattern VP may have the size L2 that satisfies the condition that the at least one vertical connecting pattern VP is formed of only the data storage patterns DSP. For example, when an ONO layer is used as the data storage pattern DSP, the at least one vertical connecting pattern VP may have the size L2 of 35 nm or less by which the ONO layer having a thickness of 16 nm is able to be deposited on both inner walls, such that the at least one vertical connecting pattern VP is formed of only the ONO layer.

Since the at least one vertical connecting pattern VP has the small size L2 as described above, the vertical channel structures VS may maintain a gate all around (GAA) structure, and field characteristics applied to the cell string CSTR may also be maintained the same as those of the GAA structure.

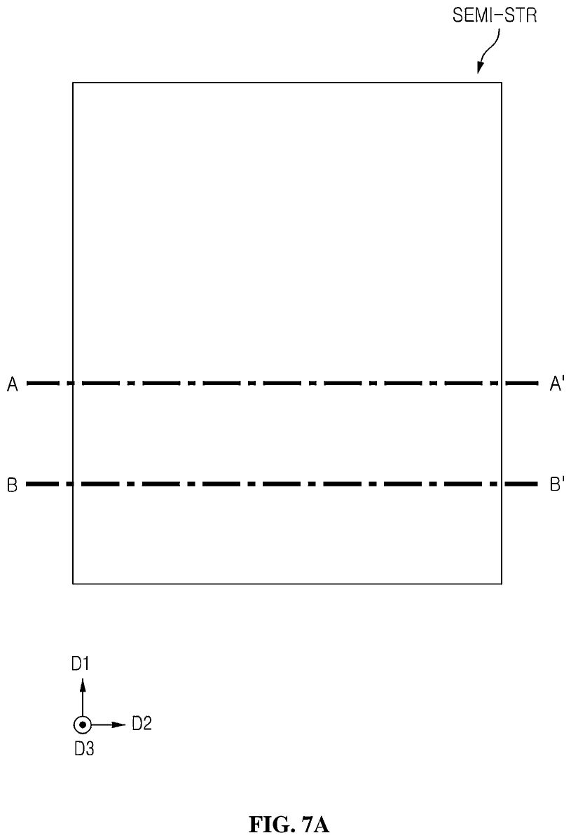

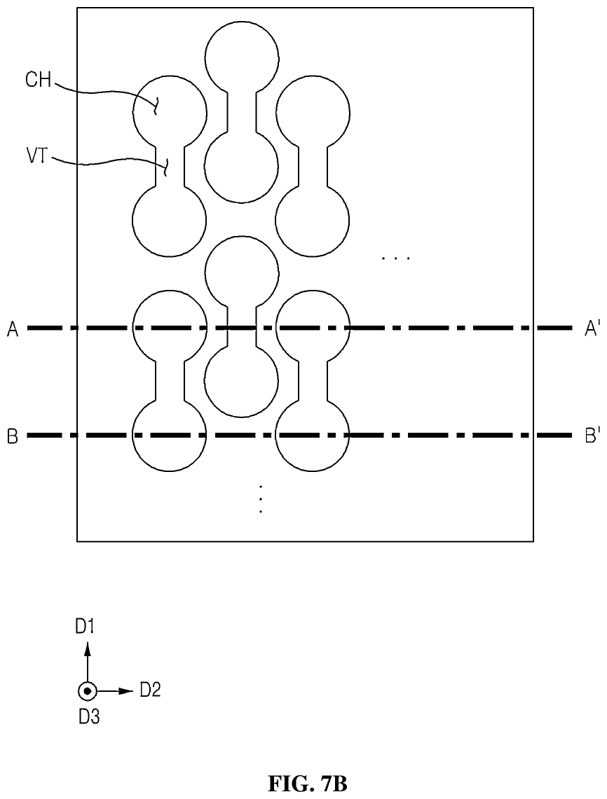

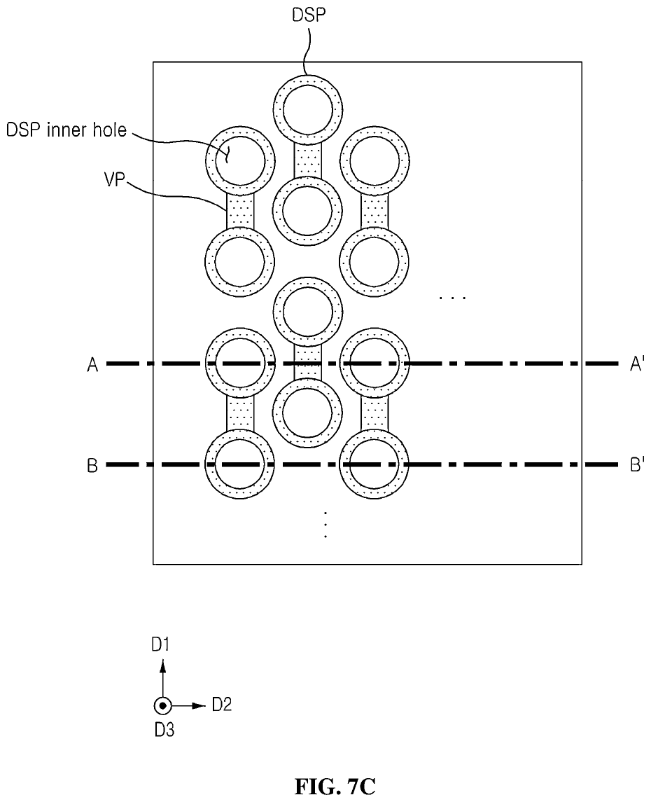

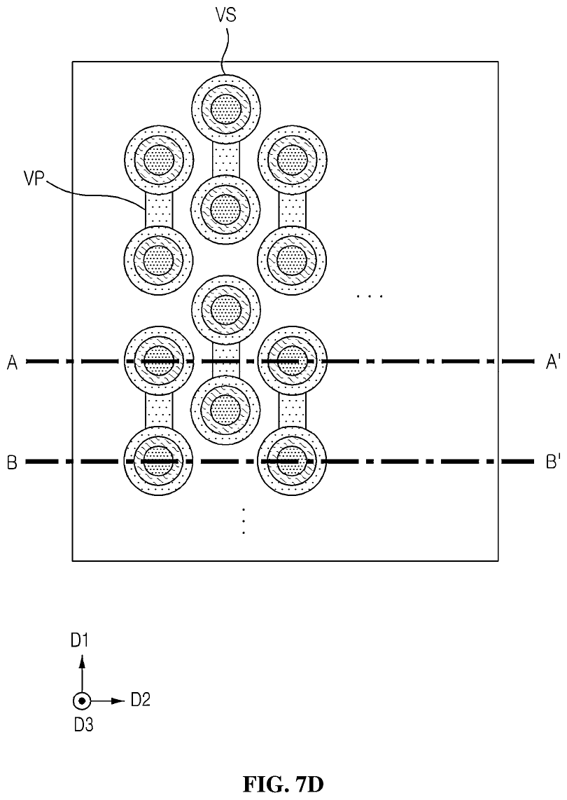

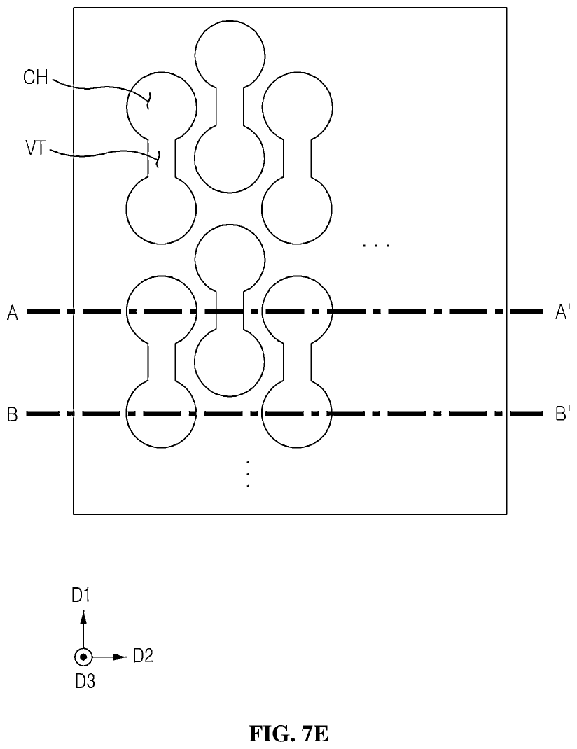

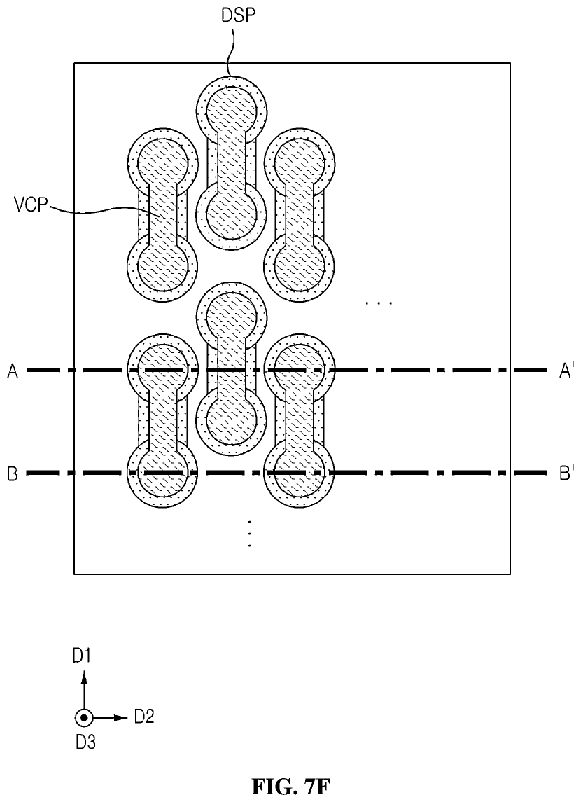

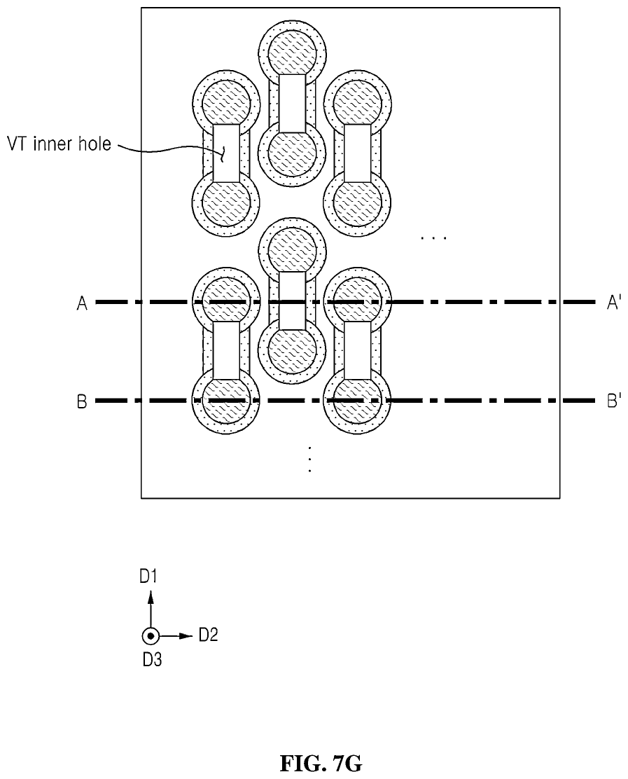

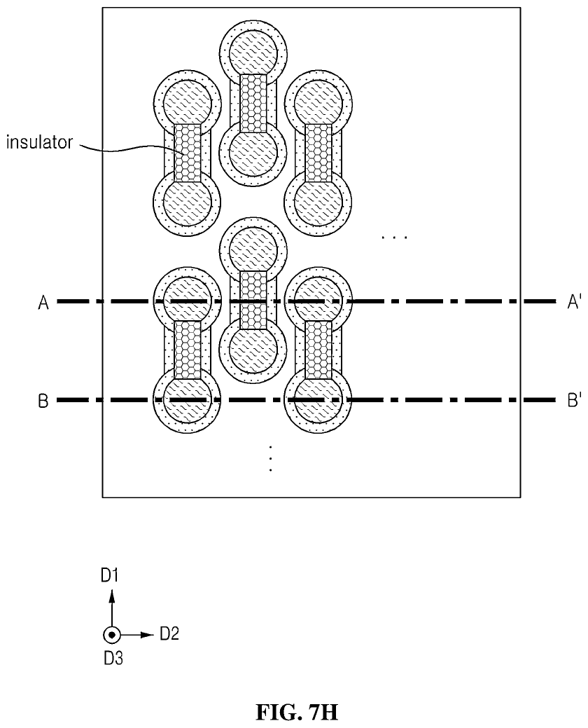

However, without being restricted or limited thereto, the at least one vertical connecting pattern VP may have a size similar to the size L1 of each of the vertical channel structures VS. In this case, additional etching and filling processes may be required such that a channel is not included in the at least one vertical connecting pattern VP. Detailed description thereabout will be given below with reference to FIGS. 7E to 7H, 8E to 8H, and 9E to 9H.

The at least one vertical connecting pattern VP may be used as the at least one vertical connecting trench VT that introduces the etching gas into the channel holes CH in a process of etching the channel holes CH, in which the vertical channel structures VS are formed, before the inside is filled. Accordingly, an etching profile may be secured through the at least one vertical connecting trench VT.

As described above, the at least one vertical connecting pattern VP extending in the at least one vertical connecting trench VT may be simultaneously formed with the vertical channel structures VS extending in the channel holes CH through the same process (the data storage patterns DSP deposited in the channel holes CH may be buried in the at least one vertical connecting trench VT to form the at least one vertical connecting pattern VP). Accordingly, the filling process of the at least one vertical connecting trench VT may be simplified.

The at least one vertical connecting pattern VP may not only connect two vertical channel structures VS included in one column as illustrated in the drawing, but may also connect three or more vertical channel structures VS included in one column.

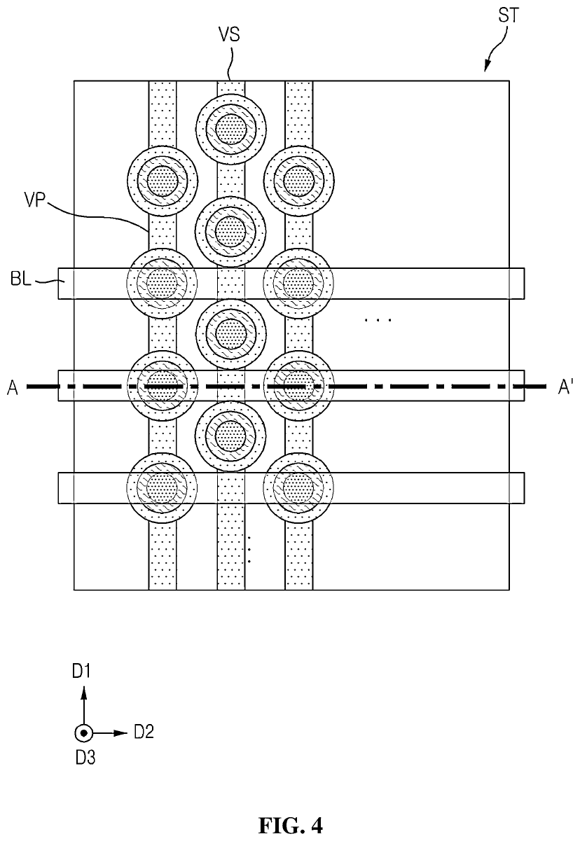

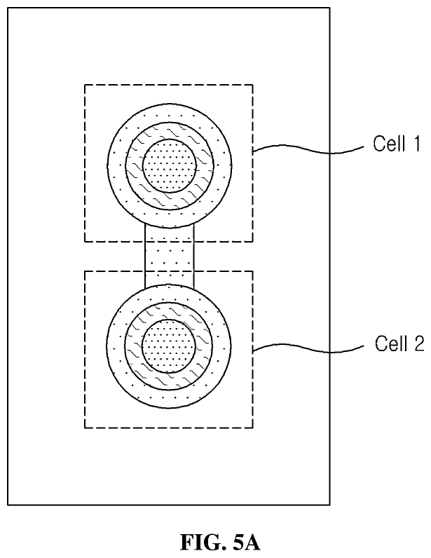

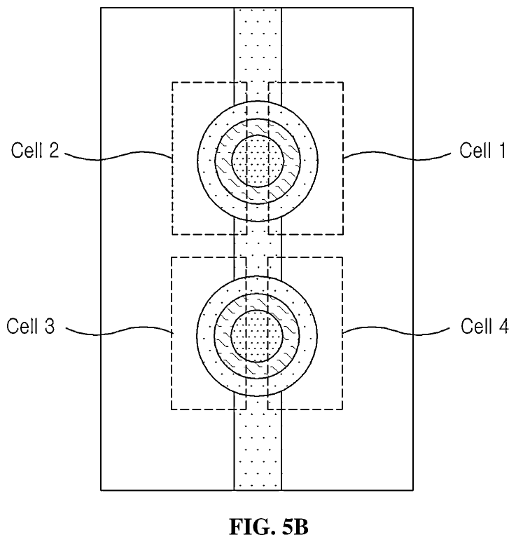

The at least one vertical connecting pattern VP may be formed to connect all vertical channel structures VS included in one column and may divide the word lines WL0-WLn on the horizontal plane. This is to improve the influence of a fringing field due to the large area of the word lines WL0 to WL of the 3D flash memory and implement a multi-level cell. Detailed description thereabout will be given below with reference to FIGS. 4, 5A, and 5B.

The at least one vertical connecting pattern VP may connect two or more vertical channel structures VS included in different columns. That is, the at least one vertical connecting pattern VP may connect at least two vertical channel structures VS on the horizontal plane irrespective of the rows of the vertical channel structures VS.

Although not illustrated in the drawing, an isolation trench TR extending in the first direction D1 may be provided between the stack structures ST adjacent to each other. A common source area CSR may be provided inside the substrate SUB exposed by the isolation trench TR. The common source area CSR may extend in the first direction D1 inside the substrate SUB. The common source area CSR may be formed of a semiconductor material doped with the second conductive type impurity (e.g., an N-type impurity). The common source area CSR may correspond to the common source line CSL of FIG. 1.

A common source plug CSP may be provided in the isolation trench TR. The common source plug CSP may be connected with the common source area CSR. The upper surface of the common source plug CSP may be substantially coplanar with the upper surface of each of the stack structures ST (that is, the upper surface of the uppermost one of the interlayer insulating films ILD). The common source plug CSP may have a plate shape extending in the first direction D1 and the third direction D3. In this case, the common source plug CSP may have a shape in which the width in the second direction D2 is increased in the third direction D3.

Insulating spacers SP may be interposed between the common source plug CSP and the stack structures ST. The insulating spacers SP may be provided between the adjacent stack structures ST to face each other. For example, the insulating spacers SP may be formed of silicon oxide, silicon nitride, silicon oxy nitride, or a low-k material having a low dielectric constant.

A capping insulating film CAP may be provided on the stack structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected with the conductive pad PAD may be provided inside the capping insulating film CAP. The bit line contact plug BLPG may have a shape in which the widths in the first direction D1 and the second direction D2 are increased in the third direction D3.

The bit line BL may be provided on the capping insulating film CAP and the bit line contact plug BLPG. The bit line BL may correspond to one of the plurality of bit lines BL0, BL1, and BL2 illustrated in FIG. 1. The bit line BL may be formed of a conductive material and may extend in the second direction D2. The conductive material constituting the bit line BL may be the same material as the conductive material that forms each of the gate electrodes EL1, EL2, and EL3 described above.

The bit line BL may be electrically connected with the vertical channel structures VS through the bit line contact plug BLPG. When the bit line BL is connected with the vertical channel structures VS, this may mean that the bit line BL is connected with the vertical channel patterns VCP included in the vertical channel structures VS.

The 3D flash memory having the above-described structure may perform a program operation, a read operation, and an erase operation, based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL. For example, the 3D flash memory may perform a program operation by forming a channel in the vertical channel pattern VCP and transferring charges or holes to the data storage pattern DSP of a target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Without being restricted or limited to the described structure, the 3D flash memory may be implemented in various structures on the premise that the 3D flash memory includes the vertical channel pattern VCP, the data storage pattern DSP, the at least one vertical connecting pattern VP, the gate electrodes EL1, EL2, and EL3, the bit line BL, and the common source line CSL.

For example, the 3D flash memory may be implemented in a structure that includes a back gate BG instead of the vertical semiconductor pattern VSP making contact with the inner wall of the vertical channel pattern VCP. In this case, the back gate BG may be at least partially surrounded by the vertical channel pattern VCP to apply a voltage for a memory operation to the vertical channel pattern VCP. The back gate BG may be formed of a conductive material including at least one selected from doped semiconductor (e.g., doped silicon), metal (e.g., tungsten (W), copper (Cu), aluminum (Al), titanium (Ti), tantalum (Ta), molybdenum (Mo), ruthenium (Ru), or gold (Au)), or conductive metal nitride (e.g., titanium nitride or tantalum nitride) and may extend in the vertical direction (e.g., the third direction D3).

FIG. 4 is a plan view illustrating the structure of a 3D flash memory according to another embodiment, and FIGS. 5A and 5B are plan views for explaining implementation of a multi-level cell by the structure of the 3D flash memory illustrated in FIG. 4.

Referring to FIG. 4, the 3D flash memory according to the other embodiment is the same as the 3D flash memory described with reference to FIGS. 2 and 3, differing only in that only the at least one vertical connecting pattern VP has a different structure.

More specifically, in the 3D flash memory according to the other embodiment, the at least one vertical connecting pattern VP may connect all vertical channel structures VS included in one column and may extend in a horizontal direction (e.g., the first direction D1) to divide word lines WL0 to WLn on a horizontal plane.

Accordingly, the 3D flash memory described with reference to FIGS. 2 and 3 may implement 2 bits of data using two vertical channel structures VS as two memory cells as illustrated in FIG. 5A, whereas the 3D flash memory according to the other embodiment may implement 4 bits of data using two vertical channel structures VS as four memory cells as illustrated in FIG. 5B, thereby achieving a multi-level cell.

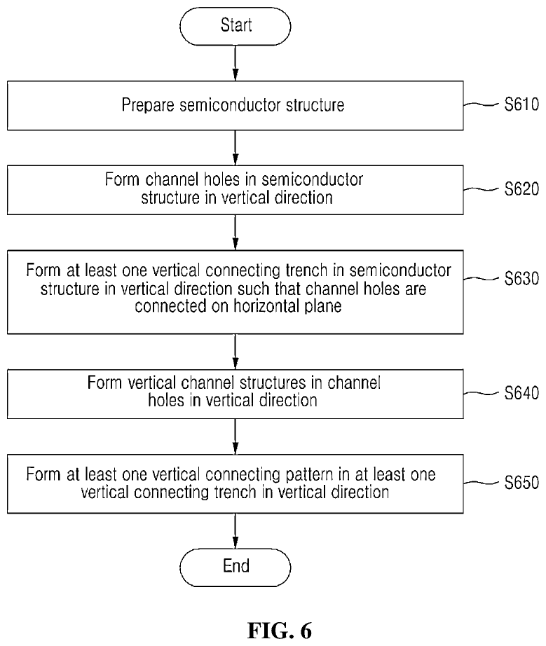

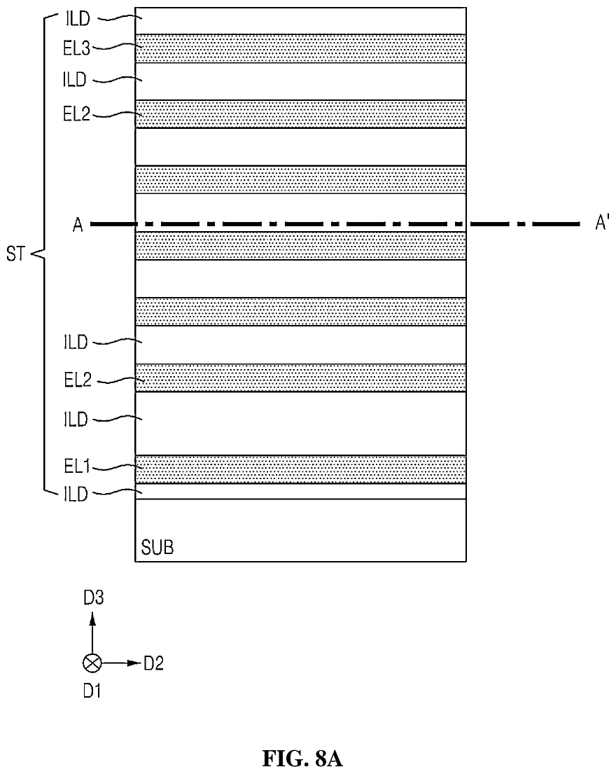

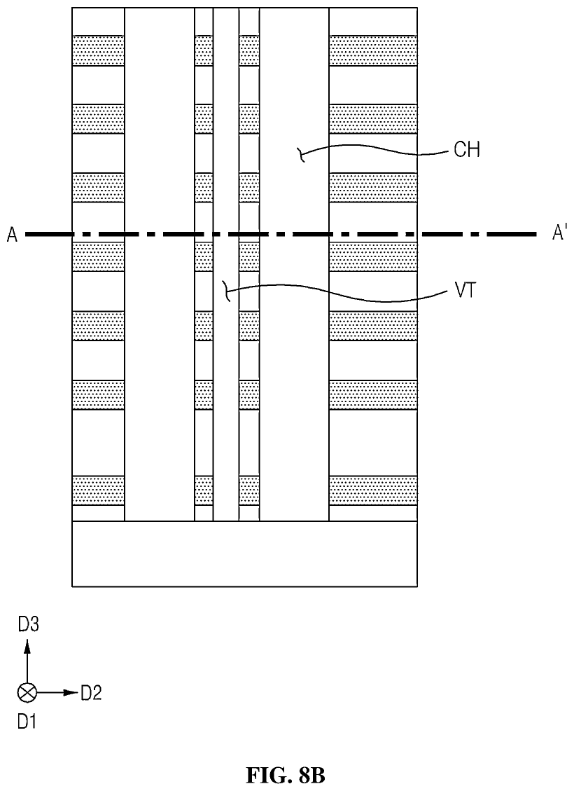

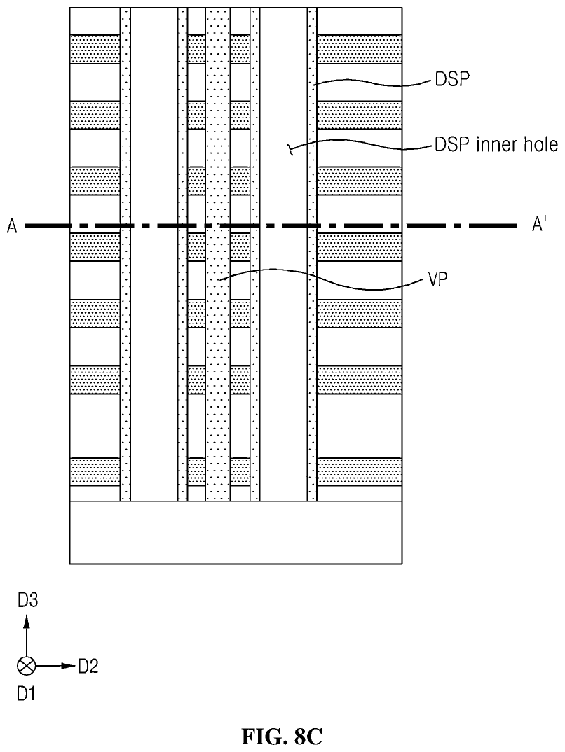

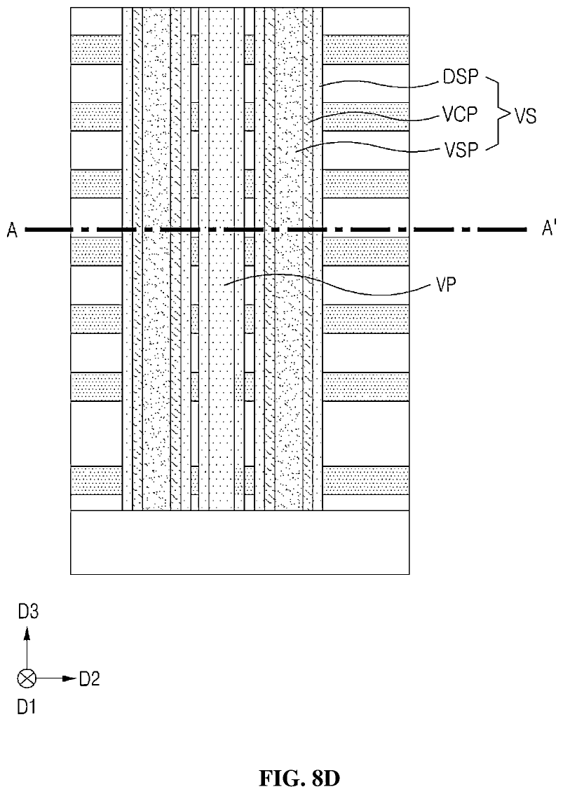

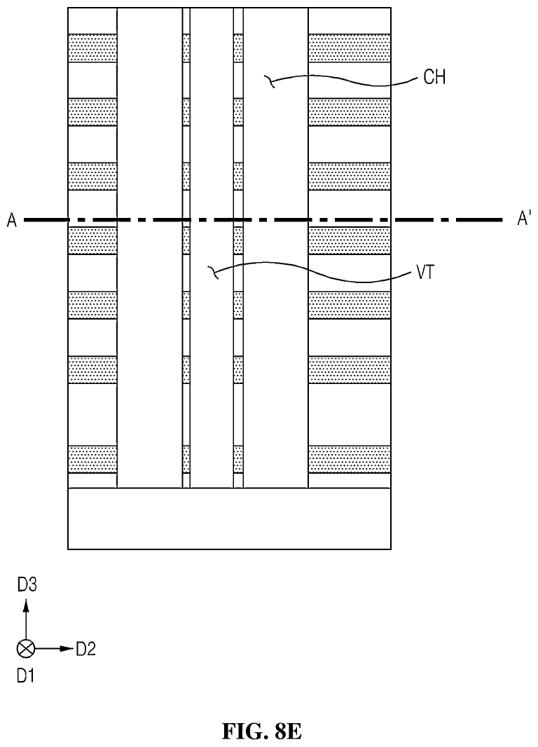

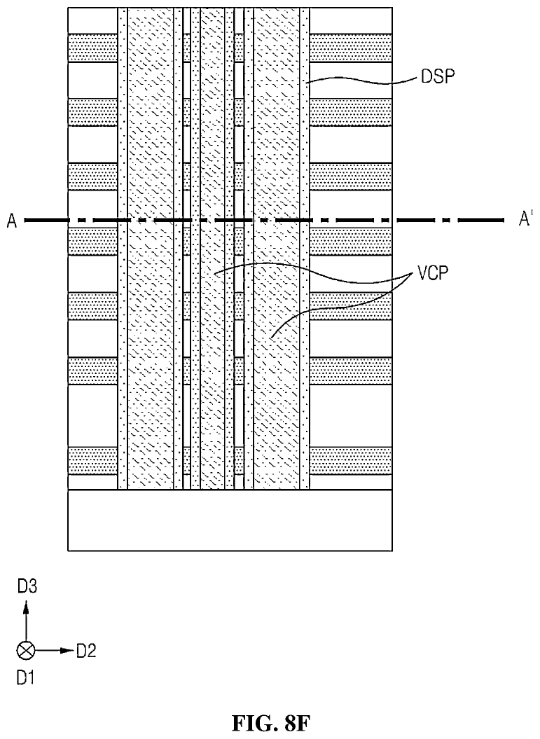

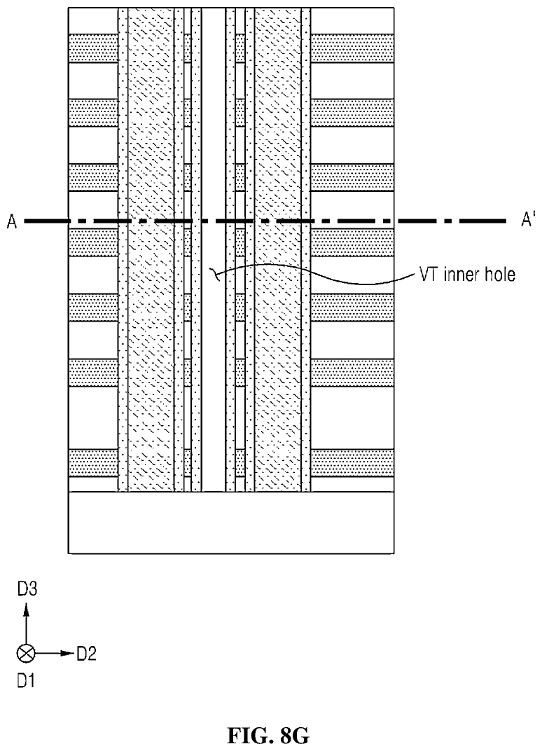

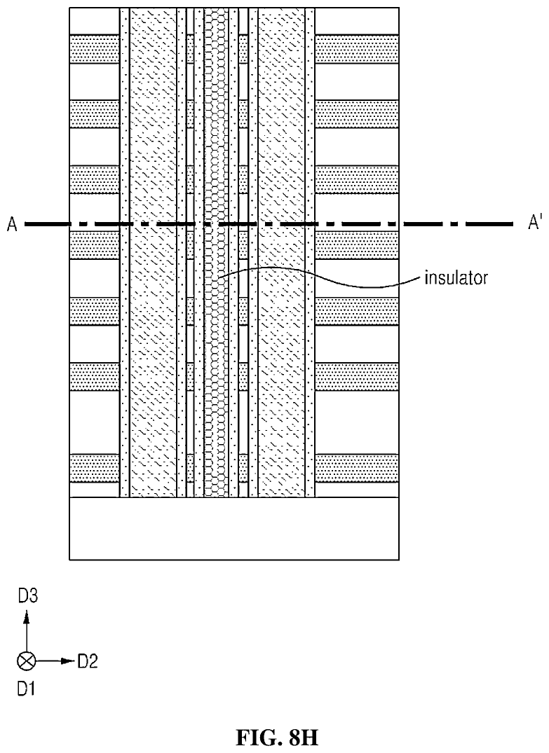

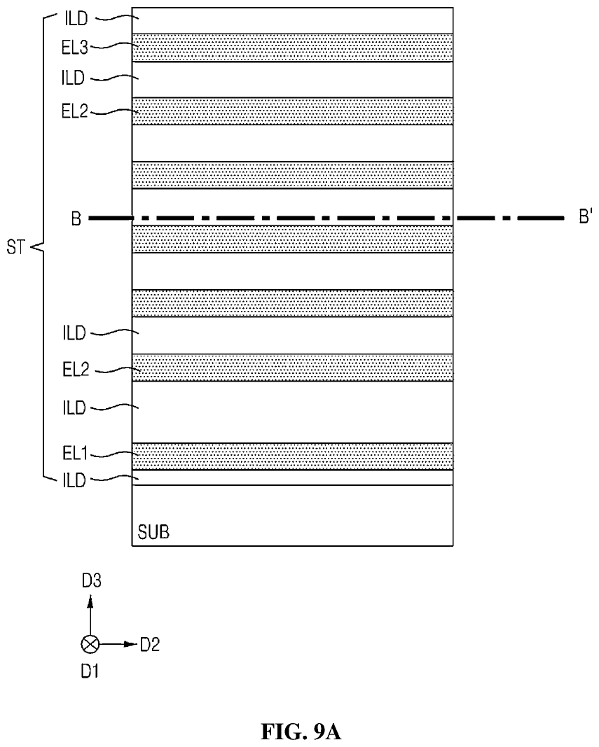

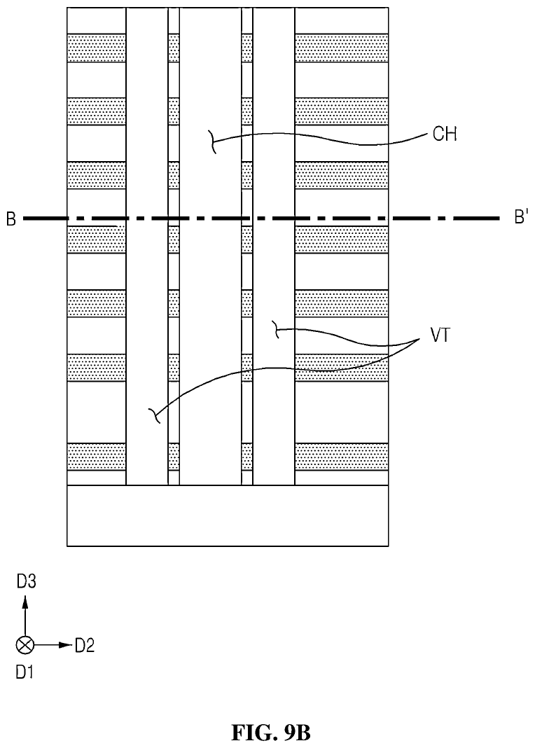

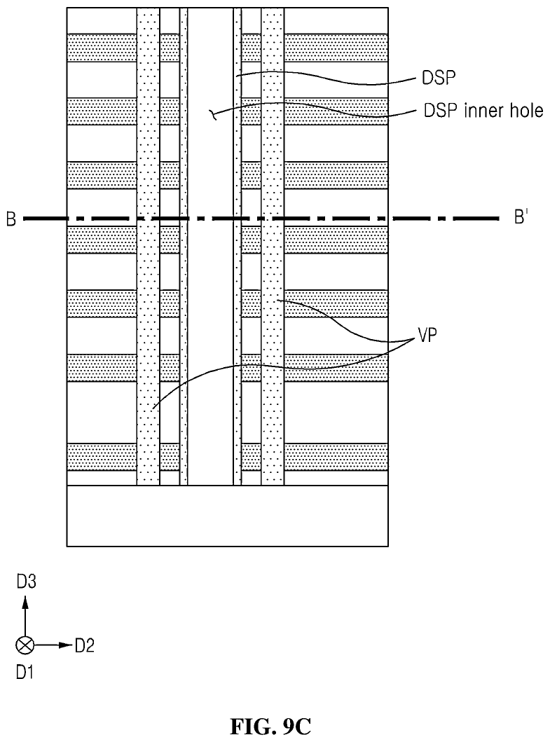

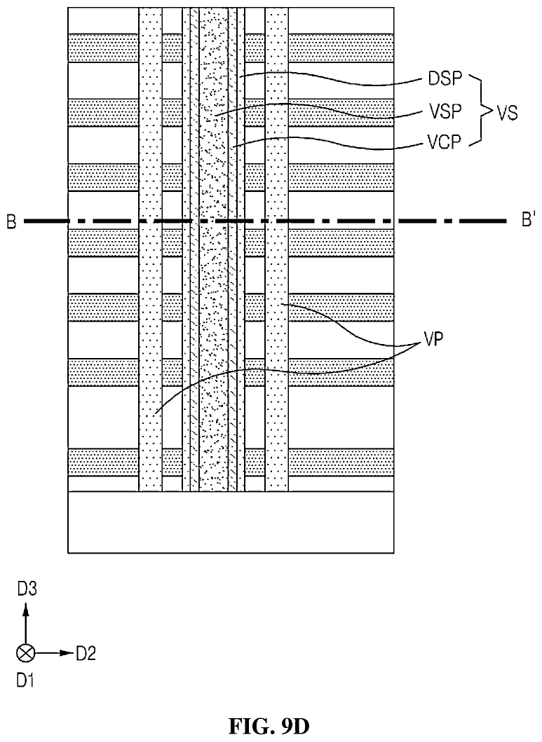

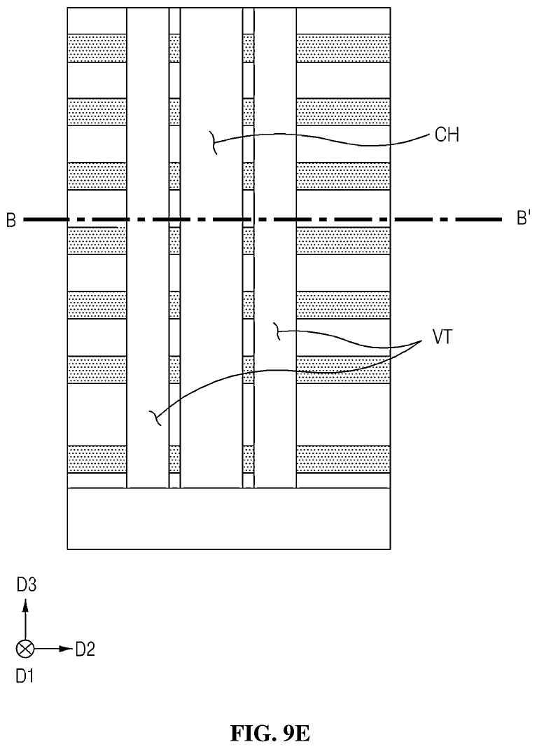

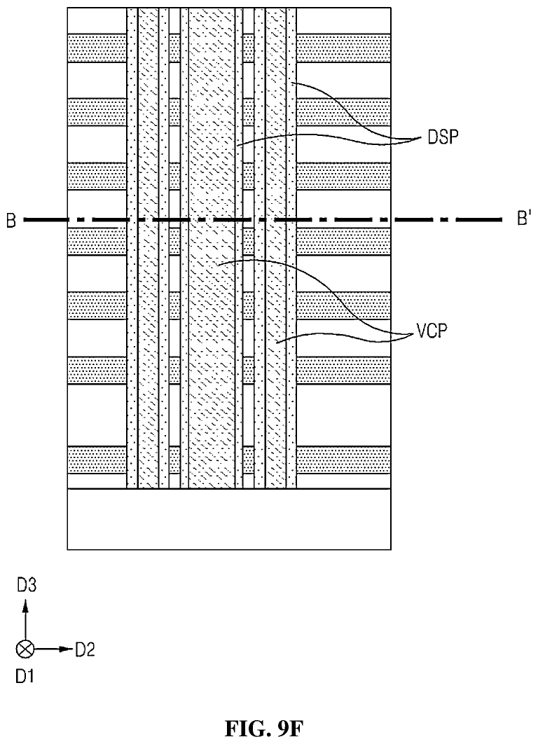

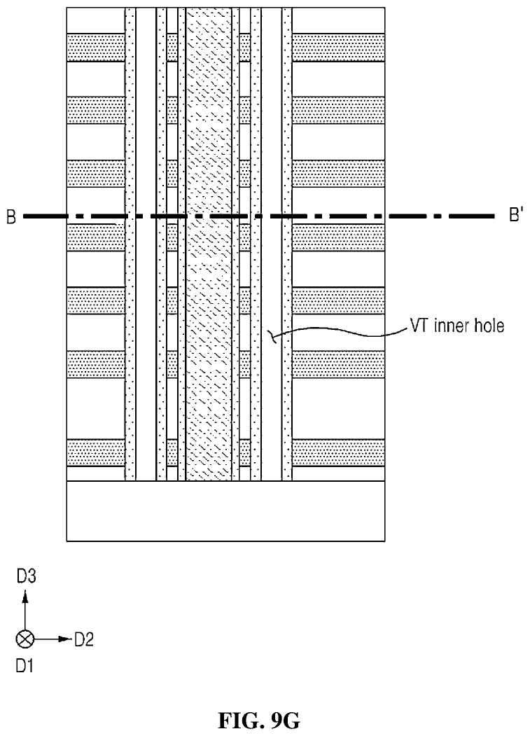

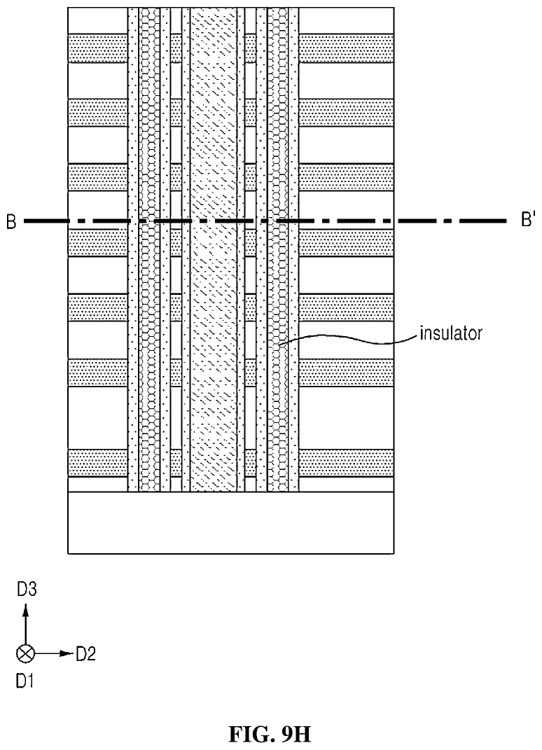

FIG. 6 is a flowchart illustrating a 3D flash memory manufacturing method according to an embodiment. FIGS. 7A to 7H are plan views illustrating the structure of the 3D flash memory to explain the 3D flash memory manufacturing method illustrated in FIG. 6. FIGS. 8A to 8H are sectional views illustrating the structure of the 3D flash memory illustrated in FIG. 6 and correspond to sections taken along lines A-A′ in FIGS. 7A to 7H. FIGS. 9A to 9H are sectional views illustrating the structure of the 3D flash memory illustrated in FIG. 6 and correspond to sections taken along lines B-B′ in FIGS. 7A to 7H.

The 3D flash memory manufacturing method according to this embodiment is for manufacturing the 3D flash memory having the structure described with reference to FIGS. 2 and 3 and is assumed to be performed by an automated and mechanized manufacturing system. However, without being restricted or limited thereto, the 3D flash memory manufacturing method according to this embodiment may be used to manufacture the 3D flash memory having the structure described with reference to FIG. 4.

Hereinafter, for convenience of description, the 3D flash memory manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S610, as illustrated in FIGS. 7A, 8A, and 9A, the manufacturing system may prepare a semiconductor structure SEMI-STR including the interlayer insulating films ILD and the word lines WL0 to WLn that extend in the horizontal direction (e.g., the second direction D2) and that are alternately stacked in the vertical direction (e.g., the third direction D3).

In step S620, the manufacturing system may form the channel holes CH in the semiconductor structure SEMI-STR in the vertical direction (e.g., the third direction D3).

In step S630, the manufacturing system may form the at least one vertical connecting trench VT in the semiconductor structure SEMI-STR in the vertical direction (e.g., the third direction D3) such that the channel holes CH are connected together on the horizontal plane.

At this time, in step S630, the manufacturing system may form the at least one vertical connecting trench VT having a size smaller than the size of each of the channel holes CH on the horizontal plane. Accordingly, the vertical channel structures VS formed in step S640 to be described below may maintain the gate all around (GAA) structure, and field characteristics applied to the cell string CSTR may be maintained the same as those of the GAA structure.

However, without being restricted or limited thereto, the at least one vertical connecting channel VT may be formed to have a size similar to the size of each of the channel holes CH. Detailed description thereabout will be given below.

In step S630, the manufacturing system may form the at least one vertical connecting trench VT to connect the channel holes CH and divide the word lines WL0 to WLn on the horizontal plane, thereby implementing a multi-level cell while improving the influence of the fringing field due to the large area of the word lines WL0 to WLn.

In particular, as illustrated in FIGS. 7B, 8B, and 9B, step S620 and step S630 may be simultaneously performed through the same process. That is, etching the channel holes CH and etching the at least one vertical connecting trench VT may be simultaneously performed through a single process. Accordingly, the etching gas may be smoothly introduced into the channel holes CH through the at least one vertical connecting trench VT, and thus the etching profile may be secured.

In step S640, the manufacturing system may form the vertical channel structures VS, each of which includes the data storage pattern DSP and the vertical channel pattern VCP, in the channel holes CH in the vertical direction (e.g., the third direction D3).

In more detail, step S640 may include a first step of forming the data storage pattern DSP on the inner wall of each of the channel holes CH as illustrated in FIGS. 7C, 8C, and 9C and a second step of forming the vertical channel pattern VCP on the inner wall of the data storage pattern DSP as illustrated in FIGS. 7D, 8D, and 9D (the vertical semiconductor pattern VSP is also formed together with the vertical channel pattern VCP).

In step S650, the manufacturing system may form the at least one vertical connecting pattern VP in the at least one vertical connecting trench VT in the vertical direction (e.g., the third direction D3).

Here, as illustrated in FIGS. 7C, 8C, and 9C, step S640 and step S650 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S650 may be a step of forming the at least one vertical connecting pattern VP with the data storage pattern DSP as the first step of step S640 is performed, and thus simplification of the process of filling the at least one vertical connecting trench VT may be achieved.

Although it has been described that the at least one vertical connecting trench VT is formed to have a size smaller than the size of each of the channel holes CH so that the at least one vertical connecting pattern VP is formed of only the data storage pattern DSP, the manufacturing system may form the at least one vertical connecting trench VT in a size similar to the size of each of the channel holes CH such that the at least one vertical connecting pattern VP further includes a buried film in addition to the data storage pattern DSP.

In more detail, in step S620 and step S630, as illustrated in FIGS. 7E, 8E, and 9E, the manufacturing system may form the channel holes CH and the at least one vertical connecting trench VT in the vertical direction (e.g., the third direction D3) in similar sizes on the horizontal plane.

Accordingly, in step S640 and S650, as illustrated in FIGS. 7F, 8F, and 9F, the manufacturing system may form the data storage pattern DSP and the vertical channel pattern VCP in the channel holes CH and the at least one vertical connecting trench VT.

Although not illustrated as a separate step in FIG. 6, as illustrated in FIGS. 7G, 8G, and 9G, the manufacturing system may remove the vertical channel pattern VCP formed in the at least one vertical connecting trench VT. This is because when the vertical channel pattern VCP remains in the at least one vertical connecting trench VT and the at least one vertical connecting pattern VP includes the vertical channel pattern VCP, the vertical channel structures VS are connected by the channel and are not able to be used as independent memory cells.

Thereafter, although not illustrated as a separate step in FIG. 6, as illustrated in FIGS. 7H, 8H, and 9H, the manufacturing system may form a buried film in the space where the vertical channel pattern VCP is removed in the at least one vertical connecting trench VT. At this time, the buried film may be formed of an insulating material to prevent the vertical channel structures VS from being connected through a channel.

Although not illustrated in the drawing, in each of the vertical channel structures VS, the vertical semiconductor pattern VSP may be formed in the vertical channel pattern VCP.

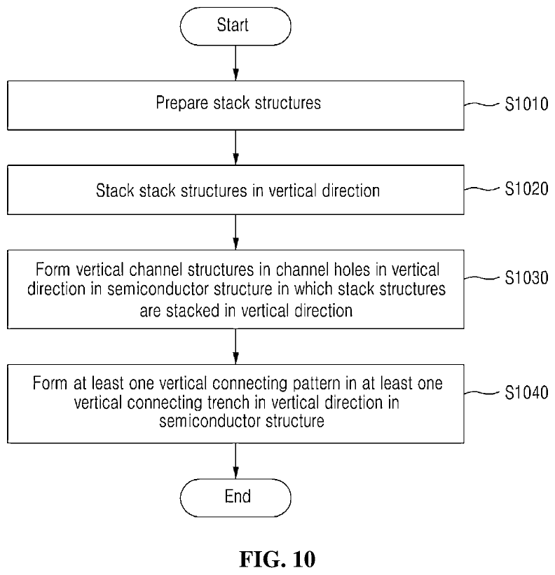

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 10.

FIG. 10 is a flowchart illustrating a 3D flash memory manufacturing method according to another embodiment.

The 3D flash memory manufacturing method according to the other embodiment is for manufacturing the 3D flash memory having the structure described with reference to FIGS. 2 and 3 and is assumed to be performed by an automated and mechanized manufacturing system. However, without being restricted or limited thereto, the 3D flash memory manufacturing method according to the other embodiment may be used to manufacture the 3D flash memory having the structure described with reference to FIG. 4.

Hereinafter, for convenience of description, the 3D flash memory manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S1010, the manufacturing system may prepare stack structures ST-STR, each of which includes the interlayer insulating films ILD and the word lines WL0 to WLn that extend in the horizontal direction (e.g., the second direction D2) and that are alternately stacked in the vertical direction (e.g., the third direction D3), the channel holes CH penetrating the interlayer insulating films ILD and the word lines WL0 to WLn in the vertical direction (e.g., the third direction D3), and the at least one vertical connecting trench VT penetrating the interlayer insulating films ILD and the word lines WL0 to WLn in the vertical direction (e.g., the third direction D3) such that the channel holes CH are connected together on the horizontal plane.

In each of the stack structures ST-STR prepared in step S1010, the at least one vertical connecting trench VT may be formed to have a size smaller than the size of each of the channels CH on the horizontal plane. Accordingly, the vertical channel structures VS formed in step S1030 to be described below may maintain the gate all around (GAA) structure, and field characteristics applied to the cell string CSTR may be maintained the same as those of the GAA structure.

However, without being restricted or limited thereto, the at least one vertical connecting channel VT may be formed to have a size similar to the size of each of the channel holes CH. Detailed description thereabout has been made above and therefore will be omitted.

In each of the stack structures ST-STR prepared in step S1010, the at least one vertical connecting trench VT may be formed to connect the channel holes CH and divide the word lines WL0 to WLn on the horizontal plane. Accordingly, the influence of the fringing field due to the large area of the word lines WL0 to WLn may be improved, and a multi-level cell may be implemented.

In particular, in each of the stack structures ST-STR prepared in step S1010, the channel holes CH and the at least one vertical connecting trench VT may be simultaneously formed through the same process. That is, etching the channel holes CH and etching the at least one vertical connecting trench VT may be simultaneously performed through a single process. Accordingly, the etching gas may be smoothly introduced into the channel holes CH through the at least one vertical connecting trench VT, and thus the etching profile may be secured.

In step S1020, the manufacturing system may stack the stack structures ST-STR in the vertical direction (e.g., the third direction D3).

In step S1030, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S1030 may include a first step of forming the data storage pattern DSP on the inner wall of each of the channel holes CH and a second step of forming the vertical channel pattern VCP on the inner wall of the data storage pattern DSP.

In step S1040, the manufacturing system may form the at least one vertical connecting pattern VP in the at least one vertical connecting trench VT in the vertical direction (e.g., the third direction D3) in the semiconductor structure SEMI-STR.

Here, step S1030 and step S1040 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S1040 may be a step of forming the at least one vertical connecting pattern VP with the data storage pattern DSP as the first step of step S1030 is performed, and thus simplification of the process of filling the at least one vertical connecting trench VT may be achieved.

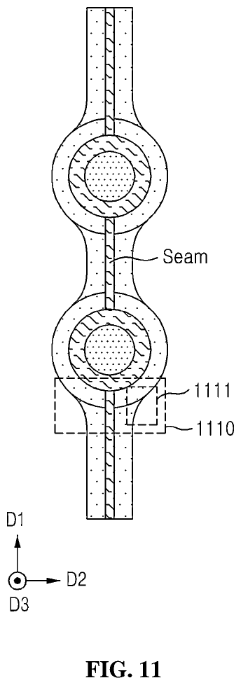

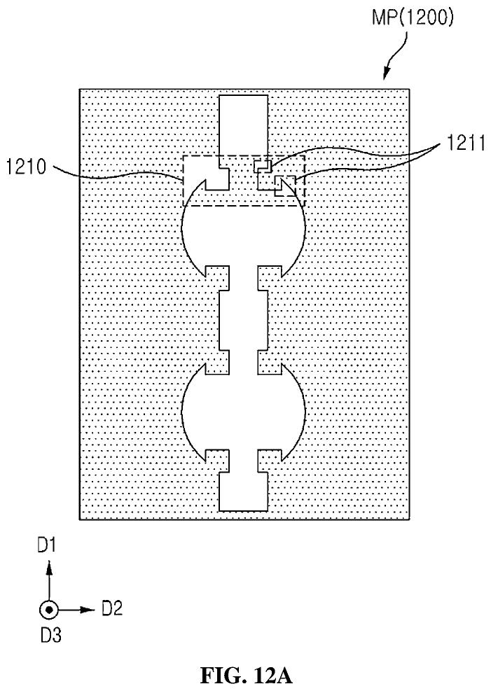

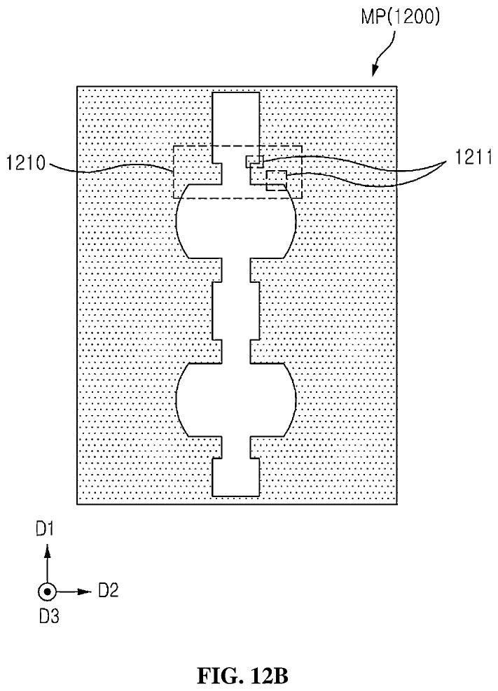

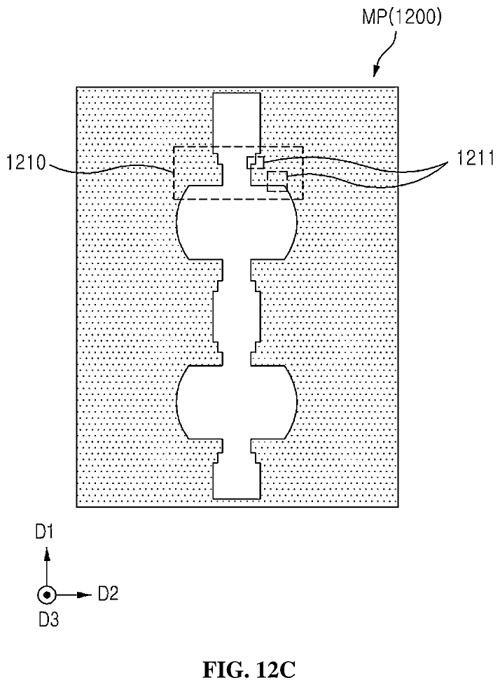

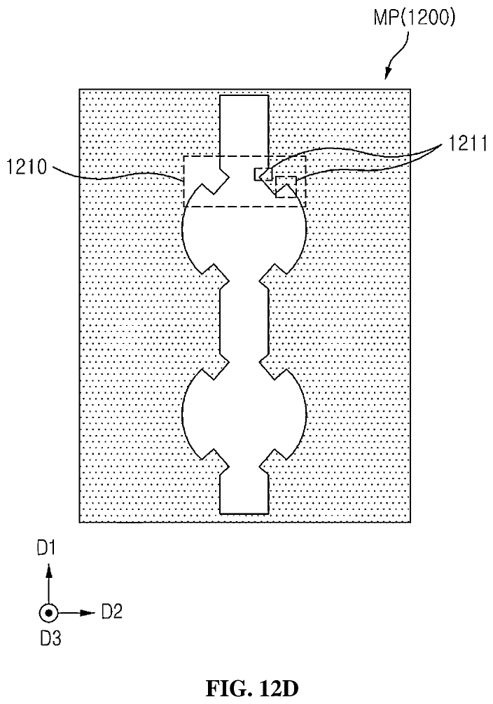

FIG. 11 is a plan view illustrating a 3D flash memory having a structure in which a rounded portion is included in an edge where at least one vertical connecting pattern is brought into contact with each of vertical channel structures, and FIGS. 12A to 12D are plan views illustrating mask patterns used in the process of manufacturing the 3D flash memory illustrated in FIGS. 2 and 3.

When a mask pattern used to form the vertical channel structures VS and the at least one vertical connecting pattern VP to manufacture the 3D flash memory having the above-described structure is implemented in the shape of the peanut structure described above, as illustrated in FIG. 11, the 3D flash memory manufactured with the corresponding mask includes a rounded portion 1111 at an edge 1110 where the at least one vertical connecting pattern VP is brought into contact with each of the vertical channel structures VS.

Since the rounded portion 1111 causes a seam to be generated within the at least one vertical connecting pattern VP in the process of forming the at least one vertical connecting pattern VP, the seam may also be filled with the material constituting the vertical channel pattern VCP in the process of forming the vertical channel pattern VCP of each of the vertical channel structures VS, and therefore a short circuit may occur.

To prevent the seam from being generated within the at least one vertical connecting pattern VP, a mask pattern has to be used to prevent the rounded portion 1111 from being included in the edge 1110 where the at least one vertical connecting pattern VP is brought into contact with each of the vertical channel structures VS.

As illustrated in FIGS. 12A to 12D, a mask pattern 1200 used to form the vertical channel structures VS and the at least one vertical connecting pattern VP of the 3D flash memory illustrated in FIGS. 2 and 3 may include a serif-shaped portion 1211 in an area 1210 corresponding to the edge where the at least one vertical connecting pattern VP is brought into contact with each of the vertical channel structures VS. Accordingly, in the at least one vertical connecting pattern VP and the vertical channel structures VS formed through the corresponding mask pattern 1200, a rounded portion may not be included in the edge.

That is, the mask pattern 1200 is characterized by including the serif-shaped portion 1211 considering optical proximity correction (OPC) during use.

Hereinafter, a method of manufacturing the 3D flash memory having the structure illustrated in FIGS. 2 and 3 using the mask pattern 1200 described above will be described.

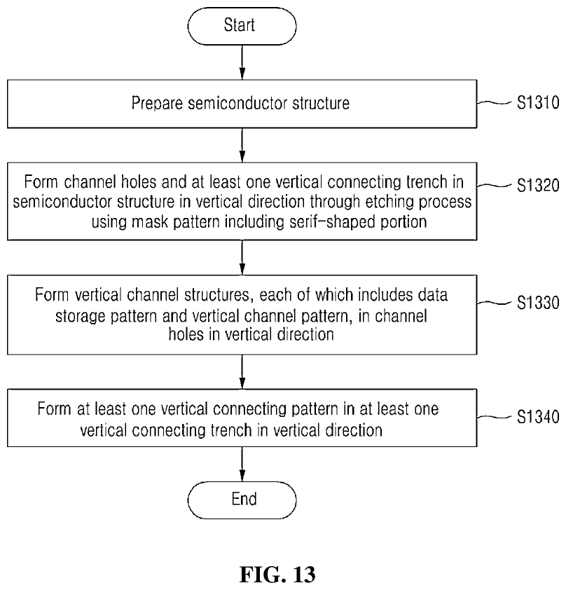

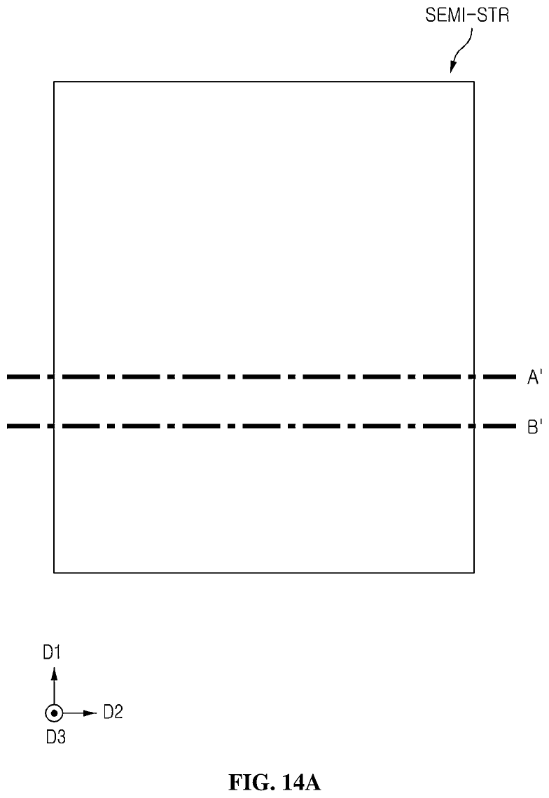

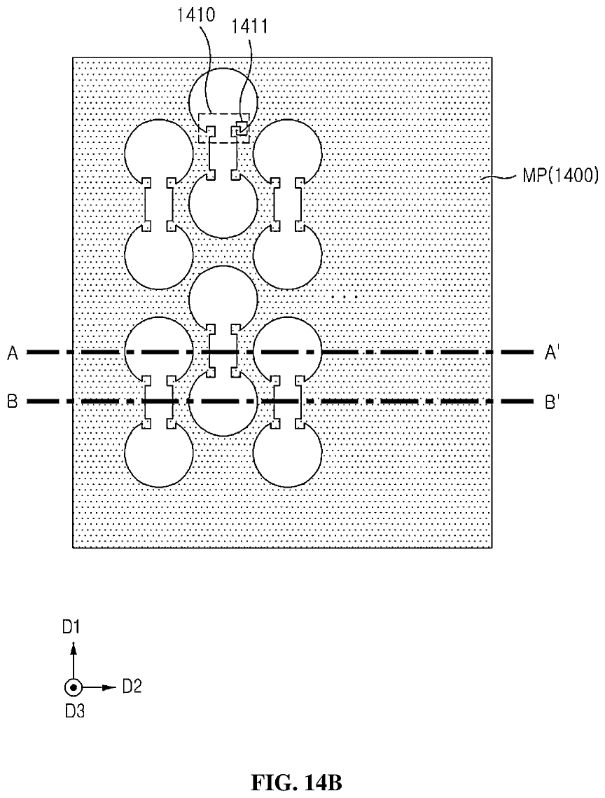

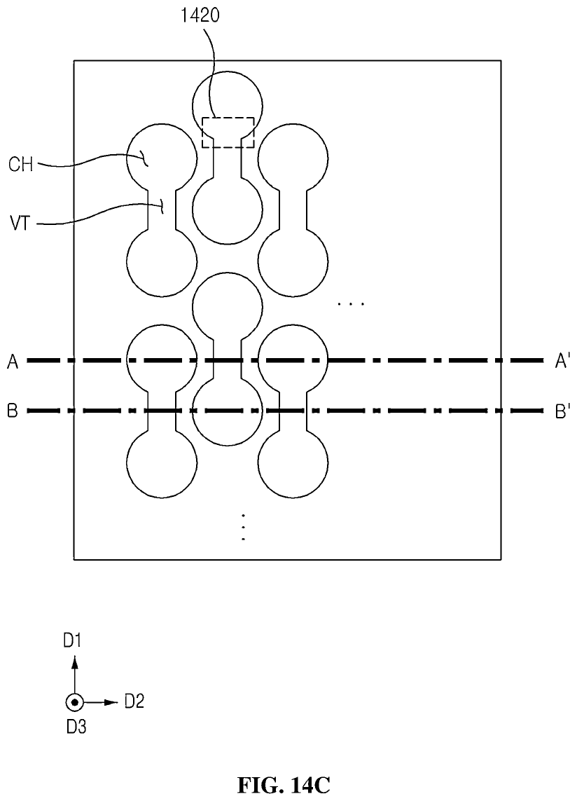

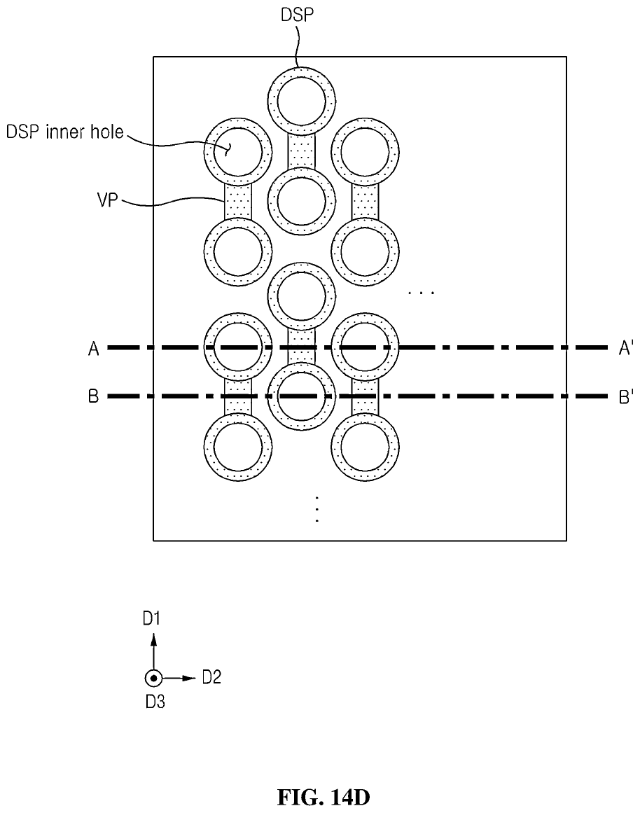

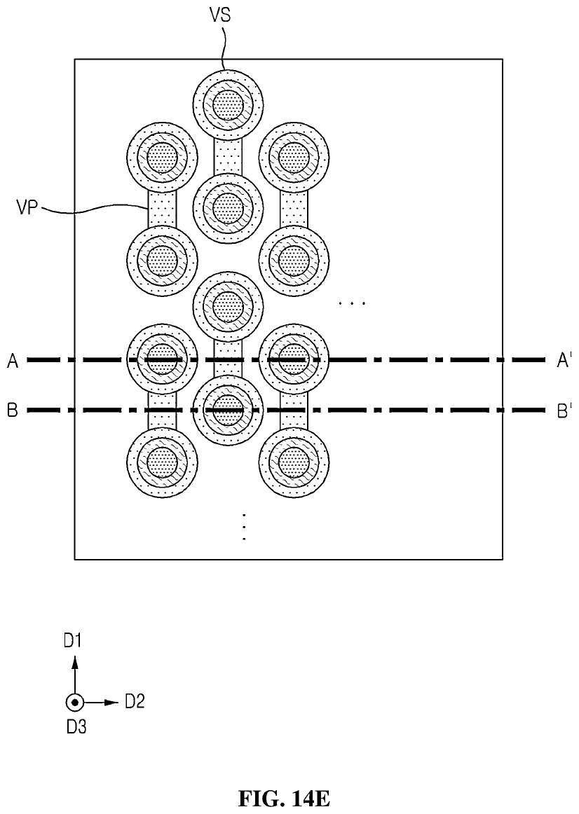

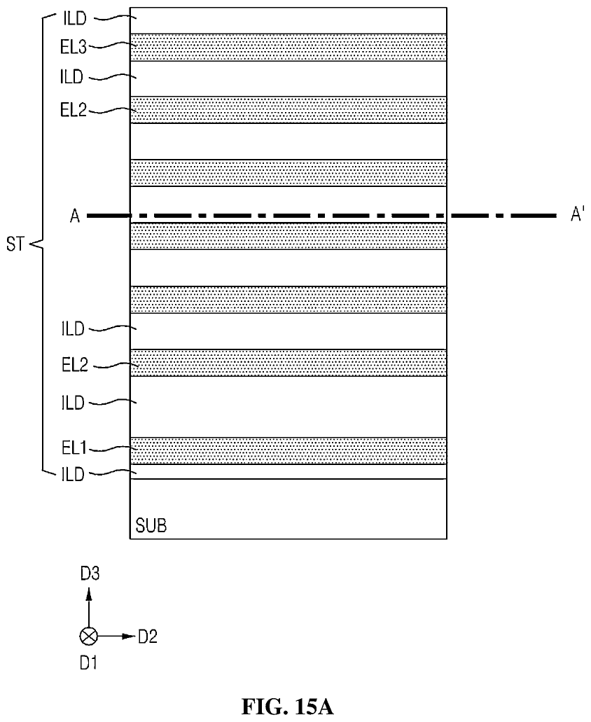

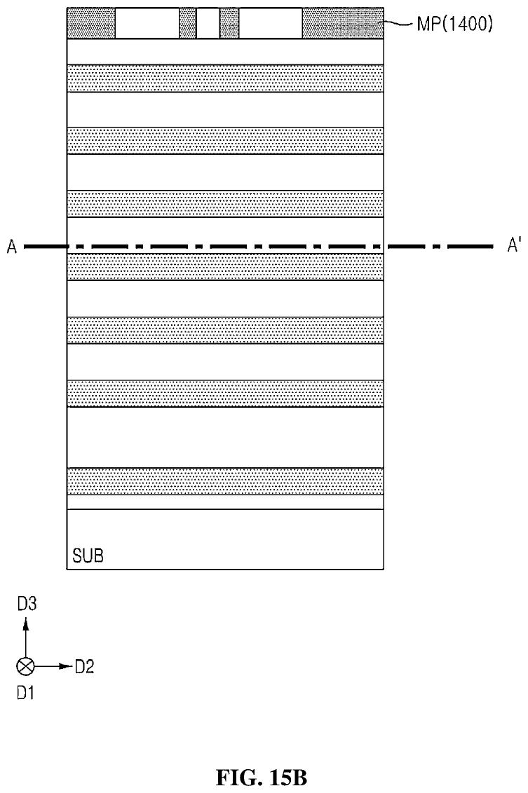

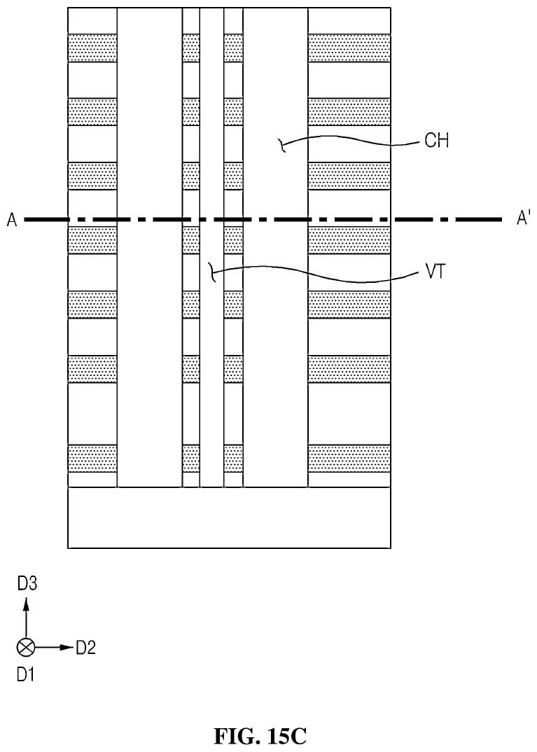

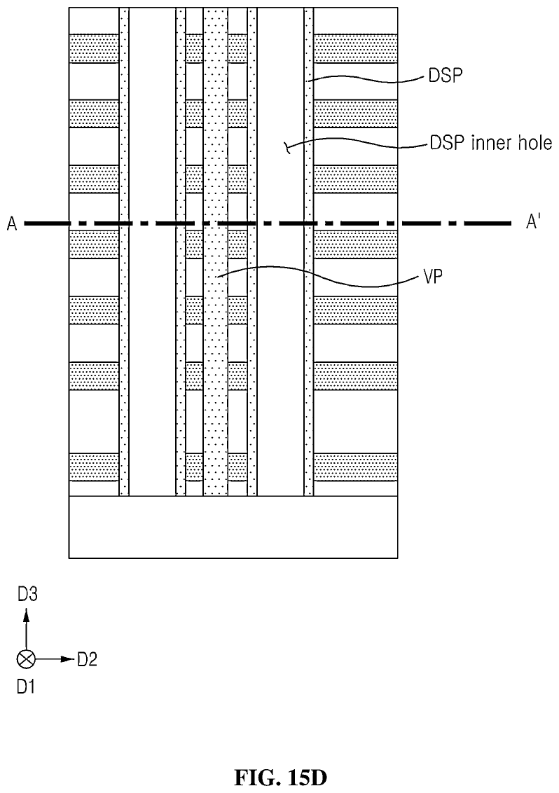

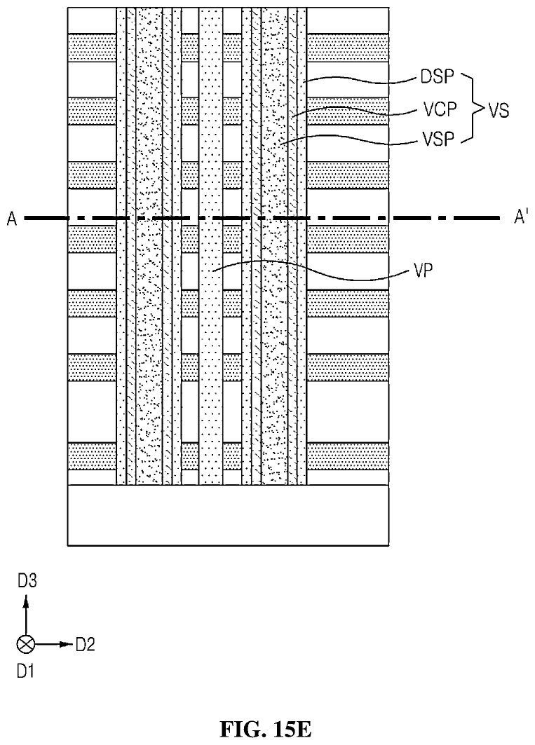

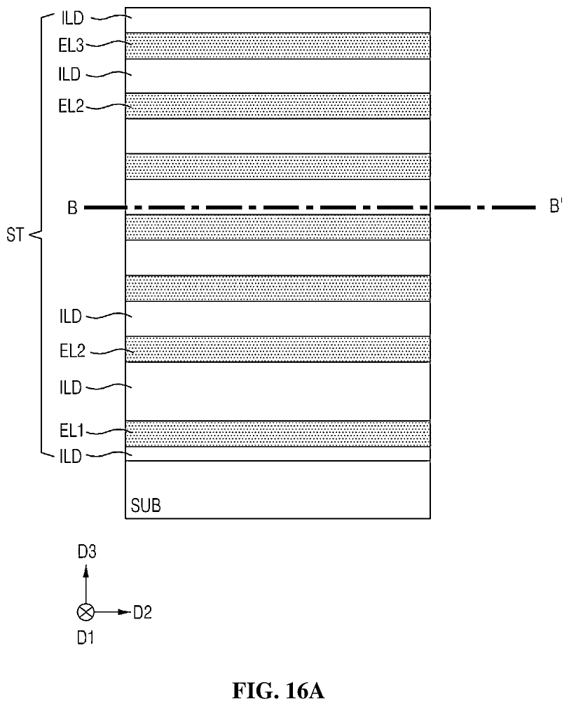

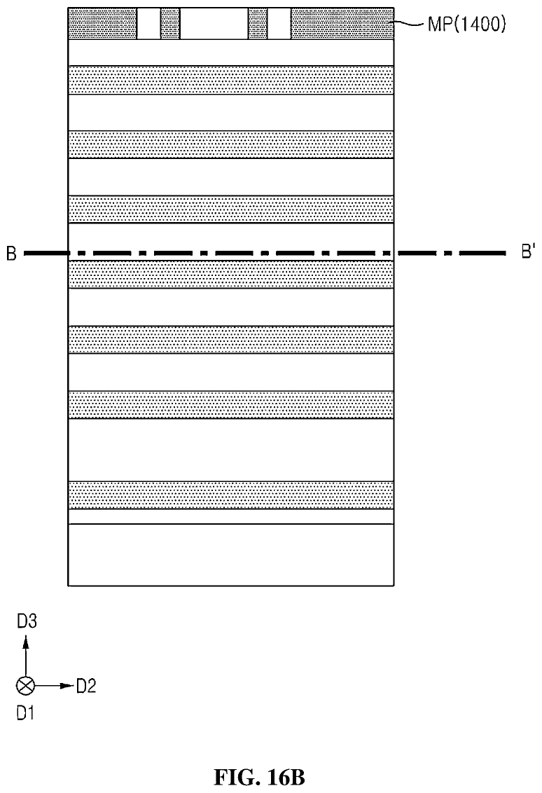

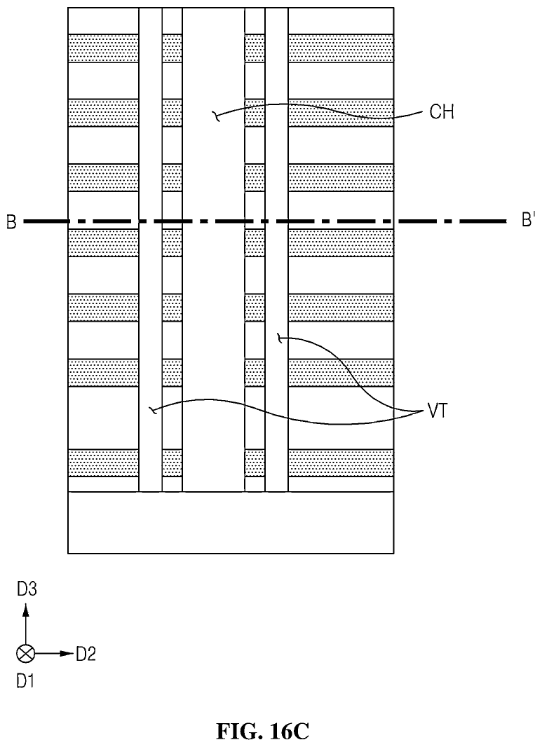

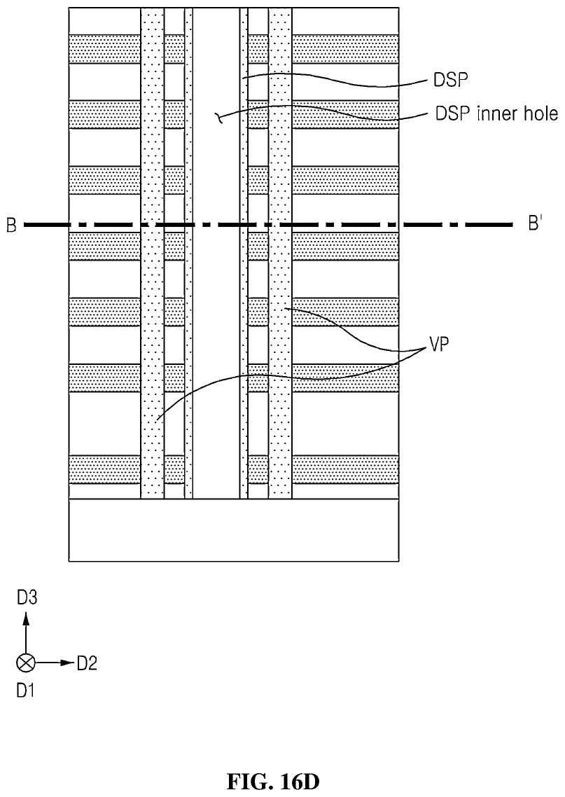

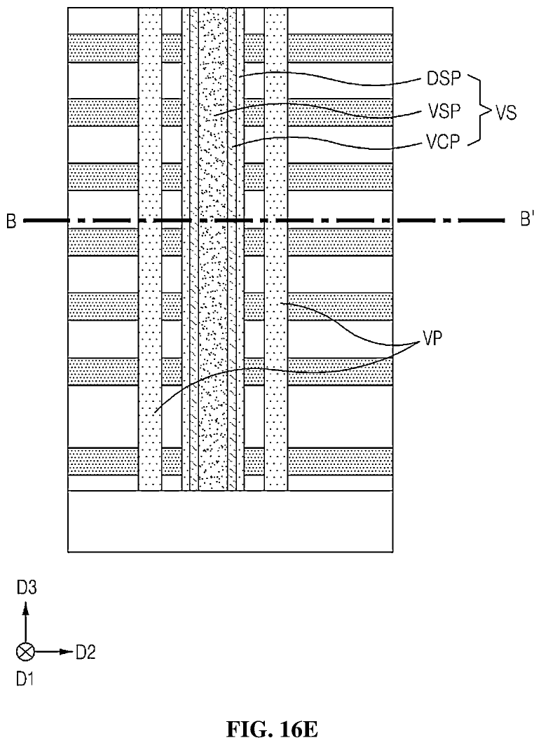

FIG. 13 is a flowchart illustrating a manufacturing method according to an embodiment in which a gate first method is applied to manufacture the 3D flash memory illustrated in FIGS. 2 and 3. FIGS. 14A to 14E are plan views illustrating the structure of the 3D flash memory to explain the 3D flash memory manufacturing method illustrated in FIG. 13. FIGS. 15A to 15E are sectional views illustrating the structure of the 3D flash memory illustrated in FIGS. 14A to 14E and correspond to sections taken along lines A-A′ in FIGS. 14A to 14E. FIGS. 16A to 16E are sectional views illustrating the structure of the 3D flash memory illustrated in FIGS. 14A to 14E and correspond to sections taken along lines B-B′ in FIGS. 14A to 14E.

The 3D flash memory manufacturing method according to this embodiment is for manufacturing the 3D flash memory having the structure described with reference to FIGS. 2 and 3 by applying the gate first method and is assumed to be performed by an automated and mechanized manufacturing system.

Hereinafter, for convenience of description, the 3D flash memory manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S1310, as illustrated in FIGS. 14A, 15A, and 16A, the manufacturing system may prepare a semiconductor structure SEMI-STR including the interlayer insulating films ILD and the word lines WL0 to WLn that extend in the horizontal direction (e.g., the second direction D2) and that are alternately stacked in the vertical direction (e.g., the third direction D3).

In step S1320, the manufacturing system may place a mask pattern MP on the upper surface of the semiconductor structure SEMI-STR as illustrated in FIGS. 14B, 15B, and 16B and may form the channel holes CH and the at least one vertical connecting channel VT in the semiconductor structure SEMI-STR in the vertical direction (e.g., the third direction D3) through an etching process using the mask pattern MP as illustrated in FIGS. 14C, 15C, and 16C. FIGS. 14C, 15C, and 16C illustrate a state in which the mask pattern MP is removed after the etching process.

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S1330 to be described below may maintain the gate all around (GAA) structure, and field characteristics applied to the cell string CSTR may be maintained the same as those of the GAA structure.

In step S1320, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In particular, in step S1320, as described above, a mask pattern 1400 including a serif-shaped portion 1411 considering optical proximity correction (OPC) may be used in an area 1410 corresponding to an edge 1420 where the at least one vertical connecting trench VT is brought into contact with each of the channel holes CH, and thus a rounded portion may not be included in the edge 1420 where the at least one vertical connecting trench VT is brought into contact with each of the channel holes CH.

Various well-known etching methods based on the mask pattern 1400 may be used as an etching process using the mask pattern 1400.

In step S1330, the manufacturing system may form the vertical channel structures VS, each of which includes the data storage pattern DSP and the vertical channel pattern VCP, in the channel holes CH in the vertical direction (e.g., the third direction D3).

In more detail, step S1330 may include a first step of forming the data storage pattern DSP on the inner wall of each of the channel holes CH as illustrated in FIGS. 14D, 15D, and 16D and a second step of forming the vertical channel pattern VCP on the inner wall of the data storage pattern DSP as illustrated in FIGS. 14E, 15E, and 16E (the vertical semiconductor pattern VSP is also formed together with the vertical channel pattern VCP when the vertical semiconductor pattern VSP is included).

In step S1340, the manufacturing system may form the at least one vertical connecting pattern VP in the at least one vertical connecting trench VT in the vertical direction (e.g., the third direction D3).

Here, as illustrated in FIGS. 14D, 15D, and 16D, step S1330 and step S1340 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S1340 may be a step of forming the at least one vertical connecting pattern VP with the data storage pattern DSP as the first step of step S1330 is performed, and thus simplification of the process of filling the at least one vertical connecting trench VT may be achieved.

As described above, in step S1320, the at least one vertical connecting trench VT and each of the channel holes CH may be formed by using the mask pattern 1400 including the serif-shaped portion 1411 considering the optical proximity correction (OPC). Accordingly, a rounded portion may not be included in an edge 1430 where the at least one vertical connecting pattern VP is brought into contact with each of the vertical channel structures VS, and thus a problem such as a short circuit may be prevented.

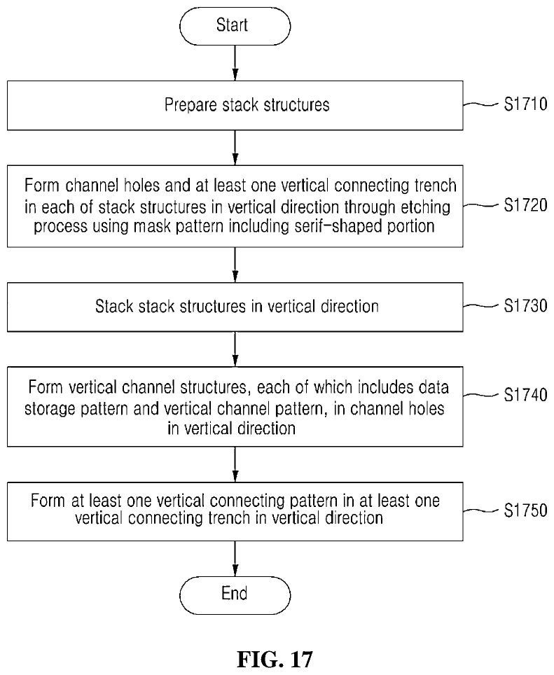

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 17.

FIG. 17 is a flowchart illustrating a manufacturing method according to an embodiment in which the stack method is applied in addition to the gate first method to manufacture the 3D flash memory illustrated in FIGS. 2 and 3.

The 3D flash memory manufacturing method according to this embodiment is for manufacturing the 3D flash memory having the structure described with reference to FIGS. 2 and 3 by applying the gate first method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S1710, the manufacturing system may prepare stack structures ST-STR, each of which includes the interlayer insulating films ILD and the word lines WL0 to WLn that extend in the horizontal direction (e.g., the second direction D2) and that are alternately stacked in the vertical direction (e.g., the third direction D3).

In step S1720, the manufacturing system may place a mask pattern MP on the upper surface of each of the stack structures ST-STR and may form the channel holes CH and the at least one vertical connecting trench VT in each of the stack structures ST-STR in the vertical direction (e.g., the third direction D3) through an etching process using the mask pattern MP.

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S1740 to be described below may maintain the gate all around (GAA) structure, and field characteristics applied to the cell string CSTR may be maintained the same as those of the GAA structure.

In step S1720, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In particular, in step S1720, as described above, a mask pattern including a serif-shaped portion considering optical proximity correction (OPC) may be used in an area corresponding to an edge where the at least one vertical connecting trench VT is brought into contact with each of the channel holes CH, and thus a rounded portion may not be included in the edge where the at least one vertical connecting trench VT is brought into contact with each of the channel holes CH.

Various well-known etching methods based on the mask pattern may be used as an etching process using the mask pattern.

In step S1730, the manufacturing system may stack the stack structures ST-STR in the vertical direction (e.g., the third direction D3).

In step S1740, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S1740 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S1750, the manufacturing system may form the at least one vertical connecting pattern VP in the at least one vertical connecting trench VT in the vertical direction (e.g., the third direction D3).

Here, step S1740 and step S1750 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S1750 may be a step of forming the at least one vertical connecting pattern VP with the data storage pattern DSP as the first step of step S1740 is performed, and thus simplification of the process of filling the at least one vertical connecting trench VT may be achieved.

As described above, in step S1720, the at least one vertical connecting trench VT and each of the channel holes CH may be formed by using the mask pattern including the serif-shaped portion considering the optical proximity correction (OPC). Accordingly, a rounded portion may not be included in an edge where the at least one vertical connecting pattern VP is brought into contact with each of the vertical channel structures VS, and thus a problem such as a short circuit may be prevented.

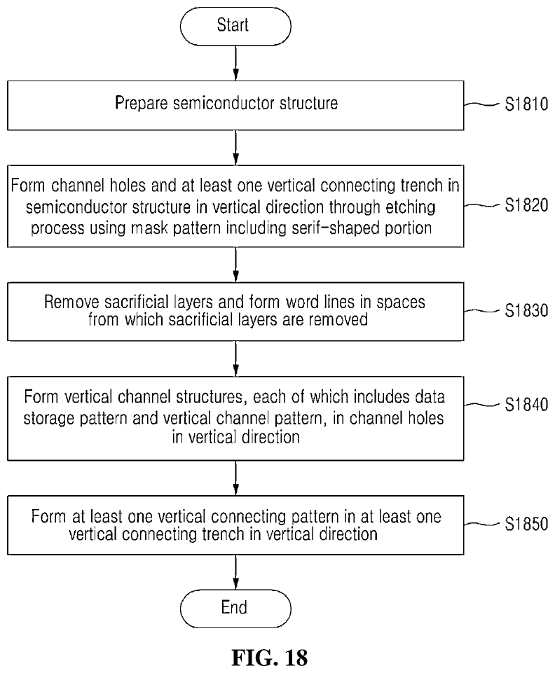

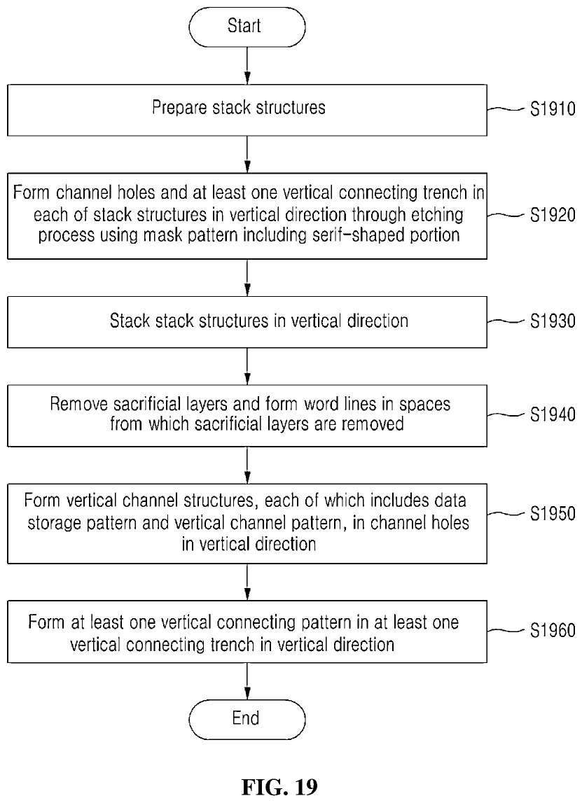

Although it has been described that the 3D flash memory is manufactured based on the gate first method, the present disclosure is not restricted or limited thereto, and the 3D flash memory may be manufactured based on a word line replacement method. Detailed description thereabout will be given below with reference to FIGS. 18 and 19.

FIG. 18 is a flowchart illustrating a manufacturing method according to an embodiment in which the word line replacement method is applied to manufacture the 3D flash memory illustrated in FIGS. 2 and 3.

The 3D flash memory manufacturing method according to this embodiment is for manufacturing the 3D flash memory having the structure described with reference to FIGS. 2 and 3 by applying the word line replacement method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S1810, the manufacturing system may prepare a semiconductor structure SEMI-STR including the interlayer insulating films ILD and sacrificial layers SAC that extend in the horizontal direction (e.g., the second direction D2) and that are alternately stacked in the vertical direction (e.g., the third direction D3).

In step S1820, the manufacturing system may place a mask pattern MP on the upper surface of the semiconductor structure SEMI-STR and may form the channel holes CH and the at least one vertical connecting trench VT in the semiconductor structure SEMI-STR in the vertical direction (e.g., the third direction D3) through an etching process using the mask pattern MP.

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S1840 to be described below may maintain the gate all around (GAA) structure, and field characteristics applied to the cell string CSTR may be maintained the same as those of the GAA structure.

In step S1820, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In particular, in step S1820, as described above, a mask pattern including a serif-shaped portion considering optical proximity correction (OPC) may be used in an area corresponding to an edge where the at least one vertical connecting trench VT is brought into contact with each of the channel holes CH, and thus a rounded portion may not be included in the edge where the at least one vertical connecting trench VT is brought into contact with each of the channel holes CH.

Various well-known etching methods based on the mask pattern may be used as an etching process using the mask pattern.

In step S1830, the manufacturing system may remove the sacrificial layers SAC and may form the word lines WL0 to WLn in the spaces from which the sacrificial layers SAC are removed. Removing the sacrificial layers SAC and filling a conductive material to form the word lines WL0 to WLn may be performed through the channel holes CH or the at least one vertical connecting trench VT. However, without being restricted or limited thereto, removing the sacrificial layers SAC and filling the conductive material to form the word lines WL0 to WLn may be performed through an isolation trench TR (not illustrated) or a separate trench (not illustrated).

In step S1840, the manufacturing system may form the vertical channel structures VS, each of which includes the data storage pattern DSP and the vertical channel pattern VCP, in the channel holes CH in the vertical direction (e.g., the third direction D3).

In more detail, step S1840 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S1850, the manufacturing system may form the at least one vertical connecting pattern VP in the at least one vertical connecting trench VT in the vertical direction (e.g., the third direction D3).

Here, step S1840 and step S1850 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S1850 may be a step of forming the at least one vertical connecting pattern VP with the data storage pattern DSP as the first step of step S1840 is performed, and thus simplification of the process of filling the at least one vertical connecting trench VT may be achieved.

As described above, in step S1820, the at least one vertical connecting trench and each of the channel holes may be formed by using the mask pattern including the serif-shaped portion considering the optical proximity correction (OPC). Accordingly, a rounded portion may not be included in an edge where the at least one vertical connecting pattern VP is brought into contact with each of the vertical channel structures VS, and thus a problem such as a short circuit may be prevented.

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 19.

FIG. 19 is a flowchart illustrating a manufacturing method according to an embodiment in which a stack method is in addition to the word line replacement method to manufacture the 3D flash memory illustrated in FIGS. 2 and 3.

The 3D flash memory manufacturing method according to this embodiment is for manufacturing the 3D flash memory having the structure described with reference to FIGS. 2 and 3 by applying the word line replacement method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical flash memory have been described with reference to FIGS. 2 and 3, detailed description thereabout will be omitted.

In step S1910, the manufacturing system may prepare stack structures ST-STR, each of which includes the interlayer insulating films ILD and the word lines WL0 to WLn that extend in the horizontal direction (e.g., the second direction D2) and that are alternately stacked in the vertical direction (e.g., the third direction D3).

In step S1920, the manufacturing system may place a mask pattern MP on the upper surface of each of the stack structures ST-STR and may form the channel holes CH and the at least one vertical connecting trench VT in each of the stack structures ST-STR in the vertical direction (e.g., the third direction D3) through an etching process using the mask pattern MP.

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S1950 to be described below may maintain the gate all around (GAA) structure, and field characteristics applied to the cell string CSTR may be maintained the same as those of the GAA structure.

In step S1920, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In particular, in step S1920, as described above, a mask pattern including a serif-shaped portion considering optical proximity correction (OPC) may be used in an area corresponding to an edge where the at least one vertical connecting trench VT is brought into contact with each of the channel holes CH, and thus a rounded portion may not be included in the edge where the at least one vertical connecting trench VT is brought into contact with each of the channel holes CH.

Various well-known etching methods based on the mask pattern may be used as an etching process using the mask pattern.

In step S1930, the manufacturing system may stack the stack structures ST-STR in the vertical direction (e.g., the third direction D3).

In step S1940, the manufacturing system may remove the sacrificial layers SAC and may form the word lines WL0 to WLn in the spaces from which the sacrificial layers SAC are removed. Removing the sacrificial layers SAC and filling a conductive material to form the word lines WL0 to WLn may be performed through the channel holes CH or the at least one vertical connecting trench VT. However, without being restricted or limited thereto, removing the sacrificial layers SAC and filling the conductive material to form the word lines WL0 to WLn may be performed through an isolation trench TR (not illustrated) or a separate trench (not illustrated).

In step S1950, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S1950 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S1960, the manufacturing system may form the at least one vertical connecting pattern VP in the at least one vertical connecting trench VT in the vertical direction (e.g., the third direction D3).

Here, step S1950 and step S1960 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S1960 may be a step of forming the at least one vertical connecting pattern VP with the data storage pattern DSP as the first step of step S1950 is performed, and thus simplification of the process of filling the at least one vertical connecting trench VT may be achieved.

As described above, in step S1920, the at least one vertical connecting trench VT and each of the channel holes CH may be formed by using the mask pattern including the serif-shaped portion considering the optical proximity correction (OPC). Accordingly, a rounded portion may not be included in an edge where the at least one vertical connecting pattern VP is brought into contact with each of the vertical channel structures VS, and thus a problem such as a short circuit may be prevented.

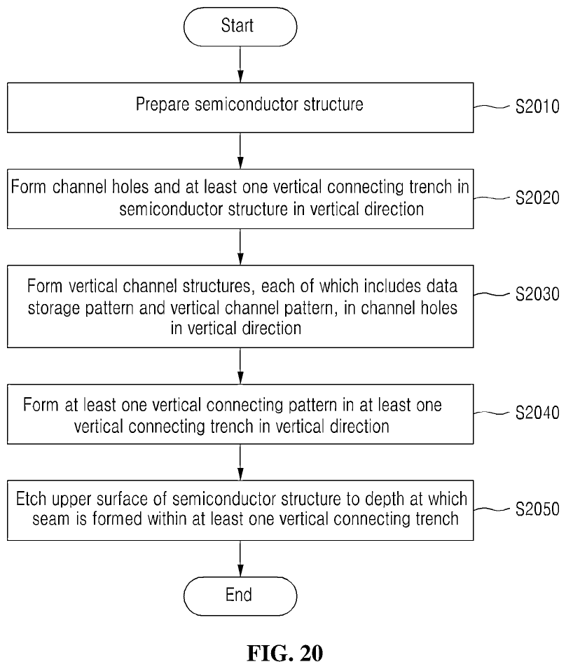

Hereinabove, to solve a problem such as a short circuit that occurs as a rounded portion is included in the edge where the at least one vertical connecting pattern VP is brought into contact with each of the vertical channel structures VS, the method of manufacturing the 3D flash memory using the mask pattern including the serif-shaped portion considering the optical proximity correction (OPC) has been described. However, the problem may be solved by a method of removing a seam generated within the at least one vertical connecting pattern VP. Detailed description thereabout will be given below with reference to FIGS. 20 to 26.

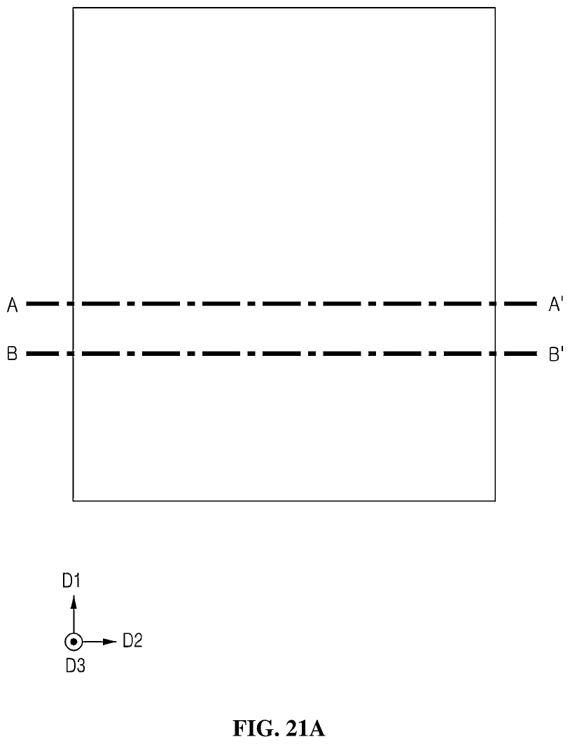

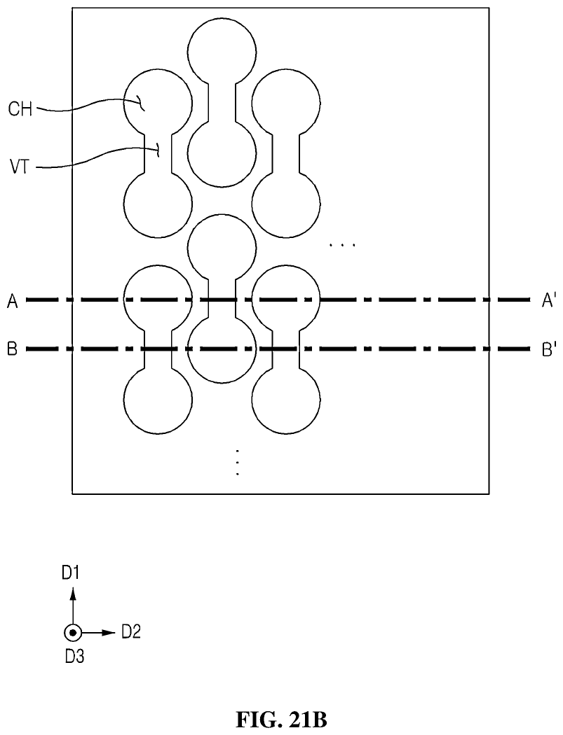

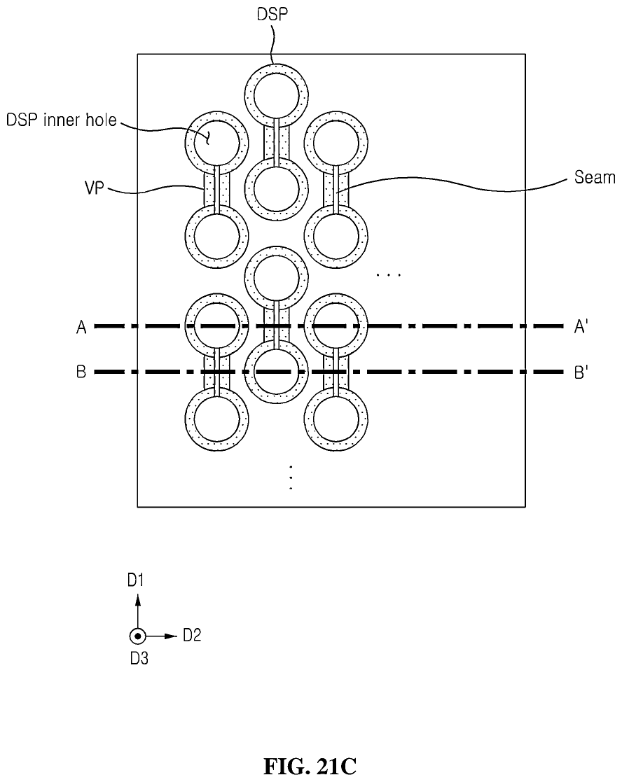

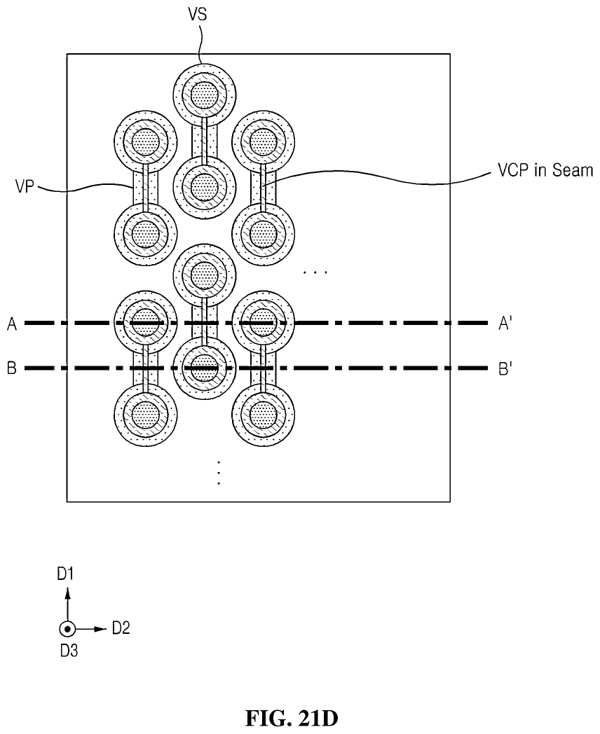

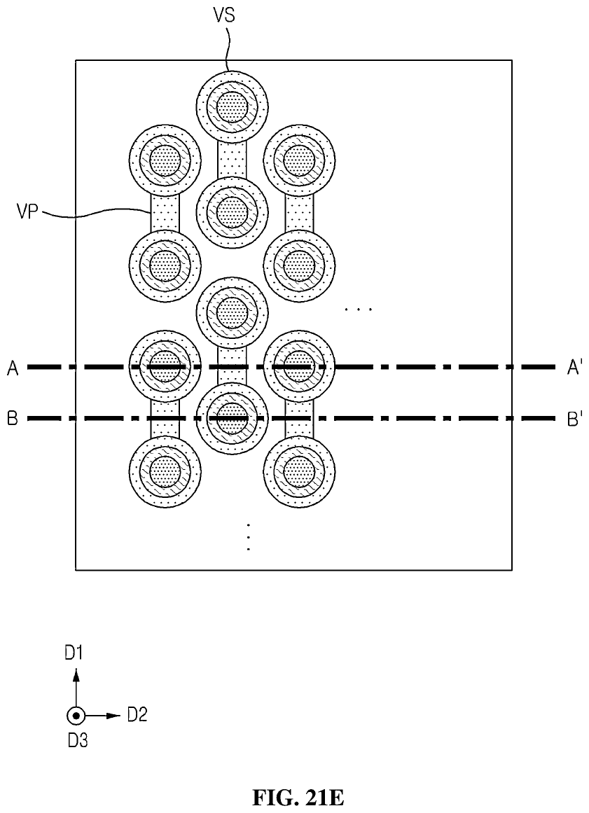

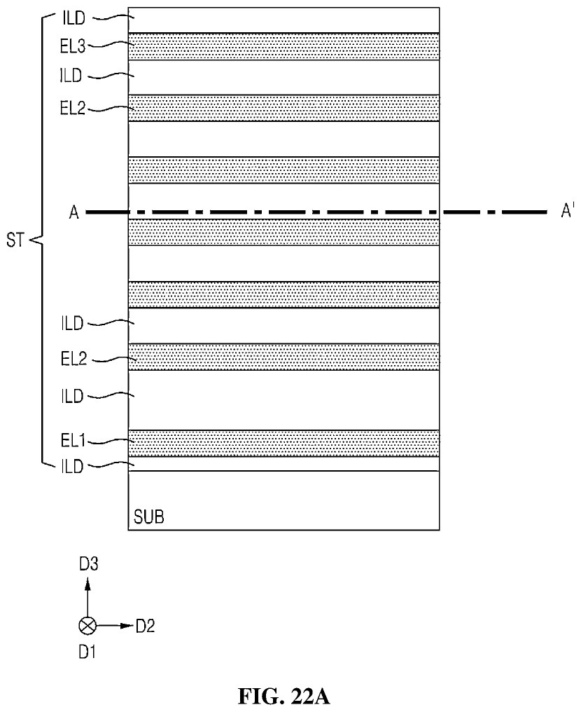

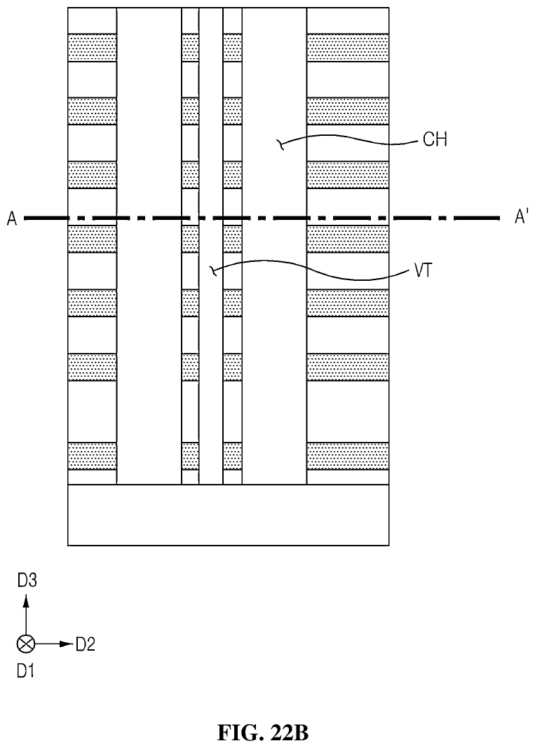

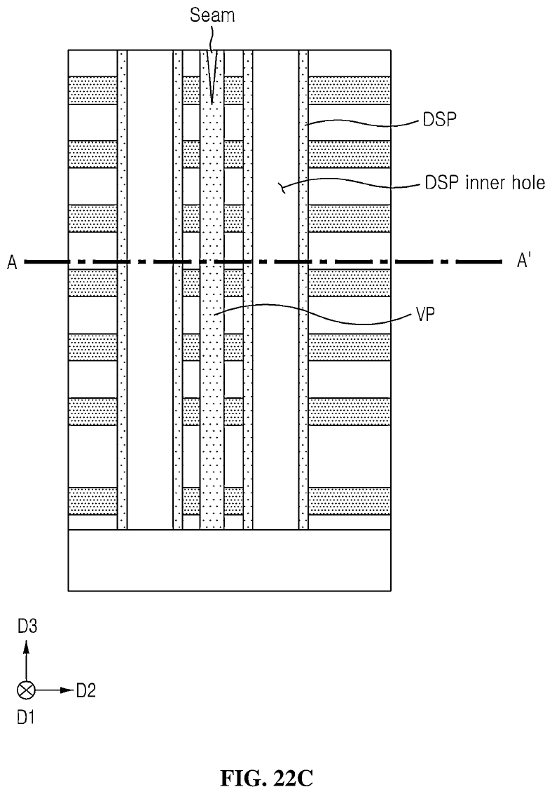

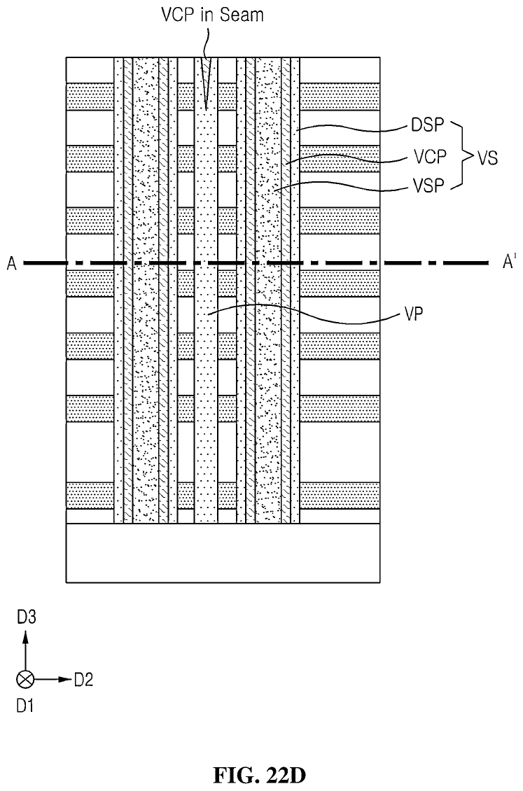

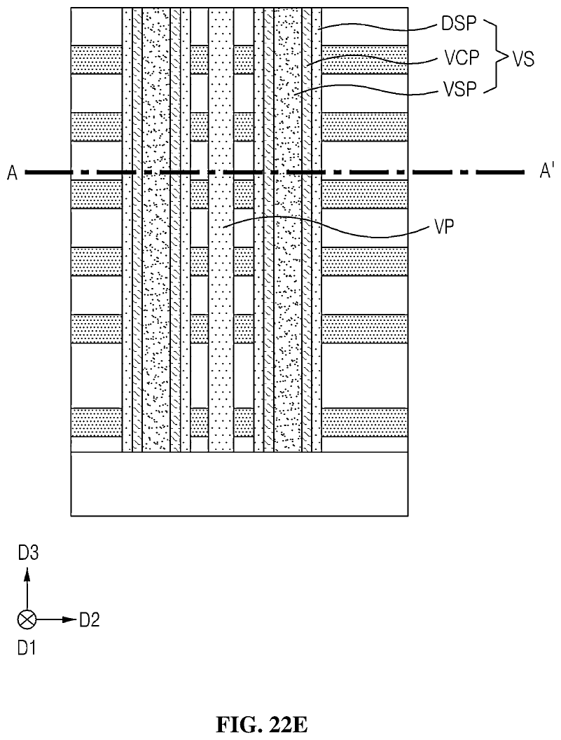

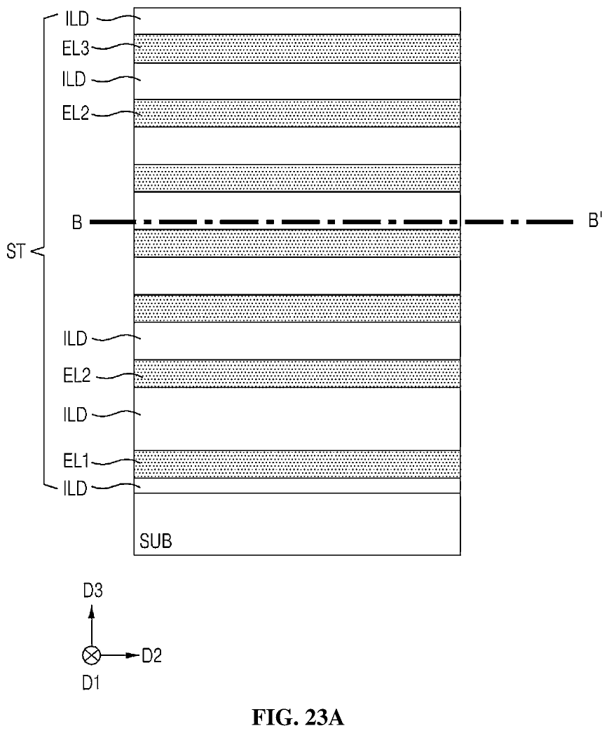

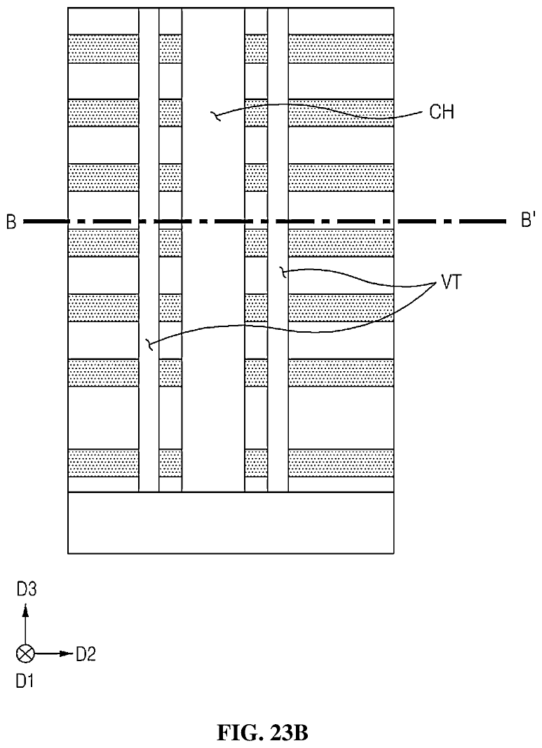

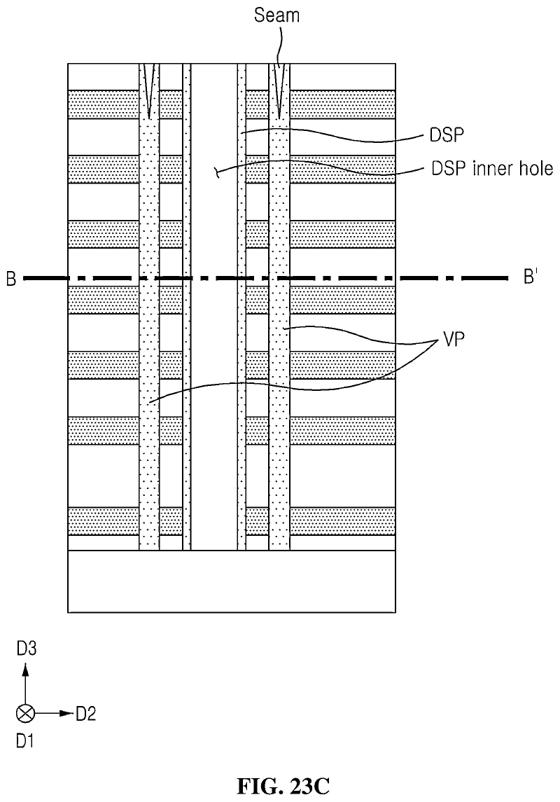

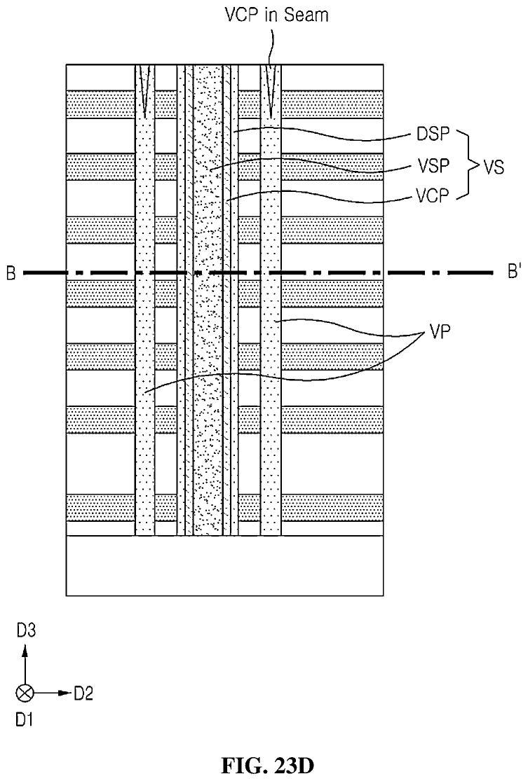

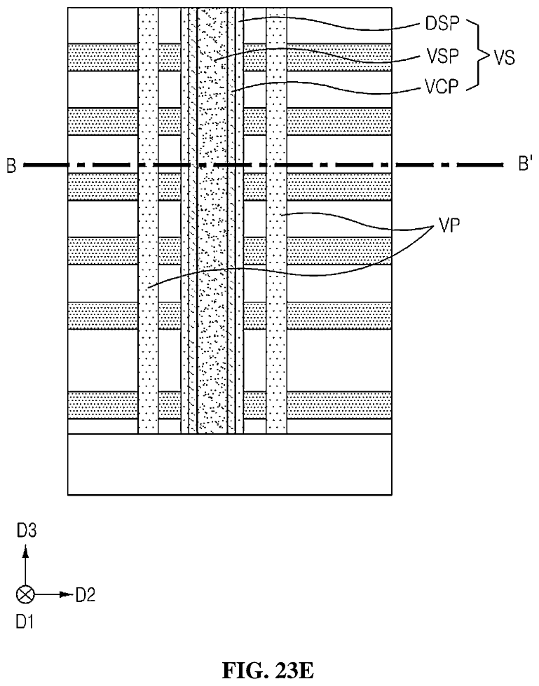

FIG. 20 is a flowchart illustrating a manufacturing method according to another embodiment in which the gate first method is applied to manufacture the 3D flash memory illustrated in FIGS. 2 and 3. FIGS. 21A to 21E are plan views illustrating the structure of the 3D flash memory to explain the 3D flash memory manufacturing method illustrated in FIG. 20. FIGS. 22A to 22E are sectional views illustrating the structure of the 3D flash memory illustrated in FIGS. 21A to 21E and correspond to sections taken along lines A-A′ in FIGS. 21A to 21E. FIGS. 23A to 23E are sectional views illustrating the structure of the 3D flash memory illustrated in FIGS. 21A to 21E and correspond to sections taken along lines B-B′ in FIGS. 21A to 21E.

The 3D flash memory manufacturing method according to the other embodiment is for manufacturing the 3D flash memory having the structure described with reference to FIGS. 2 and 3 by applying the gate first method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S2010, as illustrated in FIGS. 21A, 22A, and 23A, the manufacturing system may prepare a semiconductor structure SEMI-STR including the interlayer insulating films ILD and the word lines WL0 to WLn that extend in the horizontal direction (e.g., the second direction D2) and that are alternately stacked in the vertical direction (e.g., the third direction D3).

In step S2020, as illustrated in FIGS. 21B, 22B, and 23B, the manufacturing system may form the channel holes CH and the at least one vertical connecting trench VT in the semiconductor structure SEMI-STR in the vertical direction (e.g., the third direction D3).

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S2030 to be described below may maintain the gate all around (GAA) structure, and field characteristics applied to the cell string CSTR may be maintained the same as those of the GAA structure.

In step S2020, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In step S2030, the manufacturing system may form the vertical channel structures VS, each of which includes the data storage pattern DSP and the vertical channel pattern VCP, in the channel holes CH in the vertical direction (e.g., the third direction D3).

In more detail, step S2030 may include a first step of forming the data storage pattern DSP on the inner wall of each of the channel holes CH as illustrated in FIGS. 21C, 22C, and 23C and a second step of forming the vertical channel pattern VCP on the inner wall of the data storage pattern DSP as illustrated in FIGS. 21D, 22D, and 23D (the vertical semiconductor pattern VSP is also formed together with the vertical channel pattern VCP when the vertical semiconductor pattern VSP is included).

In step S2040, the manufacturing system may form the at least one vertical connecting pattern VP in the at least one vertical connecting trench VT in the vertical direction (e.g., the third direction D3).

Here, as illustrated in FIGS. 21C, 22C, and 23C, step S2030 and step S2040 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S2040 may be a step of forming the at least one vertical connecting pattern VP with the data storage pattern DSP as the first step of step S2030 is performed, and thus simplification of the process of filling the at least one vertical connecting trench VT may be achieved.

Since the mask pattern having the structure described with reference to FIGS. 11 to 19 is not used in the manufacturing method according to the other embodiment, a rounded portion (not illustrated) may be included in an edge where the at least one vertical connecting pattern VP is brought into contact with each of the vertical channel structures VS. As illustrated in FIG. 22C, this causes a seam within the at least one vertical connecting pattern VP, and as the second step of step S2030 is performed, the seam is filled with the vertical channel pattern VCP.

Accordingly, in the manufacturing method according to the other embodiment, the manufacturing system may remove the seam, which is filled with the vertical channel pattern VCP, through step S2050, thereby preventing a problem such as a short circuit due to the seam filled with the vertical channel pattern VCP.

In more detail, in step S2050 after step S2040, as illustrated in FIGS. 21E, 22E, and 23E, the manufacturing system may etch the upper surface of the semiconductor structure SEMI-STR to a depth D1 at which the seam is formed within the at least one vertical connecting pattern VP.

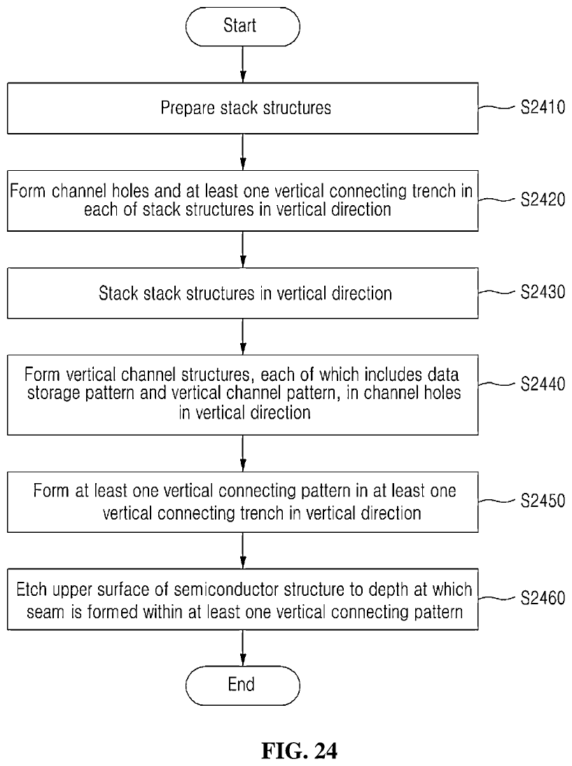

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 24.

FIG. 24 is a flowchart illustrating a manufacturing method according to another embodiment in which the stack method is applied in addition to the gate first method to manufacture the 3D flash memory illustrated in FIGS. 2 and 3.

The 3D flash memory manufacturing method according to the other embodiment is for manufacturing the 3D flash memory having the structure described with reference to FIGS. 2 and 3 by applying the gate first method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S2410, the manufacturing system may prepare stack structures ST-STR, each of which includes the interlayer insulating films ILD and the word lines WL0 to WLn that extend in the horizontal direction (e.g., the second direction D2) and that are alternately stacked in the vertical direction (e.g., the third direction D3).

In step S2420, the manufacturing system may form the channel holes CH and the at least one vertical connecting trench VT in each of the stack structures ST-STR in the vertical direction (e.g., the third direction D3).

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S2440 to be described below may maintain the gate all around (GAA) structure, and field characteristics applied to the cell string CSTR may be maintained the same as those of the GAA structure.

In step S2420, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In step S2430, the manufacturing system may stack the stack structures ST-STR in the vertical direction (e.g., the third direction D3).

In step S2440, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S2440 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S2450, the manufacturing system may form the at least one vertical connecting pattern VP in the at least one vertical connecting trench VT in the vertical direction (e.g., the third direction D3).

Here, step S2440 and step S2450 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S2450 may be a step of forming the at least one vertical connecting pattern VP with the data storage pattern DSP as the first step of step S2440 is performed, and thus simplification of the process of filling the at least one vertical connecting trench VT may be achieved.

Since the mask pattern having the structure described with reference to FIGS. 11 to 19 is not used in the manufacturing method according to the other embodiment, a rounded portion (not illustrated) may be included in an edge where the at least one vertical connecting pattern VP is brought into contact with each of the vertical channel structures VS. This causes a seam within the at least one vertical connecting pattern VP, and as the second step of step S2440 is performed, the seam is filled with the vertical channel pattern VCP.

Accordingly, in the manufacturing method according to the other embodiment, the manufacturing system may remove the seam, which is filled with the vertical channel pattern VCP, through step S2460, thereby preventing a problem such as a short circuit due to the seam filled with the vertical channel pattern VCP.

In more detail, in step S2460 after step S2450, the manufacturing system may etch the upper surface of the semiconductor structure SEMI-STR to a depth D1 at which the seam is formed within the at least one vertical connecting pattern VP.

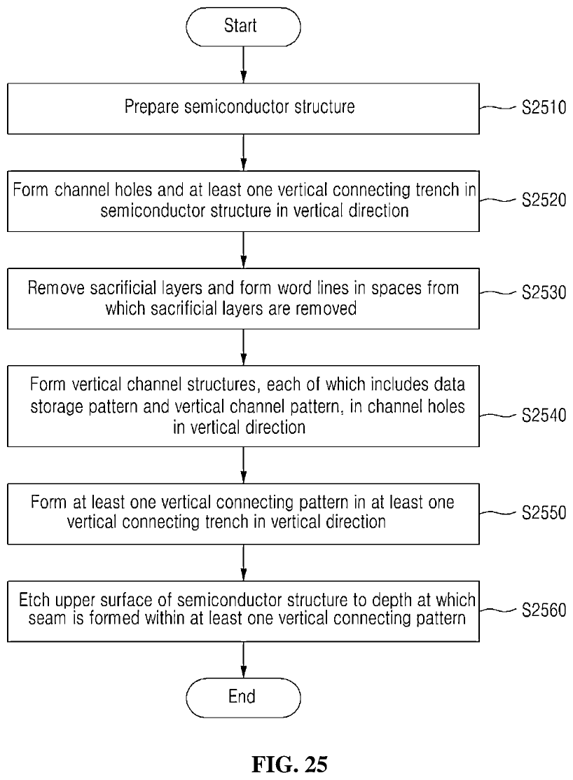

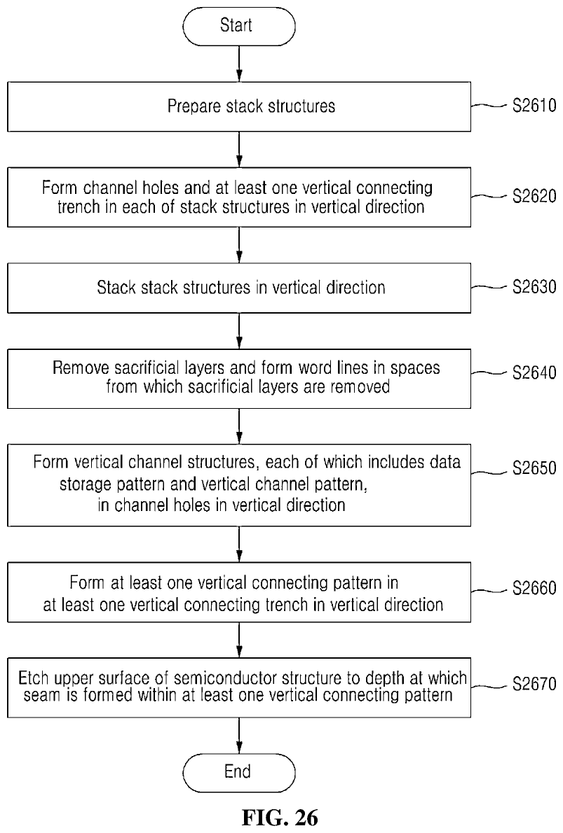

Although it has been described that the 3D flash memory is manufactured based on the gate first method, the present disclosure is not restricted or limited thereto, and the 3D flash memory may be manufactured based on the word line replacement method. Detailed description thereabout will be given below with reference to FIGS. 25 and 26.

FIG. 25 is a flowchart illustrating a manufacturing method according to another embodiment in which the word line replacement method is applied to manufacture the 3D flash memory illustrated in FIGS. 2 and 3.

The 3D flash memory manufacturing method according to the other embodiment is for manufacturing the 3D flash memory having the structure described with reference to FIGS. 2 and 3 by applying the word line replacement method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical flash memory have been described with reference to FIGS. 2 and 3, detailed description thereabout will be omitted.

In step S2510, the manufacturing system may prepare a semiconductor structure SEMI-STR including the interlayer insulating films ILD and the sacrificial layers SAC that extend in the horizontal direction (e.g., the second direction D2) and that are alternately stacked in the vertical direction (e.g., the third direction D3).

In step S2520, the manufacturing system may form the channel holes CH and the at least one vertical connecting trench VT in the semiconductor structure SEMI-STR in the vertical direction (e.g., the third direction D3).

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S2540 to be described below may maintain the gate all around (GAA) structure, and field characteristics applied to the cell string CSTR may be maintained the same as those of the GAA structure.

In step S2520, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In step S2530, the manufacturing system may remove the sacrificial layers SAC and may form the word lines WL0 to WLn in the spaces from which the sacrificial layers SAC are removed. Removing the sacrificial layers SAC and filling a conductive material to form the word lines WL0 to WLn may be performed through the channel holes CH or the at least one vertical connecting trench VT. However, without being restricted or limited thereto, removing the sacrificial layers SAC and filling the conductive material to form the word lines WL0 to WLn may be performed through an isolation trench TR (not illustrated) or a separate trench (not illustrated).

In step S2540, the manufacturing system may form the vertical channel structures VS, each of which includes the data storage pattern DSP and the vertical channel pattern VCP, in the channel holes CH in the vertical direction (e.g., the third direction D3).

In more detail, step S2540 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S2550, the manufacturing system may form the at least one vertical connecting pattern VP in the at least one vertical connecting trench VT in the vertical direction (e.g., the third direction D3).

Here, step S2540 and step S2550 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S2550 may be a step of forming the at least one vertical connecting pattern VP with the data storage pattern DSP as the first step of step S2540 is performed, and thus simplification of the process of filling the at least one vertical connecting trench VT may be achieved.

Since the mask pattern having the structure described with reference to FIGS. 11 to 19 is not used in the manufacturing method according to the other embodiment, a rounded portion (not illustrated) may be included in an edge where the at least one vertical connecting pattern VP is brought into contact with each of the vertical channel structures VS. This causes a seam within the at least one vertical connecting pattern VP, and as the second step of step S2540 is performed, the seam is filled with the vertical channel pattern VCP.

Accordingly, in the manufacturing method according to the other embodiment, the manufacturing system may remove the seam, which is filled with the vertical channel pattern VCP, through step S2560, thereby preventing a problem such as a short circuit due to the seam filled with the vertical channel pattern VCP.

In more detail, in step S2560 after step S2550, the manufacturing system may etch the upper surface of the semiconductor structure SEMI-STR to a depth D1 at which the seam is formed within the at least one vertical connecting pattern VP.

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 26.

FIG. 26 is a flowchart illustrating a manufacturing method according to another embodiment in which the stack method is applied in addition to the word line replacement method to manufacture the 3D flash memory illustrated in FIGS. 2 and 3.

The 3D flash memory manufacturing method according to the other embodiment is for manufacturing the 3D flash memory having the structure described with reference to FIGS. 2 and 3 by applying the word line replacement method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one vertical connecting pattern VP. Since the constituent materials constituting the components of the 3D flash memory have been described with reference to FIGS. 2 and 3, detailed description thereabout will be omitted.

In step S2610, the manufacturing system may prepare stack structures ST-STR, each of which includes the interlayer insulating films ILD and the word lines WL0 to WLn that extend in the horizontal direction (e.g., the second direction D2) and that are alternately stacked in the vertical direction (e.g., the third direction D3).

In step S2620, the manufacturing system may form the channel holes CH and the at least one vertical connecting trench VT in each of the stack structures ST-STR in the vertical direction (e.g., the third direction D3).

Here, the at least one vertical connecting trench VT may be formed at a position connecting the channel holes CH on the horizontal plane.

The manufacturing system may form the at least one vertical connecting trench VT in a size smaller than the size of each of the channel holes CH on the horizontal plane. Accordingly, the vertical channel structures VS formed in step S2650 to be described below may maintain the gate all around (GAA) structure, and field characteristics applied to the cell string CSTR may be maintained the same as those of the GAA structure.

In step S2620, forming the channel holes CH and forming the at least one vertical connecting trench VT may be simultaneously performed through a single process. Accordingly, the etching gas may be smoothly introduced into the channel holes CH through the at least one vertical connecting trench VT, and thus an etching profile may be secured.

In step S2630, the manufacturing system may stack the stack structures ST-STR in the vertical direction (e.g., the third direction D3).

In step S2640, the manufacturing system may remove the sacrificial layers SAC and may form the word lines WL0 to WLn in the spaces from which the sacrificial layers SAC are removed. Removing the sacrificial layers SAC and filling a conductive material to form the word lines WL0 to WLn may be performed through the channel holes CH or the at least one vertical connecting trench VT. However, without being restricted or limited thereto, removing the sacrificial layers SAC and filling the conductive material to form the word lines WL0 to WLn may be performed through an isolation trench TR (not illustrated) or a separate trench (not illustrated).

In step S2650, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S2650 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S2660, the manufacturing system may form the at least one vertical connecting pattern VP in the at least one vertical connecting trench VT in the vertical direction (e.g., the third direction D3).

Here, step S2650 and step S2660 may be simultaneously performed through the same process. In more detail, the manufacturing system may form the at least one vertical connecting pattern VP by depositing the data storage pattern DSP in the at least one vertical connecting trench VT through a process of depositing the data storage pattern DSP of the vertical channel structure VS in the channel hole CH. Accordingly, step S2660 may be a step of forming the at least one vertical connecting pattern VP with the data storage pattern DSP as the first step of step S2650 is performed, and thus simplification of the process of filling the at least one vertical connecting trench VT may be achieved.

Since the mask pattern having the structure described with reference to FIGS. 11 to 19 is not used in the manufacturing method according to the other embodiment, a rounded portion (not illustrated) may be included in an edge where the at least one vertical connecting pattern VP is brought into contact with each of the vertical channel structures VS. This causes a seam within the at least one vertical connecting pattern VP, and as the second step of step S2650 is performed, the seam is filled with the vertical channel pattern VCP.

Accordingly, in the manufacturing method according to the other embodiment, the manufacturing system may remove the seam, which is filled with the vertical channel pattern VCP, through step S2670, thereby preventing a problem such as a short circuit due to the seam filled with the vertical channel pattern VCP.

In more detail, in step S2670 after step S2660, the manufacturing system may etch the upper surface of the semiconductor structure SEMI-STR to a depth D1 at which the seam is formed within the at least one vertical connecting pattern VP.

Although the manufacturing method according to the other embodiment that includes the process of removing the seam filled with the vertical channel pattern VCP has been described as being independent of the manufacturing method according to one embodiment that includes the process using the mask pattern including the serif-shaped portion, the present disclosure is not restricted or limited thereto, and the process of removing the seam filled with the vertical channel pattern VCP may also be performed in the manufacturing method according to one embodiment that includes the process using the mask pattern including the serif-shaped portion.

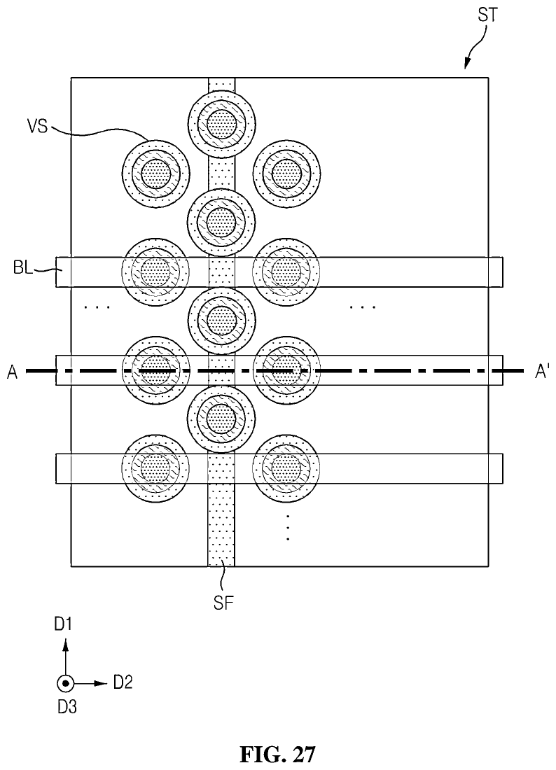

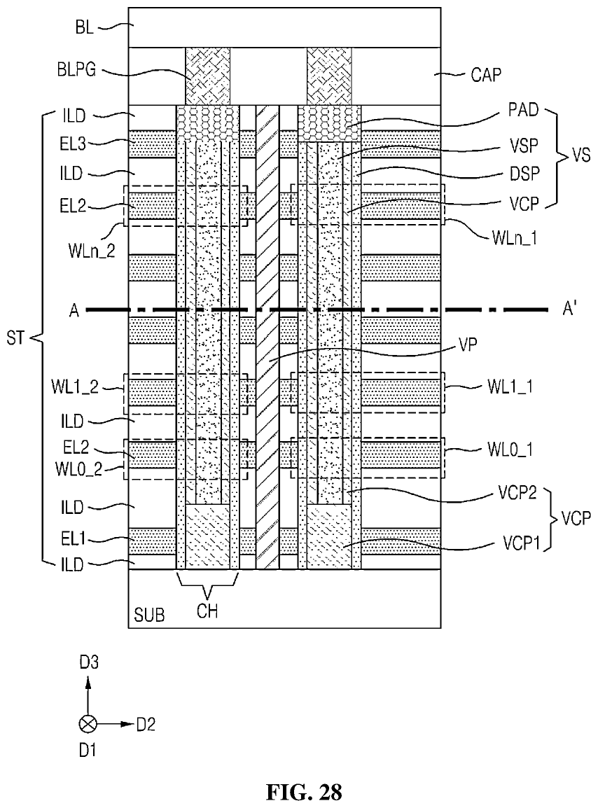

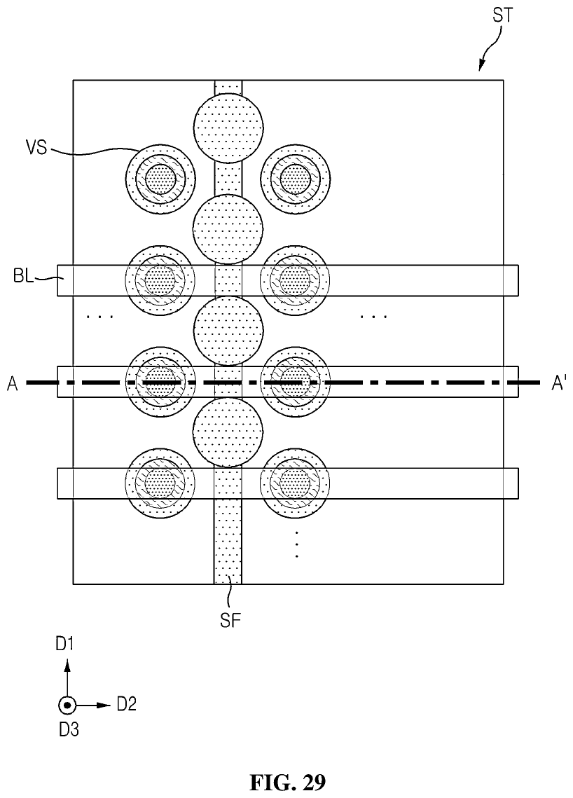

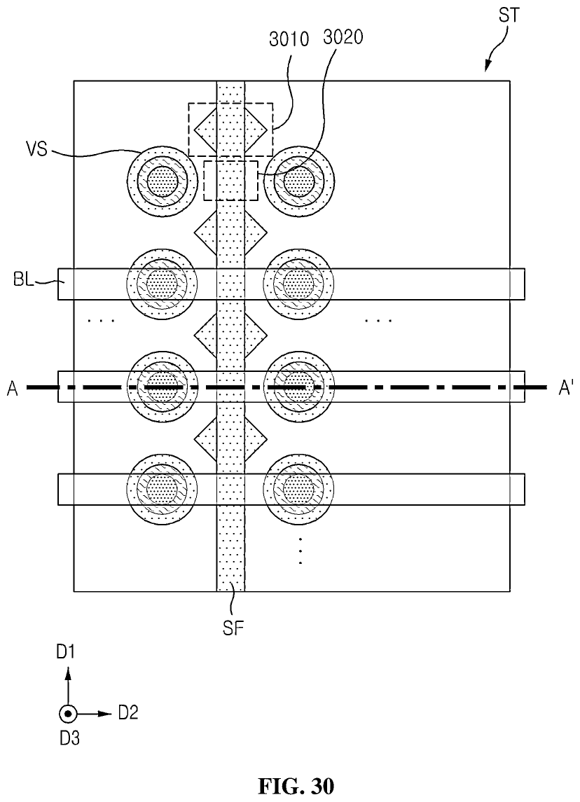

FIG. 27 is a plan view illustrating the structure of a 3D flash memory according to an embodiment. FIG. 28 is a sectional view illustrating the structure of the 3D flash memory illustrated in FIG. 27, where FIG. 28 corresponds to a sectional view taken along line A-A′ in FIG. 27. FIG. 29 is a plan view illustrating the structure of a 3D flash memory according to another embodiment. FIG. 30 is a plan view illustrating the structure of a 3D flash memory according to another embodiment.

Referring to FIGS. 27 and 30, a substrate SUB may be a semiconductor substrate such as a silicon substrate, a silicon-germanium substrate, a germanium substrate, or a monocrystalline epitaxial layer grown on a monocrystalline silicon substrate. The substrate SUB may be doped with the first conductive type impurity (e.g., a P-type impurity).

Stack structures ST may be disposed on the substrate SUB. The stack structures ST may extend in the first direction D1 and may be two-dimensionally arranged in the second direction D2. In addition, the stack structures ST may be spaced apart from one another in the second direction D2.

Each of the stack structures ST may include gate electrodes EL1, EL2, and EL3 and interlayer insulating films ILD alternately stacked on the upper surface of the substrate SUB in the vertical direction (e.g., the third direction D3). The stack structures ST may have a substantially flat upper surface. That is, the upper surfaces of the stack structures ST may be parallel to the upper surface of the substrate SUB. Hereinafter, the vertical direction refers to the third direction D3 or the direction opposite to the third direction D3.

Referring again to FIG. 1, each of the gate electrodes EL1, EL2, and EL3 may be one of the erase control line ECL, the ground selection lines GSL0, GSL1, and GSL2, the word lines WL0 to WLn and DWL, the first string selection lines SSL1-1, SSL1-2, and SSL1-2, and the second string selection lines SSL2-1, SSL2-2, and SSL2-3 sequentially stacked on the substrate SUB.

The gate electrodes EL1, EL2, and EL3 may extend in the first direction D1 and may have substantially the same thickness in the third direction D3. Hereinafter, a thickness refers to a thickness in the third direction D3. Each of the gate electrodes EL1, EL2, and EL3 may be formed of a conductive material. For example, each of the gate electrodes EL1, EL2, and EL3 may include at least one selected from doped semiconductor (e.g., doped silicon), metal (e.g., tungsten (W), copper (Cu), aluminum (Al), titanium (Ti), tantalum (Ta), molybdenum (Mo), ruthenium (Ru), or gold (Au)), or conductive metal nitride (e.g., titanium nitride or tantalum nitride). Each of the gate electrodes EL1, EL2, and EL3 may include at least one of all metallic materials capable of being formed through ALD, in addition to the metallic materials described above.

More specifically, the gate electrodes EL1, EL2, and EL3 may include the first gate electrode EL1 at the bottom, the third gate electrode EL3 at the top, and the plurality of second gate electrodes EL2 between the first gate electrode EL1 and the third gate electrode EL3. Each of the first gate electrode EL1 and the third gate electrode EL3 is illustrated and described in a singular form. However, this is illustrative, and the present disclosure is not limited thereto. The first gate electrode EL1 and the third gate electrode EL3 may be provided in plural numbers as needed. The first gate electrode EL1 may correspond to one of the ground selection lines GSL0, GSL1, and GSL2 illustrated in FIG. 1. The second gate electrode EL2 may correspond to one of the word lines WL0 to WLn and DWL illustrated in FIG. 1. The third gate electrode EL3 may correspond to one of the first string selection lines SSL1-1, SSL1-2, and SSL1-3 illustrated in FIG. 1, or may correspond to one of the second string selection lines SSL2-1, SSL2-2, and SSL2-3 illustrated in FIG. 1.

Although not illustrated, an end portion of each of the stack structures ST may have a stepwise structure in the first direction D1. More specifically, the lengths of the gate electrodes EL1, EL2, and EL3 of the stack structures ST in the first direction D1 may be decreased farther away from the substrate SUB. The third gate electrode EL3 may have the smallest length in the first direction D1 and may have the greatest separation distance from the substrate SUB in the third direction D3. The first gate electrode EL1 may have the greatest length in the first direction D1 and may have the smallest separation distance from the substrate SUB in the third direction D3. Due to the stepwise structure, each of the stack structures ST may have a decreasing thickness farther away from the outermost one of vertical channel structures VS that will be described below, and sidewalls of the gate electrodes EL1, EL2, and EL3 may be spaced apart from one another at certain intervals in the first direction D1 when viewed in the plan view.

The interlayer insulating films ILD may have different thicknesses. For example, among the interlayer insulating films ILD, the lowermost and uppermost interlayer insulating films ILD may have thicknesses smaller than those of the other interlayer insulating films ILD. However, this is illustrative, and the present disclosure is not limited thereto. The interlayer insulating films ILD may have different thicknesses depending on the characteristics of a semiconductor device, or may have the same thickness. The interlayer insulating films ILD may be formed of an insulating material for the purpose of insulation between the gate electrodes EL1, EL2, and EL3. For example, the interlayer insulating films ILD may be formed of silicon oxide.

A plurality of channel holes CH may be formed through the stack structures ST and a portion of the substrate SUB. The vertical channel structures VS may be provided in the channel holes CH. The vertical channel structures VS may correspond to the plurality of cell strings CSTR illustrated in FIG. 1. The vertical channel structures VS may be connected with the substrate SUB and may extend in the third direction D3. The connection of the vertical channel structures VS to the substrate SUB may be achieved by bringing the lower surfaces of portions of the vertical channel structures VS into contact with the upper surface of the substrate SUB. However, without being restricted or limited thereto, the connection of the vertical channel structures VS to the substrate SUB may be achieved by embedding the portions of the vertical channel structures VS in the substrate SUB. When the portions of the vertical channel structures VS are embedded in the substrate SUB, the lower surfaces of the vertical channel structures VS may be located at a lower level than the upper surface of the substrate SUB.

A plurality of columns of vertical channel structures VS may penetrate one of the stack structures ST. For example, as illustrated in FIG. 27, columns of three vertical channel structures VS may penetrate one of the stack structures ST. However, without being restricted or limited thereto, columns of two vertical channel structures VS may penetrate one of the stack structures ST, or columns of four or more vertical channel structures VS may penetrate one of the stack structures ST. In a pair of columns adjacent to each other, vertical channel structures VS corresponding to one column may be shifted in the first direction D1 from vertical channel structures VS corresponding to the other column adjacent to the one column. The vertical channel structures VS may be arranged in zigzags in the first direction D1 when viewed in the plan view. However, without being restricted or limited thereto, the vertical channel structures VS may be arranged side by side in rows and columns to form an array.

Each of the vertical channel structures VS may extend from the substrate SUB in the third direction D3. In the drawing, the vertical channel structure VS is illustrated as having a pillar shape in which the lower and upper ends have the same width. However, without being restricted or limited thereto, the vertical channel structure VS may have a shape in which the widths in the first direction D1 and the second direction D2 are increased in the third direction D3. The upper surface of the vertical channel structure VS may have a circular shape, an oval shape, a quadrangular shape, or a bar shape.

Each of the vertical channel structures VS may include a data storage pattern DSP, a vertical channel pattern VCP, a vertical semiconductor pattern VSP, and a conductive pad PAD. In the vertical channel structure VS, the data storage pattern DSP may have a pipe or macaroni shape in which the lower end is open, and the vertical channel pattern VCP may have a pipe or macaroni shape in which the lower end is closed. The vertical semiconductor pattern VSP may fill the space surrounded by the vertical channel pattern VCP and the conductive pad PAD.

The data storage pattern DSP may cover the inner wall of the channel hole CH. The inside of the data storage pattern DSP may surround the outer wall of the vertical channel pattern VCP, and the outside of the data storage pattern DSP may make contact with the sidewalls of the gate electrodes EL1, EL2, and EL3. Accordingly, areas of the data storage pattern DSP that correspond to the second gate electrodes EL2, together with areas of the vertical channel pattern VCP that correspond to the second gate electrodes EL2, may constitute memory cells in which a memory operation (e.g., a program operation, a read operation, or an erase operation) is performed by a voltage applied through the second gate electrodes EL2. The memory cells correspond to the memory cell transistors MCT illustrated in FIG. 1. That is, the data storage pattern DSP may serve as data storage in the 3D flash memory by trapping charges or holes due to the voltage applied through the second gate electrodes EL2 or maintaining the state of the charges (e.g., the polarization state of the charges). For example, an ONO (tunnel oxide film (Oxide)-charge storage film (Nitride)-blocking oxide film (Oxide)) layer or a ferroelectric layer may be used as the data storage pattern DSP. The data storage pattern DSP may represent a binary data value or a multi-level data value due to a change in the trapped charges or holes, or may represent a binary data value or a multi-level data value due to a change in the state of the charges.

The vertical channel pattern VCP may cover the inner wall of the data storage pattern DSP. The vertical channel pattern VCP may include a first part VCP1 and a second part VCP2 on the first part VCP1.

The first part VCP1 of the vertical channel pattern VCP may be provided in a lower portion of the channel hole CH and may make contact with the substrate SUB. The first part VCP1 of the vertical channel pattern VCP may be used to block, suppress, or minimize leakage current in the vertical channel structure VS and/or may be used as an epitaxial pattern. For example, the thickness of the first part VCP1 of the vertical channel pattern VCP may be greater than the thickness of the first gate electrode EL1. The sidewall of the first part VCP1 of the vertical channel pattern VCP may be surrounded by the data storage pattern DSP. The upper surface of the first part VCP1 of the vertical channel pattern VCP may be located at a higher level than the upper surface of the first gate electrode EL1. More specifically, the upper surface of the first part VCP1 of the vertical channel pattern VCP may be located between the upper surface of the first gate electrode EL1 and the lower surface of the lowermost one of the second gate electrodes EL2. The lower surface of the first part VCP1 of the vertical channel pattern VCP may be located at a lower level than the top surface of the substrate SUB (that is, the lower surface of the lowermost one of the interlayer insulating films ILD). A portion of the first part VCP1 of the vertical channel pattern VCP may overlap the first gate electrode EL1 in a horizontal direction. Hereinafter, the horizontal direction refers to any one direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2. Accordingly, as described above, the second part VCP2 of the vertical channel pattern VCP may constitute the memory cells together with the areas of the data storage pattern DSP that correspond to the second gate electrodes EL2.

The upper surface of the second part VCP2 of the vertical channel pattern VCP may be substantially coplanar with the upper surface of the vertical semiconductor pattern VSP. The upper surface of the second part VCP2 of the vertical channel pattern VCP may be located at a higher level than the upper surface of the uppermost one of the second gate electrodes EL2. More specifically, the upper surface of the second part VCP2 of the vertical channel pattern VCP may be located between the upper and lower surfaces of the third gate electrode EL3.

The vertical channel pattern VCP may be a component that transfers charges or holes to the data storage pattern DSP. The vertical channel pattern VCP may be formed of monocrystalline silicon or polycrystalline silicon and may form a channel, or may be boosted, by an applied voltage. However, without being restricted or limited thereto, the vertical channel pattern VCP may be formed of an oxide semiconductor material capable of blocking, suppressing, or minimizing leakage current. For example, the vertical channel pattern VCP may be formed of an oxide semiconductor material containing at least one of In, Zn, or Ga with excellent leakage current characteristics or a group IV semiconductor material. For example, the vertical channel pattern VCP may be formed of a ZnOx-based material including AZO, ZTO, IZO, ITO, IGZO, or Ag—ZnO. Accordingly, the vertical channel pattern VCP may block, suppress, or minimize leakage current to the gate electrodes EL1, EL2, and EL3 or the substrate SUB and may improve transistor characteristics (e.g., threshold voltage distribution and the speed of program/read operations) of at least one of the gate electrodes EL1, EL2, and EL3. Thus, the vertical channel pattern VCP may improve electrical characteristics of the 3D flash memory.

The vertical semiconductor pattern VSP may be surrounded by the second part VCP2 of the vertical channel pattern VCP. The upper surface of the vertical semiconductor pattern VSP may make contact with the conductive pad PAD, and the lower surface of the vertical semiconductor pattern VSP may make contact with the first part VCP1 of the vertical channel pattern VCP. The vertical semiconductor pattern VSP may be spaced apart from the substrate SUB in the third direction D3. In other words, the vertical semiconductor pattern VSP may be electrically floated from the substrate SUB.

The vertical semiconductor pattern VSP may be formed of a material that helps diffusion of charges or holes in the vertical channel pattern VCP. In more detail, the vertical semiconductor pattern VSP may be formed of a material with excellent charge and hole mobility. For example, the vertical semiconductor pattern VSP may be formed of a semiconductor material doped with an impurity, an intrinsic semiconductor material that is not doped with an impurity, or a polycrystalline semiconductor material. In a more specific example, the vertical semiconductor pattern VSP may be formed of polycrystalline silicon doped with the same first conductive type impurity (e.g., a P-type impurity) as that of the substrate SUB. That is, the vertical semiconductor pattern VSP may improve the speed of a memory operation by improving the electrical characteristics of the 3D flash memory.

Referring again to FIG. 1, the vertical channel structures VS may correspond to channels of the erase control transistor ECT, the first and second string selection transistors SST1 and SST2, the ground selection transistor GST, and the memory cell transistors MCT.

The conductive pad PAD may be provided on the upper surface of the second part VCP2 of the vertical channel pattern VCP and the upper surface of the vertical semiconductor pattern VSP. The conductive pad PAD may be connected with the upper portion of the vertical channel pattern VCP and the upper portion of the vertical semiconductor pattern VSP. The sidewall of the conductive pad PAD may be surrounded by the data storage pattern DSP. The upper surface of the conductive pad PAD may be substantially coplanar with the upper surface of each of the stack structures ST (that is, the upper surface of the uppermost one of the interlayer insulating films ILD). The lower surface of the conductive pad PAD may be located at a lower level than the upper surface of the third gate electrode EL3. More specifically, the lower surface of the conductive pad PAD may be located between the upper surface and the lower surface of the third gate electrode EL3. That is, at least a portion of the conductive pad PAD may overlap the third gate electrode EL3 in the horizontal direction.

The conductive pad PAD may be formed of a semiconductor or conductive material doped with an impurity. For example, the conductive pad PAD may be formed of a semiconductor material doped with an impurity different from that of the vertical semiconductor pattern VSP (more precisely, an impurity of the second conductive type (e.g., N-type) different from the first conductive type (e.g., P-type)).

The conductive pad PAD may reduce contact resistance between a bit line BL to be described below and the vertical channel pattern VCP (or, the vertical semiconductor pattern VSP).

Although it has been described that the vertical channel structures VS include the conductive pad PAD, the present disclosure is not restricted or limited thereto, and the vertical channel structures VS may have a structure in which the conductive pad PAD is omitted. Since the conductive pad PAD is omitted from the vertical channel structures VS in this case, the vertical channel pattern VCP and the vertical semiconductor pattern VSP may extend in the third direction D3 such that the upper surfaces of the vertical channel pattern VCP and the vertical semiconductor pattern VSP are substantially coplanar with the upper surface of each of the stack structures ST (that is, the upper surface of the uppermost one of the interlayer insulating films ILD). In addition, in this case, a bit line contact plug BLPG to be described below may be electrically connected with the vertical channel pattern VCP through direct contact therebetween instead of being indirectly electrically connected with the vertical channel pattern VCP through the conductive pad PAD.

Although it has been described that the vertical semiconductor pattern VSP is included in the vertical channel structures VS, the present disclosure is not restricted or limited thereto, and the vertical semiconductor pattern VSP may be omitted.

Although it has been described that the vertical channel pattern VCP includes the first part VCP1 and the second part VCP2, the present disclosure is not restricted or limited thereto, and the vertical channel pattern VCP may have a structure from which the first part VCP1 is excluded. For example, the vertical channel pattern VCP may be provided between the vertical semiconductor pattern VSP extending to the substrate SUB and the data storage pattern DSP and may extend to the substrate SUB to make contact with the substrate SUB. In this case, the lower surface of the vertical channel pattern VCP may be located at a lower level than the top surface of the substrate SUB (the lower surface of the lowermost one of the interlayer insulating films ILD), and the upper surface of the vertical channel pattern VCP may be substantially coplanar with the upper surface of the vertical semiconductor pattern VSP.

Although not illustrated in the drawing, an isolation trench TR extending in the first direction D1 may be provided between the stack structures ST adjacent to each other. The isolation trench TR may separate and isolate each of the stack structures ST to form one block. Accordingly, in an existing 3D flash memory, vertical channel patterns VS included in each of stack structures ST share each of word lines WL0 to WLn, whereas the 3D flash memory according to one embodiment includes at least one separation film SF so that the vertical channel patterns VS included in each of the stack structures ST do not share each of the word lines WL0 to WLn. Detailed description thereabout will be given below.

A common source area CSR may be provided inside the substrate SUB exposed by the isolation trench TR. The common source area CSR may extend in the first direction D1 inside the substrate SUB. The common source area CSR may be formed of a semiconductor material doped with the second conductive type impurity (e.g., an N-type impurity). The common source area CSR may correspond to the common source line CSL of FIG. 1.

A common source plug CSP may be provided in the isolation trench TR. The common source plug CSP may be connected with the common source area CSR. The upper surface of the common source plug CSP may be substantially coplanar with the upper surface of each of the stack structures ST (that is, the upper surface of the uppermost one of the interlayer insulating films ILD). The common source plug CSP may have a plate shape extending in the first direction D1 and the third direction D3. In this case, the common source plug CSP may have a shape in which the width in the second direction D2 is increased in the third direction D3.

Insulating spacers SP may be interposed between the common source plug CSP and the stack structures ST. The insulating spacers SP may be provided between the adjacent stack structures ST to face each other. For example, the insulating spacers SP may be formed of silicon oxide, silicon nitride, silicon oxy nitride, or a low-k material having a low dielectric constant.

A capping insulating film CAP may be provided on the stack structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected with the conductive pad PAD may be provided inside the capping insulating film CAP. The bit line contact plug BLPG may have a shape in which the widths in the first direction D1 and the second direction D2 are increased in the third direction D3.

The bit line BL may be provided on the capping insulating film CAP and the bit line contact plug BLPG. The bit line BL may correspond to one of the plurality of bit lines BL0, BL1, and BL2 illustrated in FIG. 1. The bit line BL may be formed of a conductive material and may extend in the second direction D2. The conductive material constituting the bit line BL may be the same material as the conductive material that forms each of the gate electrodes EL1, EL2, and EL3 described above.

The bit line BL may be electrically connected with the vertical channel structures VS through the bit line contact plug BLPG. When the bit line BL is connected with the vertical channel structures VS, this may mean that the bit line BL is connected with the vertical channel patterns VCP included in the vertical channel structures VS.

Within each of the stack structures VS, the at least one separation film SF may separate and isolate each of the word lines WL0 to WLn into a plurality of word lines on the horizontal plane. For example, the at least one separation film SF may separate and isolate the first word line WL0 into a 1_1 word line WL0_1 and a 1_2 word line WL0_2, may separate and isolate the second word line WL1 into a 2_1 word line WL1_1 and a 2_2 word line WL1_2, and may separate and isolate the (n−1)^{th} word line WLn into an (n−1)_1 word line WLn_1 and an (n−1)_2 word line WLn_2. In the drawing, one separation film SF is illustrated as separating and isolating each of the word lines WL0 to WLn into two word lines within the stack structure ST. However, a plurality of separation films SF may be provided within the stack structure ST and may separate and isolate each of the word lines WL0 to WLn into three or more word lines.

Accordingly, the at least one separation film SF may achieve a technical effect of improving the influence of a fringing field generated in the existing 3D flash memory in which each of the word lines WL0 to WLn is provided as one component in each of the stack structures VS without being separated and isolated.

In particular, the at least one separation film SF may be simultaneously formed with the vertical channel structures VS through the same process. In more detail, the at least one separation film SF may be simultaneously formed through a process in which the data storage patterns DSP of the vertical channel structures VS are formed. Accordingly, the at least one separation film SF may be formed of only the data storage pattern DSP. For example, when the data storage patterns DSP of the vertical channel structures VS are implemented with an ONO layer, the at least one separation film SF may be formed of a charge storage film (Nitride) and a blocking oxide film (Oxide) of the ONO layer.

The at least one separation film SF may connect vertical channel structures VS included in at least one column or row among the vertical channel structures VS on the horizontal plane as illustrated in FIGS. 2 and 3 and may extend in the vertical direction (e.g., the third direction D3). Hereinafter, when the at least one separation film SF connects the vertical channel structures VS on the horizontal plane, this means that the at least one separation film SF connects the entire side surfaces of the vertical channel structures VS.

In this case, the at least one separation film SF may be constituted by connecting parts that connect the vertical channel structures VS included in at least one column or row on the horizontal plane.

When the at least one separation film SF is formed to connect the vertical channel structures included in at least one column or row on the horizontal plane, each of the vertical channel structures VS connected by the at least one separation film SF may be used as a memory cell. That is, likewise to the other vertical channel structures VS (vertical channel structure not connected with the at least one separation film SF), each of the vertical channel structures VS connected together on the horizontal plane by the at least one separation film SF may have a structure including the vertical channel pattern VCP so as to be used as a memory cell as illustrated in FIGS. 2 and 3. However, without being restricted or limited thereto, each of the vertical channel structures VS connected by the at least one separation film SF may not include the vertical channel pattern VCP as illustrated in FIG. 4 and thus may only function as a component of the separation film SF without being used as a memory cell.

The width L1 at which the at least one separation film SF is formed may be determined to be a value greater than or equal to the minimum width by which each of the word lines WL0 to WLn is electrically separated and isolated. In addition, the width L1 at which the at least one separation film SF is formed may be determined to be a value that satisfies the condition in which the vertical channel patterns VCP of the vertical channel structure VS connected by the at least one separation film SF are not connected together while satisfying the minimum width condition for electrically separating and isolating each of the word lines WL0 to WLn when the vertical channel structures VS included in at least one column or row are connected together on the horizontal plane. That is, the at least one separation film SF may be formed to have a width that satisfies the condition that the at least one separation film SF is formed of only the data storage pattern DSP. For example, when an ONO layer is used as the data storage pattern DSP, the at least one separation film SF may be formed to have a width of 35 nm or less by which the ONO layer having a thickness of 16 nm is able to be deposited on both inner walls, such that the at least one separation film SF is formed of only the ONO layer.

As described above, when the at least one separation film SF connects the vertical channel structures VS included in at least one column or row on the horizontal plane, the width L1 at which the at least one separation film SF is formed may be determined to be a value that satisfies the condition in which the vertical channel patterns VCP of the vertical channel structure VS connected by the at least one separation film SF are not connected together while satisfying the minimum width condition for electrically separating and isolating each of the word lines WL0 to WLn. Accordingly, the vertical channel structures VS may maintain the gate all around (GAA) structure, and field characteristics applied to the cell string CSTR may be maintained the same as those of the GAA structure.

However, without being restricted or limited thereto, the width L1 at which the at least one separation film SF is formed may be set to a value greater than or equal to the minimum width by which at least one separation film trench SFT (the at least one separation film SF is formed by filling the at least one separation film trench SFT) smoothly introduces the etching gas into the channel holes CH.

When the at least one separation film SF connects the vertical channel structures VS included in at least one column or row on the horizontal plane, the at least one separation film trench SFT may be used as a passage through which the etching gas is introduced into the channel holes CH in a process of etching the channel holes CH in which the vertical channel structures VS are formed. Accordingly, an etching profile may be secured through the at least one separation film trench SFT.

Although it has been described that the at least one separation film SF connects the vertical channel structures VS included in at least one column or row on the horizontal plane and extends in the vertical direction (e.g., the third direction D3), the at least one separation film SF is not restricted or limited thereto and may be formed to separate and isolate each of the word lines WL0 to WLn without making contact with the vertical channel structures VS as illustrated in FIG. 5. In this case, the at least one separation film SF may have a shape in which protrusions 510 and indentations 520 are repeated along the direction in which the at least one separation film SF is formed on the horizontal plane. This shape is to overcome the limitation that it is difficult for the at least one separation film trench SFT to be uniformly formed with a constant width when the at least one separation film SF has a long line shape.

The 3D flash memory having the above-described structure may perform a program operation, a read operation, and an erase operation, based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL. For example, the 3D flash memory may perform a program operation by forming a channel in the vertical channel pattern VCP and transferring charges or holes to the data storage pattern DSP of a target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Without being restricted or limited to the described structure, the 3D flash memory may be implemented in various structures on the premise that the 3D flash memory includes the vertical channel pattern VCP, the data storage pattern DSP, the at least one separation film SF, the gate electrodes EL1, EL2, and EL3, the bit line BL, and the common source line CSL.

For example, the 3D flash memory may be implemented in a structure that includes a back gate BG instead of the vertical semiconductor pattern VSP making contact with the inner wall of the vertical channel pattern VCP. In this case, the back gate BG may be at least partially surrounded by the vertical channel pattern VCP to apply a voltage for a memory operation to the vertical channel pattern VCP. The back gate BG may be formed of a conductive material including at least one selected from doped semiconductor (e.g., doped silicon), metal (e.g., tungsten (W), copper (Cu), aluminum (Al), titanium (Ti), tantalum (Ta), molybdenum (Mo), ruthenium (Ru), or gold (Au)), or conductive metal nitride (e.g., titanium nitride or tantalum nitride) and may extend in the vertical direction (e.g., the third direction D3).

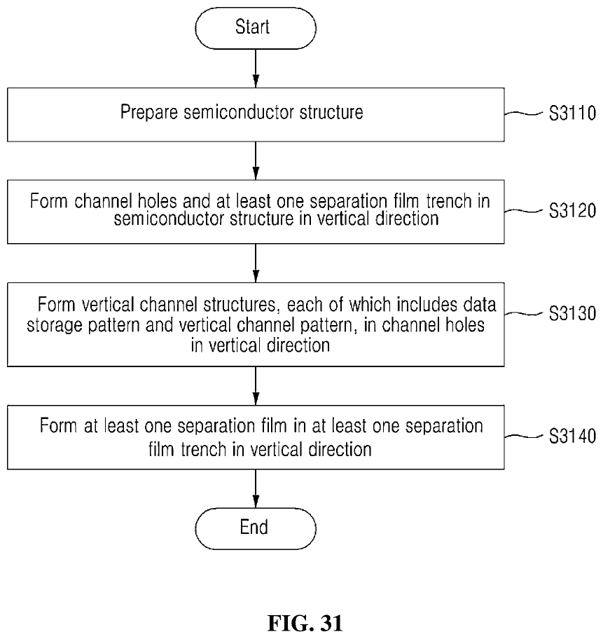

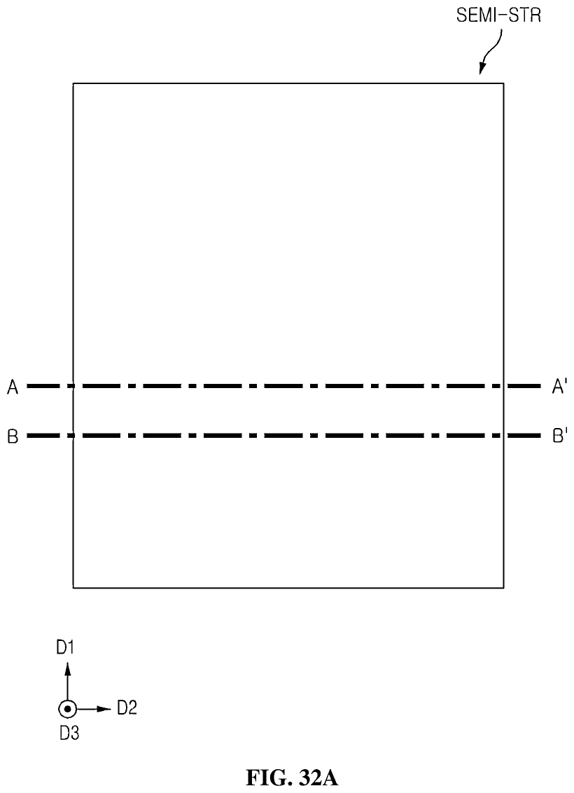

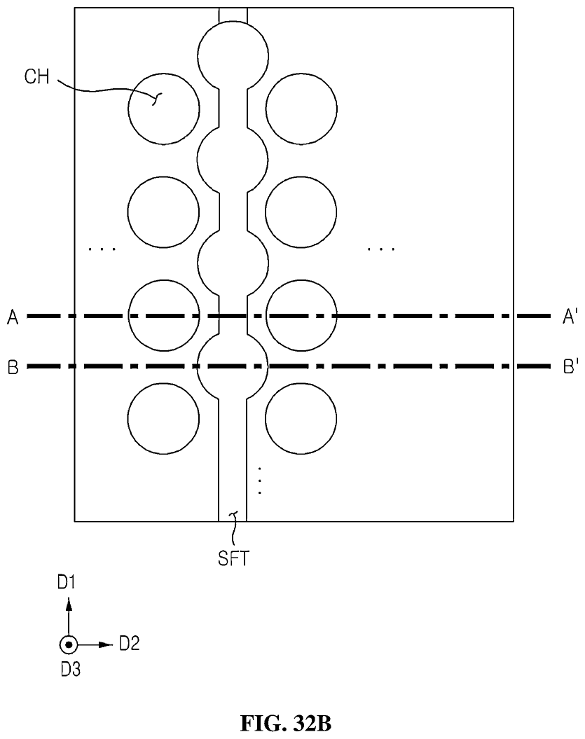

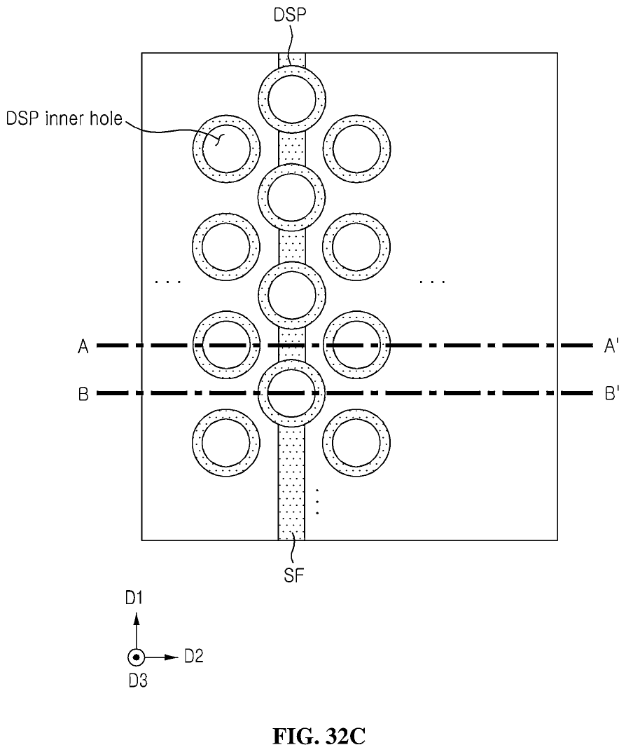

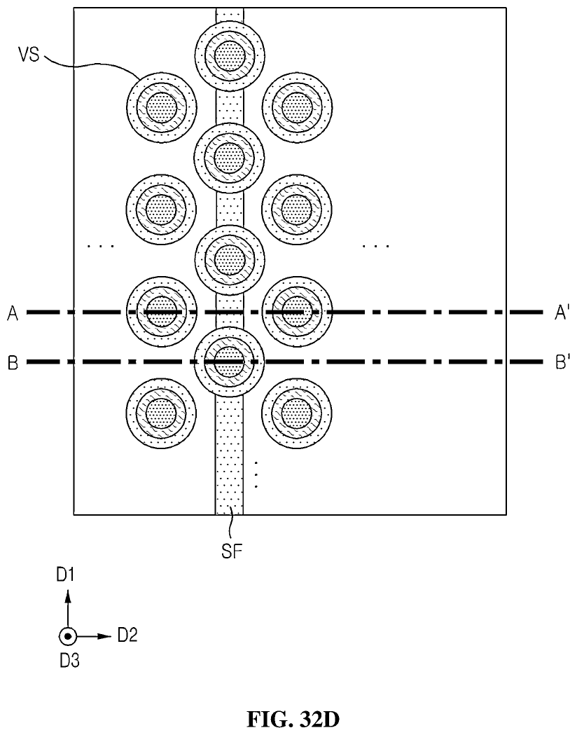

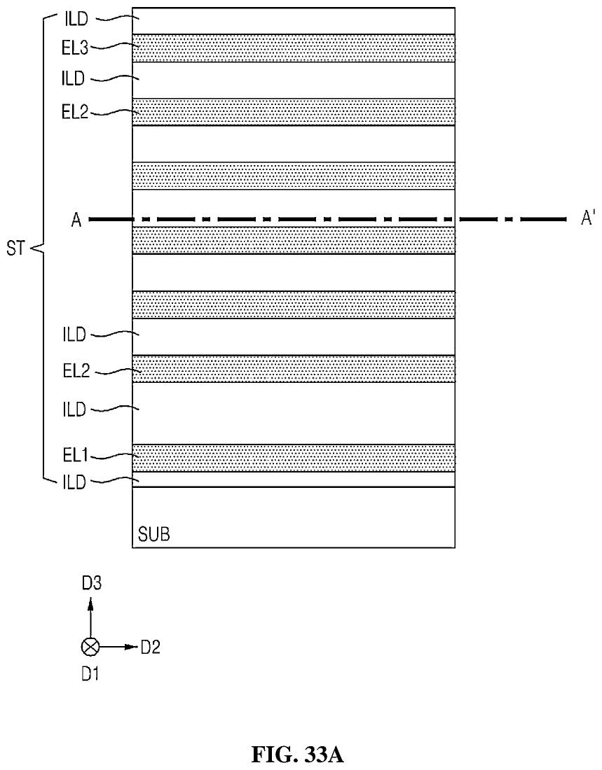

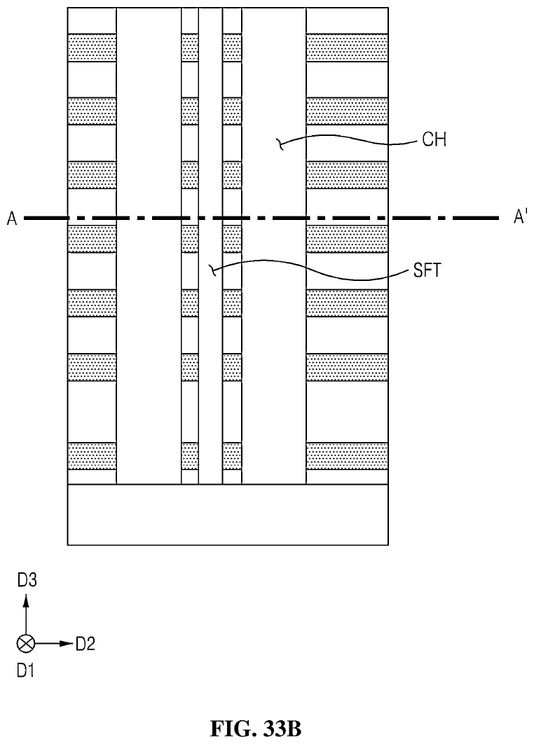

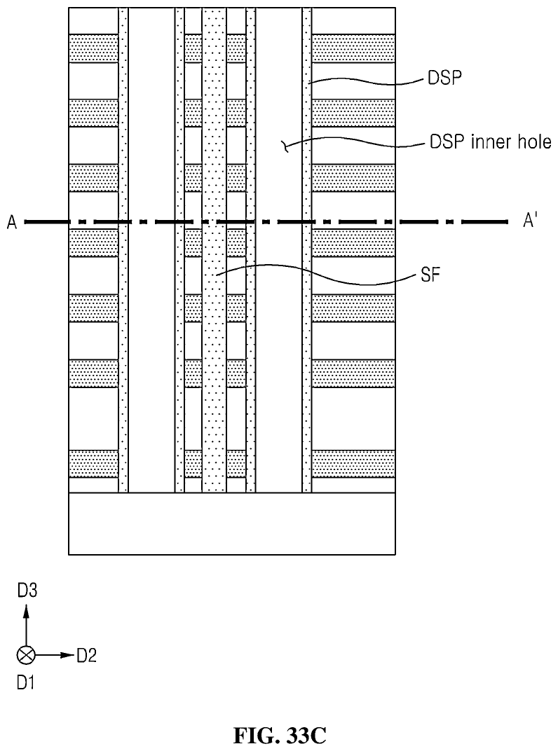

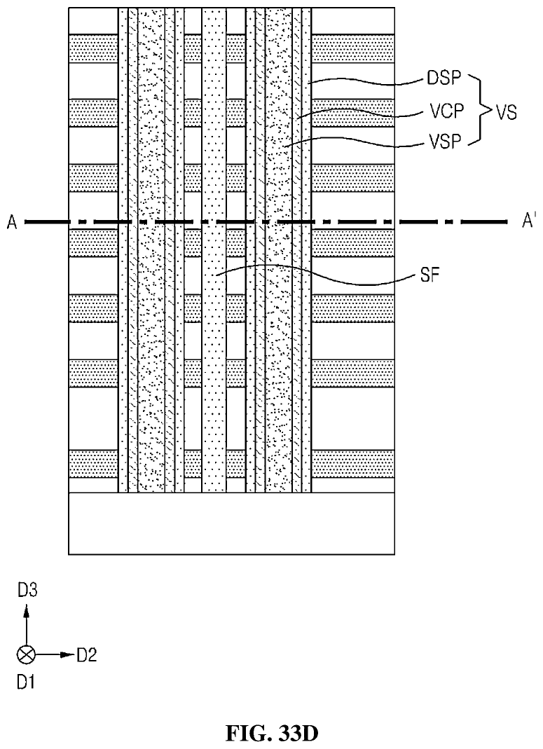

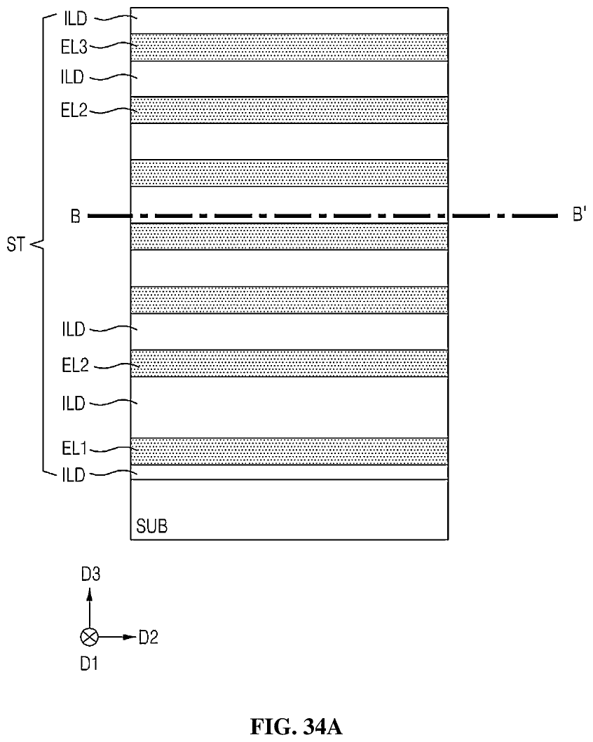

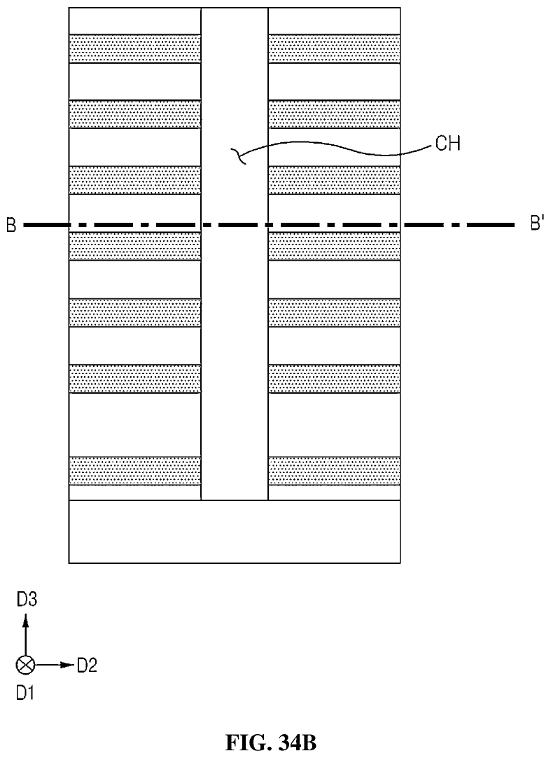

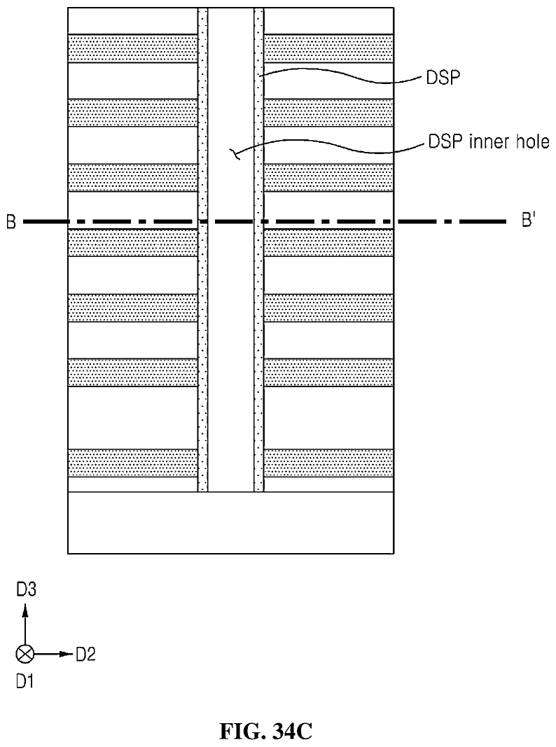

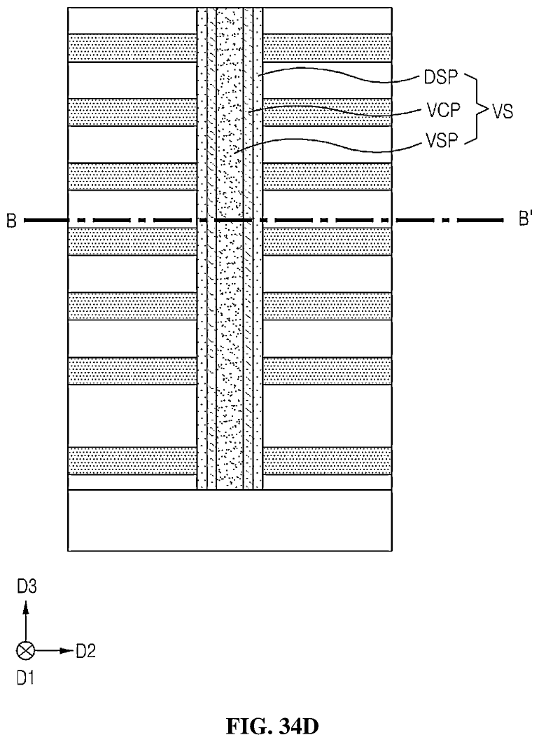

FIG. 31 is a flowchart illustrating a 3D flash memory manufacturing method according to an embodiment in which the gate first method is applied to manufacture the 3D flash memory illustrated in FIGS. 27 and 28. FIGS. 32A to 32D are plan views illustrating the structure of the 3D flash memory to explain the 3D flash memory manufacturing method illustrated in FIG. 31. FIGS. 33A to 33D are sectional views illustrating the structure of the 3D flash memory illustrated in FIGS. 32A to 32D and correspond to sections taken along lines A-A′ in FIGS. 32A to 32D. FIGS. 34A to 34D are sectional views illustrating the structure of the 3D flash memory illustrated in FIGS. 32A to 32D and correspond to sections taken along lines B-B′ in FIGS. 32A to 32D.

The 3D flash memory manufacturing method according to this embodiment is for manufacturing the 3D flash memory having the structure described with reference to FIGS. 27 and 28 by applying the gate first method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one separation film SF. Since the constituent materials constituting the components of the 3D flash memory have been described with reference to FIGS. 27 and 28, detailed description thereabout will be omitted.

In step S3110, as illustrated in FIGS. 32A, 33A, and 34A, the manufacturing system may prepare a semiconductor structure SEMI-STR including the interlayer insulating films ILD and the word lines WL0 to WLn that extend in the horizontal direction (e.g., the second direction D2) and that are alternately stacked in the vertical direction (e.g., the third direction D3).

In step S3120, as illustrated in FIGS. 32B, 33B, and 34B, the manufacturing system may form the channel holes CH and the at least one separation film trench SFT in the semiconductor structure SEMI-STR in the vertical direction (e.g., the third direction D3).

Here, the at least one separation film trench SFT may be formed at a position connecting channel holes CH included in at least one column or row among the channel holes CH in the stack structure ST on the horizontal plane. This is limited to the case of manufacturing the 3D flash memory having the structure illustrated in FIGS. 27 to 29, and when the 3D flash memory having the structure illustrated in FIG. 30 is manufactured, the at least one separation film trench SFT may be formed to separate and isolate the plurality of word lines WL0 to WLn without making contact with the channel holes CH. In more detail, when the 3D flash memory having the structure illustrated in FIG. 30 is manufactured, the manufacturing system may, in step S3120, form the at least one separation film trench SFT having a shape in which protrusions and indentations are repeated in the extension direction on the horizontal plane to separate each of the word lines WL0 to WLn into a plurality of word lines on the horizontal plane.

The manufacturing system may form the at least one separation film trench SFT in a size smaller than the size of each of the channel holes CH on the horizontal plane. Accordingly, the vertical channel structures VS formed in step S3130 to be described below may maintain the gate all around (GAA) structure, and field characteristics applied to the cell string CSTR may be maintained the same as those of the GAA structure.

In step S3120, forming the channel holes CH and forming the at least one separation film trench SFT may be simultaneously performed through a single process. Accordingly, the etching gas may be smoothly introduced into the channel holes CH through the at least one separation film trench SFT, and thus an etching profile may be secured.

In step S3130, the manufacturing system may form the vertical channel structures VS, each of which includes the data storage pattern DSP and the vertical channel pattern VCP, in the channel holes CH in the vertical direction (e.g., the third direction D3).

In more detail, step S3130 may include a first step of forming the data storage pattern DSP on the inner wall of each of the channel holes CH as illustrated in FIGS. 32C, 33C, and 34C and a second step of forming the vertical channel pattern VCP on the inner wall of the data storage pattern DSP as illustrated in FIGS. 32D, 33D, and 34D (the vertical semiconductor pattern VSP is also formed together with the vertical channel pattern VCP when the vertical semiconductor pattern VSP is included).

In step S3140, the manufacturing system may form the at least one separation film SF in the at least one separation film trench SFT in the vertical direction (e.g., the third direction D3).

Here, as illustrated in FIGS. 32C, 33C, and 34C, step S3130 and step S3140 may be simultaneously performed through the same process. In more detail, the manufacturing system may form the at least one separation film SF by depositing the data storage pattern DSP in the at least one separation film trench SFT through a process of depositing the data storage pattern DSP of the vertical channel structure VS in the channel hole CH. Accordingly, step S3140 may be a step of forming the at least one separation film SF with the data storage pattern DSP as the first step of step S3130 is performed, and thus simplification of the process of filling the at least one separation film trench SFT may be achieved.

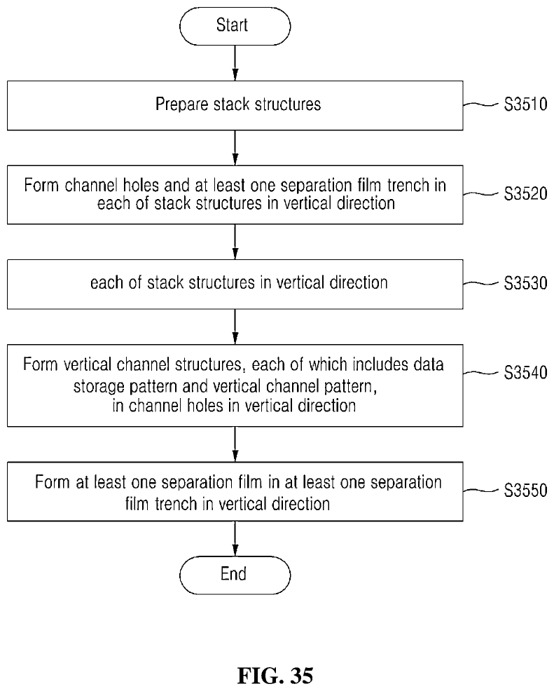

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 35.

FIG. 35 is a flowchart illustrating a 3D flash memory manufacturing method according to an embodiment in which the stack method is applied in addition to the gate first method to manufacture the 3D flash memory illustrated in FIGS. 27 and 28.

The 3D flash memory manufacturing method according to this embodiment is for manufacturing the 3D flash memory having the structure described with reference to FIGS. 27 and 28 by applying the gate first method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one separation film SF. Since the constituent materials constituting the components of the 3D flash memory have been described with reference to FIGS. 27 and 28, detailed description thereabout will be omitted.

In step S3510, the manufacturing system may prepare stack structures ST-STR, each of which includes the interlayer insulating films ILD and the word lines WL0 to WLn that extend in the horizontal direction (e.g., the second direction D2) and that are alternately stacked in the vertical direction (e.g., the third direction D3).

In step S3520, the manufacturing system may form the channel holes CH and the at least one separation film trench SFT in each of the stack structures ST-STR in the vertical direction (e.g., the third direction D3).

Here, the at least one separation film trench SFT may be formed at a position connecting channel holes CH included in at least one column or row among the channel holes CH in the stack structure ST on the horizontal plane. This is limited to the case of manufacturing the 3D flash memory having the structure illustrated in FIGS. 27 to 29, and when the 3D flash memory having the structure illustrated in FIG. 30 is manufactured, the at least one separation film trench SFT may be formed to separate and isolate the plurality of word lines WL0 to WLn without making contact with the channel holes CH. In more detail, when the 3D flash memory having the structure illustrated in FIG. 30 is manufactured, the manufacturing system may, in step S3520, form the at least one separation film trench SFT having a shape in which protrusions and indentations are repeated in the extension direction on the horizontal plane to separate each of the word lines WL0 to WLn into a plurality of word lines on the horizontal plane.

The manufacturing system may form the at least one separation film trench SFT in a size smaller than the size of each of the channel holes CH on the horizontal plane. Accordingly, the vertical channel structures VS formed in step S3540 to be described below may maintain the gate all around (GAA) structure, and field characteristics applied to the cell string CSTR may be maintained the same as those of the GAA structure.

In step S3520, forming the channel holes CH and forming the at least one separation film trench SFT may be simultaneously performed through a single process. Accordingly, the etching gas may be smoothly introduced into the channel holes CH through the at least one separation film trench SFT, and thus an etching profile may be secured.

In step S3530, the manufacturing system may stack the stack structures ST-STR in the vertical direction (e.g., the third direction D3).

In step S3540, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S3540 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S3550, the manufacturing system may form the at least one separation film SF in the at least one separation film trench SFT in the vertical direction (e.g., the third direction D3).

Here, step S3540 and step S3550 may be simultaneously performed through the same process. In more detail, the manufacturing system may form the at least one separation film SF by depositing the data storage pattern DSP in the at least one separation film trench SFT through a process of depositing the data storage pattern DSP of the vertical channel structure VS in the channel hole CH. Accordingly, step S3550 may be a step of forming the at least one separation film SF with the data storage pattern DSP as the first step of step S3540 is performed, and thus simplification of the process of filling the at least one separation film trench SFT may be achieved.

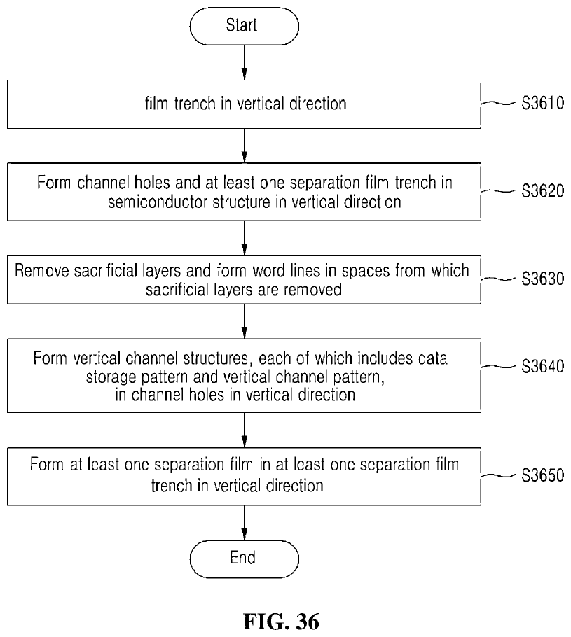

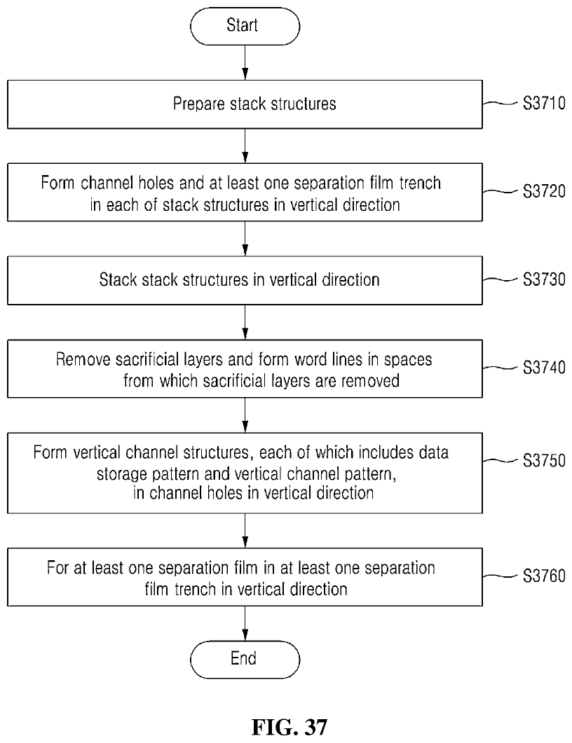

Although it has been described that the 3D flash memory is manufactured based on the gate first method, the present disclosure is not restricted or limited thereto, and the 3D flash memory may be manufactured based on the word line replacement method. Detailed description thereabout will be given below with reference to FIGS. 36 and 37.

FIG. 36 is a flowchart illustrating a 3D flash memory manufacturing method according to an embodiment in which the word line replacement method is applied to manufacture the 3D flash memory illustrated in FIGS. 27 and 28.

The 3D flash memory manufacturing method according to this embodiment is for manufacturing the 3D flash memory having the structure described with reference to FIGS. 27 and 28 by applying the word line replacement method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one separation film SF. Since the constituent materials constituting the components of the 3D flash memory have been described with reference to FIGS. 27 and 28, detailed description thereabout will be omitted.

In step S3610, the manufacturing system may prepare a semiconductor structure SEMI-STR including the interlayer insulating films ILD and sacrificial layers SAC that extend in the horizontal direction (e.g., the second direction D2) and that are alternately stacked in the vertical direction (e.g., the third direction D3).

In step S3620, the manufacturing system may form the channel holes CH and the at least one separation film trench SFT in the semiconductor structure SEMI-STR in the vertical direction (e.g., the third direction D3).

Here, the at least one separation film trench SFT may be formed at a position connecting channel holes CH included in at least one column or row among the channel holes CH in the stack structure ST on the horizontal plane. This is limited to the case of manufacturing the 3D flash memory having the structure illustrated in FIGS. 27 to 29, and when the 3D flash memory having the structure illustrated in FIG. 30 is manufactured, the at least one separation film trench SFT may be formed to separate and isolate the plurality of sacrificial layers SAC without making contact with the channel holes CH. In more detail, when the 3D flash memory having the structure illustrated in FIG. 30 is manufactured, the manufacturing system may, in step S3620, form the at least one separation film trench SFT having a shape in which protrusions and indentations are repeated in the extension direction on the horizontal plane to separate each of the sacrificial layers SAC into a plurality of sacrificial layers on the horizontal plane.

The manufacturing system may form the at least one separation film trench SFT in a size smaller than the size of each of the channel holes CH on the horizontal plane. Accordingly, the vertical channel structures VS formed in step S3630 to be described below may maintain the gate all around (GAA) structure, and field characteristics applied to the cell string CSTR may be maintained the same as those of the GAA structure.

In step S3620, forming the channel holes CH and forming the at least one separation film trench SFT may be simultaneously performed through a single process. Accordingly, the etching gas may be smoothly introduced into the channel holes CH through the at least one separation film trench SFT, and thus an etching profile may be secured.

In step S3630, the manufacturing system may remove the sacrificial layers SAC and may form the word liens WL0 to WLn in the spaces from which the sacrificial layers SAC are removed. Removing the sacrificial layers SAC and filling a conductive material to form the word lines WL0 to WLn may be performed through the channel holes CH or the at least one separation film trench SFT. However, without being restricted or limited thereto, removing the sacrificial layers SAC and filling the conductive material to form the word lines WL0 to WLn may be performed through a separate trench (not illustrated).

In step S3640, the manufacturing system may form the vertical channel structures VS, each of which includes the data storage pattern DSP and the vertical channel pattern VCP, in the channel holes CH in the vertical direction (e.g., the third direction D3).

In more detail, step S3640 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S3650, the manufacturing system may form the at least one separation film SF in the at least one separation film trench SFT in the vertical direction (e.g., the third direction D3).

Here, step S3640 and step S3650 may be simultaneously performed through the same process. In more detail, the manufacturing system may form the at least one separation film SF by depositing the data storage pattern DSP in the at least one separation film trench SFT through a process of depositing the data storage pattern DSP of the vertical channel structure VS in the channel hole CH. Accordingly, step S3650 may be a step of forming the at least one separation film SF with the data storage pattern DSP as the first step of step S3640 is performed, and thus simplification of the process of filling the at least one separation film trench SFT may be achieved.

Although it has been described that the 3D flash memory is manufactured based on one semiconductor structure, the present disclosure is not restricted or limited thereto, and the 3D flash memory structure may be manufactured using a stack method in which a plurality of stack structures are stacked. Detailed description thereabout will be given below with reference to FIG. 37.

FIG. 37 is a flowchart illustrating a 3D flash memory manufacturing method according to an embodiment in which the stack method is applied in addition to the word line replacement method to manufacture the 3D flash memory illustrated in FIGS. 27 and 28.

The 3D flash memory manufacturing method according to this embodiment is for manufacturing the 3D flash memory having the structure described with reference to FIGS. 27 and 28 by applying the gate first method and is assumed to be performed by an automated and mechanized manufacturing system.

Hereinafter, for convenience of description, the manufacturing method is described as manufacturing the 3D flash memory having the structure including the interlayer insulating films ILD, the word lines WL0 to WLn, the vertical channel structures VS, and the at least one separation film SF. Since the constituent materials constituting the components of the 3D flash memory have been described with reference to FIGS. 27 and 28, detailed description thereabout will be omitted.

In step S3710, the manufacturing system may prepare stack structures ST-STR, each of which includes the interlayer insulating films ILD and the sacrificial layers SAC that extend in the horizontal direction (e.g., the second direction D2) and that are alternately stacked in the vertical direction (e.g., the third direction D3).

In step S3720, the manufacturing system may form the channel holes CH and the at least one separation film trench SFT in each of the stack structures ST-STR in the vertical direction (e.g., the third direction D3).

Here, the at least one separation film trench SFT may be formed at a position connecting channel holes CH included in at least one column or row among the channel holes CH in the stack structure ST on the horizontal plane. This is limited to the case of manufacturing the 3D flash memory having the structure illustrated in FIGS. 27 to 29, and when the 3D flash memory having the structure illustrated in FIG. 30 is manufactured, the at least one separation film trench SFT may be formed to separate and isolate the plurality of sacrificial layers SAC without making contact with the channel holes CH. In more detail, when the 3D flash memory having the structure illustrated in FIG. 30 is manufactured, the manufacturing system may, in step S3720, form the at least one separation film trench SFT having a shape in which protrusions and indentations are repeated in the extension direction on the horizontal plane to separate each of the sacrificial layers SAC into a plurality of sacrificial layers on the horizontal plane.

The manufacturing system may form the at least one separation film trench SFT in a size smaller than the size of each of the channel holes CH on the horizontal plane. Accordingly, the vertical channel structures VS formed in step S3750 to be described below may maintain the gate all around (GAA) structure, and field characteristics applied to the cell string CSTR may be maintained the same as those of the GAA structure.

In step S3720, forming the channel holes CH and forming the at least one separation film trench SFT may be simultaneously performed through a single process. Accordingly, the etching gas may be smoothly introduced into the channel holes CH through the at least one separation film trench SFT, and thus an etching profile may be secured.

In step S3730, the manufacturing system may stack the stack structures ST-STR in the vertical direction (e.g., the third direction D3).

In step S3740, the manufacturing system may remove the sacrificial layers SAC and may form the word liens WL0 to WLn in the spaces from which the sacrificial layers SAC are removed. Removing the sacrificial layers SAC and filling a conductive material to form the word lines WL0 to WLn may be performed through the channel holes CH or the at least one separation film trench SFT. However, without being restricted or limited thereto, removing the sacrificial layers SAC and filling the conductive material to form the word lines WL0 to WLn may be performed through a separate trench (not illustrated).

In step S3750, the manufacturing system may form the vertical channel structures VS, each of which includes the data storage pattern DSP and the vertical channel pattern VCP, in the channel holes CH in the vertical direction (e.g., the third direction D3) in the semiconductor structure SEMI-STR in which the stack structures ST-STR are stacked in the vertical direction (e.g., the third direction D3).

In more detail, step S3750 may include a first step of forming the data storage pattern DSP on the inner wall of each of the channel holes CH and a second step of forming the vertical channel pattern VCP on the inner wall of the data storage pattern DSP (the vertical semiconductor pattern VSP is also formed together with the vertical channel pattern VCP when the vertical semiconductor pattern VSP is included).

In step S3760, the manufacturing system may form the at least one separation film SF in the at least one separation film trench SFT in the vertical direction (e.g., the third direction D3).

Here, step S3750 and step S3760 may be simultaneously performed through the same process. In more detail, the manufacturing system may form the at least one separation film SF by depositing the data storage pattern DSP in the at least one separation film trench SFT through a process of depositing the data storage pattern DSP of the vertical channel structure VS in the channel hole CH. Accordingly, step S3760 may be a step of forming the at least one separation film SF with the data storage pattern DSP as the first step of step S3750 is performed, and thus simplification of the process of filling the at least one separation film trench SFT may be achieved.

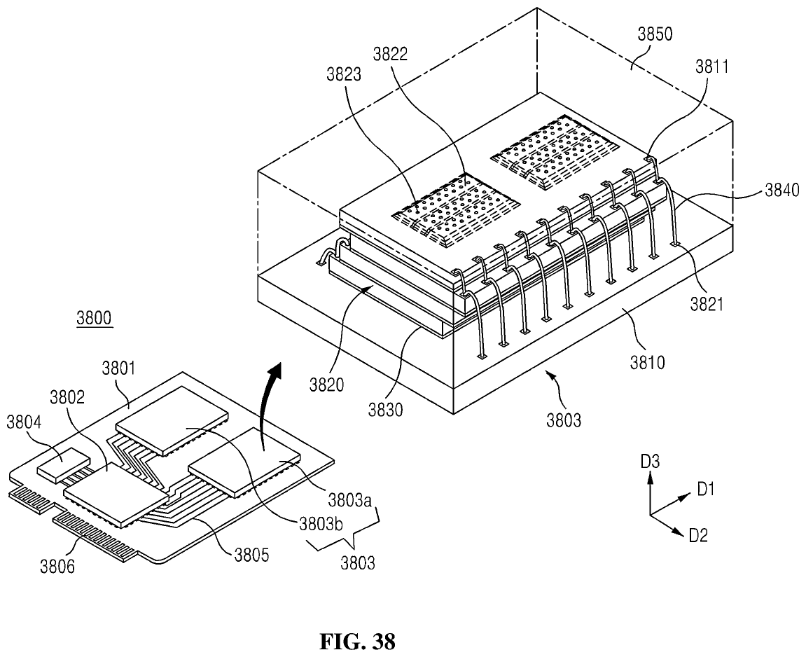

FIG. 38 is a schematic perspective view illustrating an electronic system including a 3D flash memory according to an embodiment.

Referring to FIG. 38, the electronic system 3800 including the 3D flash memory according to this embodiment may include a main board 3801, a controller 3802, one or more semiconductor packages 3803, and a DRAM 3804. The controller 3802, the one or more semiconductor packages 3803, and the DRAM 3804 may be mounted on the main board 3801.

The semiconductor packages 3803 and the DRAM 3804 may be connected with the controller 3802 by wiring patterns 3805 provided on the main board 3801.

The main board 3801 may include a connector 3806 including a plurality of pins coupled with an external host. The number and arrangement of pins in the connector 3806 may vary depending on a communication interface between the electronic system 3800 and the external host.

The electronic system 3800 may communicate with the external host depending on one of interfaces, such as universal serial bus (USB), peripheral component interconnect express (PCIExpress), serial advanced technology attachment (SATA), M-Phy for universal flash storage (UFS), and the like. For example, the electronic system 3800 may be operated by power supplied from the external host through the connector 3806. The electronic system 3800 may further include a power management integrated circuit (PMIC) that distributes the power supplied from the external host to the controller 3802 and the semiconductor packages 3803.

The controller 3802 may record data in the semiconductor packages 3803 or may read data from the semiconductor packages 3803 and may improve the operating speed of the electronic system 3800.

The DRAM 3804 may be a buffer memory for alleviating a difference in speed between the semiconductor packages 3803, which are data storage spaces, and the external host. The DRAM 3804 included in the electronic system 3800 may operate as a type of cache memory and may provide a space for temporarily storing data in a control operation for the semiconductor packages 3803. When the DRAM 3804 is included in the electronic system 3800, the controller 3802 may further include a DRAM controller for controlling the DRAM 3804, in addition to a NAND controller for controlling the semiconductor packages 3803.

The semiconductor packages 3803 may include first and second semiconductor packages 3803a and 3803b spaced apart from each other. Each of the first and second semiconductor packages 3803a and 3803b may be a semiconductor package including a plurality of semiconductor chips 3820. Each of the first and second semiconductor packages 3803a and 3803b may include a package substrate 3810, the semiconductor chips 3820 on the package substrate 3810, adhesive layers 3830 disposed on the lower surfaces of the respective semiconductor chips 3820, connecting structures 3840 electrically connecting the semiconductor chips 3820 and the package substrate 3810, and a molding layer 3850 covering the semiconductor chips 3820 and the connecting structures 3840 on the package substrate 3810.

The package substrate 3810 may be a printed circuit board including upper package pads 3811. Each of the semiconductor chips 3820 may include input/output pads 3821. Each of the semiconductor chips 3820 may include the 3D flash memory described above with reference to FIGS. 1 to 4 and 27 to 30. More specifically, each of the semiconductor chips 3820 may include gate stack structures 3822 and memory channel structures 3823. The gate stack structures 3822 may correspond to the above-described stack structures ST, and the memory channel structures 3823 may correspond to the vertical channel structures VS and the at least one vertical connecting pattern VP described above.

The connecting structures 3840 may be, for example, bonding wires electrically connecting the input/output pads 3821 and the upper package pads 3811. Accordingly, in each of the first and second semiconductor packages 3803a and 3803b, the semiconductor chips 3820 may be electrically connected with one another by a bonding wire method and may be electrically connected with the upper package pads 3811 of the package substrate 3810. In some embodiments, in each of the first and second semiconductor packages 3803a and 3803b, the semiconductor chips 3820 may be electrically connected with one other by Through Silicon Vias instead of the bonding wire-type connecting structures 3840.

Unlike those illustrated in the drawing, the controller 3802 and the semiconductor chips 3820 may be included in one package. The controller 3802 and the semiconductor chips 3820 may be mounted on a separate interposer substrate different from the main board 3801 and may be electrically connected with each other by wiring provided on the interposer substrate.

Hereinabove, although the present disclosure has been described with reference to the exemplary embodiments and the accompanying drawings, the present disclosure is not limited thereto, but may be variously modified and altered by those skilled in the art to which the present disclosure pertains. For example, suitable results may be achieved even though the described techniques are performed in a different order, and/or even though components in a described system, architecture, device, or circuit are coupled or combined in a different manner and/or replaced or supplemented by other components or their equivalents.

Therefore, other implementations, other embodiments, and equivalents of the claims also fall within the scope of the claims to be described below.

1. A 3D flash memory comprising:
interlayer insulating films and word lines configured to extend in a horizontal direction and alternately stacked in a vertical direction;
vertical channel structures configured to extend through the interlayer insulating films and the word lines in the vertical direction, wherein each of the vertical channel structures includes a vertical channel pattern configured to extend in the vertical direction and a data storage pattern configured to surround an outer wall of the vertical channel pattern; and
at least one vertical connecting pattern configured to connect the vertical channel structures to each other on a horizontal plane and extend in the vertical direction.

2. The 3D flash memory of claim 1, wherein the at least one vertical connecting pattern is simultaneously formed with the vertical channel structures through the same process.

3. The 3D flash memory of claim 2, wherein the at least one vertical connecting pattern is formed of only the data storage pattern included in each of the vertical channel structures.

4. The 3D flash memory of claim 1, wherein the at least one vertical connecting pattern has a size smaller than a size of each of the vertical channel structures on the horizontal plane.

5. The 3D flash memory of claim 1, wherein the at least one vertical connecting pattern connects the vertical channel structures to each other to divide the word lines on the horizontal plane.

6. A mask pattern used to form vertical channel structures and at least one vertical connecting pattern in a 3D flash memory, wherein the vertical channel structures extend in a vertical direction, each of which includes a vertical channel pattern configured to extend in the vertical direction and a data storage pattern configured to surround an outer wall of the vertical channel pattern, and the at least one vertical connecting pattern connects the vertical channel structures to each other on a horizontal plane and extends in the vertical direction, the mask pattern comprising:
a serif-shaped portion included in an area corresponding to an edge where the at least one vertical connecting pattern is brought into contact with each of the vertical channel structures.

7. The mask pattern of claim 6, wherein the mask pattern comprises the serif-shaped portion considering optical proximity correction (OPC) in a process in which the mask pattern is used.

8. The mask pattern of claim 7, wherein the mask pattern comprises the serif-shaped portion in the area corresponding to the edge where the at least one vertical connecting pattern is brought into contact with each of the vertical channel structures such that a rounded portion is not included in the edge where the at least one vertical connecting pattern is brought into contact with each of the vertical channel structures.

9. A 3D flash memory comprising:
interlayer insulating films and word lines configured to extend in a horizontal direction and alternately stacked in a vertical direction;
vertical channel structures configured to extend through the interlayer insulating films and the word lines in the vertical direction, wherein each of the vertical channel structures includes a vertical channel pattern configured to extend in the vertical direction and a data storage pattern configured to surround an outer wall of the vertical channel pattern; and
at least one separation film formed of the same material as that of the data storage pattern and configured to divide each of the word lines into a plurality of word lines on a horizontal plane.

10. The 3D flash memory of claim 9, wherein the at least one separation film connects vertical channel structures included in at least one row or column among the vertical channel structures on the horizontal plane.

11. The 3D flash memory of claim 10, wherein the at least one separation film includes:
the vertical channel structures included in the at least one row or column; and
connecting parts configured to connect the vertical channel structures included in the at least one row or column on the horizontal plane.

12. The 3D flash memory of claim 11, wherein each of the vertical channel structures included in the at least one row or column does not include the vertical channel pattern.

13. The 3D flash memory of claim 9, wherein the at least one separation film has a shape in which protrusions and indentations are repeated in an extension direction on the horizontal plane to divide each of the word lines into the plurality of portions on the horizontal plane.

14. The 3D flash memory of claim 9, wherein the at least one separation film is simultaneously formed with the vertical channel structures through the same process.
